(19) United States
(12) Patent Application Publication
(10) Pub. No.: US 2024/0414914 A1
(43) Pub. Date: Dec. 12, 2024

(54) MEMORY BLOCK AND MANUFACTURE METHOD THEREOF

(71) Applicant: WUHAN XINXIN SEMICONDUCTOR MANUFACTURING CO., LTD., Wuhan (CN)

(72) Inventors: Kaiwei CAO, Wuhan (CN); Wuqian GENG, Wuhan (CN); Wei FENG, Wuhan (CN); Qiong ZHAN, Wuhan (CN)

(21) Appl. No.: 18/528,818

(22) Filed: Dec. 5, 2023

(30) Foreign Application Priority Data
Jun. 9, 2023 (CN) 202310690422.5

(51) Int. Cl. H10B 43/23; H10B 41/23

(52) U.S. Cl. CPC H10B 43/23; H10B 41/23

(57) ABSTRACT

The present disclosure provides a memory block and a manufacture method thereof. The memory block includes a substrate, a memory array, and a well-lead-out region. The memory array is arranged on the substrate and includes a plurality of semiconductor-strip-structure columns. The well-lead-out region includes a plurality of well-connection structures. Each semiconductor-strip-structure column extends to the well-lead-out region. In the well-lead-out region, each semiconductor-strip-structure column includes a stepped structure with a plurality of steps. Each well-connection structure corresponds to a corresponding semiconductor-strip-structure column, for electrically connecting channel semiconductor strips in the corresponding semiconductor-strip-structure column together by using the stepped structure in the corresponding semiconductor-strip-structure column.

### CROSS REFERENCE TO RELATED APPLICATIONS

The present disclosure claims priority to Chinese Patent Application No. 202310690422.5 filed on Jun. 9, 2023, the entire contents of which are herein incorporated by reference in its entirety.

### TECHNICAL FIELD

The present disclosure relates to the field of semiconductor technology, in particular to a memory block and a manufacture method thereof.

### BACKGROUND

Two-dimensional (2D) memory array is prevalent in electronic devices. For example, the 2D memory array may include NOR flash-memory array, NAND flash-memory array, dynamic-random-access memory (DRAM) array, and so on. However, 2D memory array has already approached a scaling limit, and the memory density cannot be further improved. Although three-dimensional (3D) memory array may improve the memory density to a certain extent, how to lead out each channel portion of a plurality of memory cells of the 3D memory array is a technical problem required to be solved urgently.

### SUMMARY

The present disclosure provides a memory block and a manufacture method thereof.

In a first aspect, a memory block is provided. The memory block includes: a substrate; a memory array, arranged on the substrate and including a plurality of memory cells distributed in a three-dimensional array, wherein the memory array includes a plurality of memory subarray layers sequentially stacked along a height direction, and each memory subarray layer includes a drain-region semiconductor layer, a channel semiconductor layer, and a source-region semiconductor layer stacked along the height direction; each drain-region semiconductor layer includes a plurality of drain-region semiconductor strips distributed along a row direction, each channel semiconductor layer includes a plurality of channel semiconductor strips distributed along the row direction, and each source-region semiconductor layer includes a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column; and a well-lead-out region, including a plurality of well-connection structures, wherein each semiconductor-strip-structure column extends to the well-lead-out region; in the well-lead-out region, each semiconductor-strip-structure column includes a stepped structure with a plurality of steps; and each well-connection structure corresponds to a corresponding semiconductor-strip-structure column, for electrically connecting the channel semiconductor strips in the corresponding semiconductor-strip-structure column together by using the stepped structure in the corresponding semiconductor-strip-structure column, and then leads out the channel semiconductor strips in the corresponding semiconductor-strip-structure column.

In a second aspect, a manufacture method of a memory block is provided. The manufacture method includes: providing a semiconductor structure, wherein the semiconductor structure includes a substrate and a plurality of memory subarray layers arranged on the substrate and sequentially stacked along a height direction, and each memory subarray layer includes a drain-region semiconductor layer, a channel semiconductor layer, and a source-region semiconductor layer stacked along the height direction; each drain-region semiconductor layer includes a plurality of drain-region semiconductor strips distributed along a row direction, each channel semiconductor layer includes a plurality of channel semiconductor strips distributed along the row direction, and each source-region semiconductor layer includes a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column; forming a plurality of removing openings on the side of the semiconductor structure away from the substrate and corresponding to a well-lead-out region of the semiconductor structure, wherein each removing opening corresponds to a corresponding semiconductor-strip-structure column; removing at least part of the corresponding semiconductor-strip-structure column through the each removing opening, to enable each semiconductor-strip-structure column to include a stepped structure in the well-lead-out region, wherein the stepped structure includes a plurality of steps; and forming a well-connection structure in the each removing opening, wherein the well-connection structure corresponds to the corresponding semiconductor-strip-structure column, for electrically connecting the channel semiconductor strips in the corresponding semiconductor-strip-structure column together by using the stepped structure in the corresponding semiconductor-strip-structure column.

In a third aspect, a memory block is provided. The memory block includes: a substrate; a memory array, arranged on the substrate and including a plurality of memory cells distributed in a three-dimensional array, wherein the memory array includes a plurality of memory subarray layers sequentially stacked along a height direction, and each memory subarray layer includes a drain-region semiconductor layer, a channel semiconductor layer, and a source-region semiconductor layer stacked along the height direction; each drain-region semiconductor layer includes a plurality of drain-region semiconductor strips distributed along a row direction, each channel semiconductor layer includes a plurality of channel semiconductor strips distributed along the row direction, and each source-region semiconductor layer includes a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column; and a well-lead-out region, including a plurality of well-connection structures, wherein each semiconductor-strip-structure column extends to the well-lead-out region; in the well-lead-out region, each semiconductor-strip-structure column includes a stepped structure with a plurality of steps, to enable each channel semiconductor strip in each semiconductor-strip-structure column to be at least partially exposed; each well-connection structure corresponds to a corresponding semiconductor-strip-structure column, and includes a plurality of well-connection columns spaced apart from each other along the column direction; the well-connection columns and the channel semiconductor strips in the corresponding semiconductor-strip-structure column are arranged in one-to-one correspondence, one end of each well-connection column is connected to a corresponding channel semiconductor strip, the other end of each well-connection column serves as a well-lead-out pad.

### BRIEF DESCRIPTION OF THE DRAWINGS

In order to explain technical solutions of embodiments of the present disclosure more clearly, the following will briefly introduce figures required to be used in the description of the embodiments. Obviously, the figures in the following are only some embodiments of the present disclosure. For those skilled in the art, other figures may also be obtained from these figures.

FIG. 1 is perspective structural schematic view of a memory array according to an embodiment of the present disclosure.

FIG. 2 is a perspective structural schematic view of a memory array according to an embodiment of the present disclosure.

FIG. 3 is a perspective structural schematic view of a memory array according to an embodiment of the present disclosure.

FIG. 4 is a perspective structural schematic view of a memory array according to an embodiment of the present disclosure.

FIG. 5 is a perspective structural schematic view of a memory cell according to an embodiment of the present disclosure.

FIG. 6 is a perspective schematic view of a structure of which two memory cells share the same column of drain-region semiconductor strip, channel semiconductor strip, and source-region semiconductor strip.

FIG. 7 is a perspective structural schematic view of a memory cell according to an embodiment of the present disclosure.

FIG. 8 is a perspective structural schematic view of a memory cell according to an embodiment of the present disclosure.

FIG. 9 is a perspective schematic view of a partial structure of a memory device according to an embodiment of the present disclosure.

FIG. 10 is a perspective structural schematic view of a memory cell according to an embodiment of the present disclosure.

FIG. 11 is a perspective structural schematic view of a memory device according to an embodiment of the present disclosure.

FIG. 12 is a structural schematic view of a circuit connection of part of memory cells of a memory device according to an embodiment of the present disclosure.

FIG. 13 is a schematic view of a circuitry of the memory device shown in FIG. 11.

FIG. 14 is a schematic planar view of a memory device shown in FIG. 11.

FIG. 15 is a schematic view of memory cells corresponding to each layer of bit lines.

FIG. 16 is a schematic view of a three-dimensional distribution of word lines and bit lines.

FIG. 17 is a flowchart of a manufacture method of a memory device according to an embodiment of the present disclosure.

FIG. 18 is a schematic view of structure at specific operation of a manufacturing method of a memory device according to an embodiment of the present disclosure.

FIG. 19 is a schematic view of structure at specific operation of a manufacturing method of a memory device according to an embodiment of the present disclosure.

FIG. 20 is a schematic view of structure at specific operation of a manufacturing method of a memory device according to an embodiment of the present disclosure.

FIG. 21 is a schematic view of structure at specific operation of a manufacturing method of a memory device according to an embodiment of the present disclosure.

FIG. 22 a schematic view of structure at specific operation of a manufacturing method of a memory device according to an embodiment of the present disclosure.

FIG. 23 a schematic view of structure at specific operation of a manufacturing method of a memory device according to an embodiment of the present disclosure.

FIG. 24a is a schematic view of structure at specific operation of a manufacturing method of a memory device according to an embodiment of the present disclosure.

FIG. 24b is a schematic view of structure at specific operation of a manufacturing method of a memory device according to an embodiment of the present disclosure.

FIG. 25a is a schematic view of structure at specific operation of a manufacturing method of a memory device according to an embodiment of the present disclosure.

FIG. 25b is a schematic view of structure at specific operation of a manufacturing method of a memory device according to an embodiment of the present disclosure.

FIG. 26 is a schematic view of structure at specific operation of a manufacturing method of a memory device according to an embodiment of the present disclosure.

FIG. 27 is a schematic view of structure at specific operation of a manufacturing method of a memory device according to an embodiment of the present disclosure.

FIG. 28 is a flowchart of a manufacturing method of a memory device according to an embodiment of the present disclosure.

FIG. 29 is a schematic view of structure at specific operation of a manufacturing method of a memory device according to an embodiment of the present disclosure.

FIG. 30 is a schematic view of structure at specific operation of a manufacturing method of a memory device according to an embodiment of the present disclosure.

FIG. 31 is a schematic view of structure at specific operation of a manufacturing method of a memory device according to an embodiment of the present disclosure.

FIG. 32 is a schematic view of structure at specific operation of a manufacturing method of a memory device according to an embodiment of the present disclosure.

FIG. 33 is a schematic view of structure at specific operation of a manufacturing method of a memory device according to an embodiment of the present disclosure.

FIG. 34 is a schematic view of structure at specific operation of a manufacturing method of a memory device according to an embodiment of the present disclosure.

FIG. 35 is a schematic view of structure at specific operation of a manufacturing method of a memory device according to an embodiment of the present disclosure.

FIG. 36a is a schematic view of structure at specific operation of a manufacturing method of a memory device according to an embodiment of the present disclosure.

FIG. 36b is a schematic view of structure at specific operation of a manufacturing method of a memory device according to an embodiment of the present disclosure.

FIG. 37 is a schematic view of structure at specific operation of a manufacturing method of a memory device according to an embodiment of the present disclosure.

FIG. 38 is a schematic view of structure at specific operation of a manufacturing method of a memory device according to an embodiment of the present disclosure.

FIG. 39a is a schematic view of structure at specific operation of a manufacturing method of a memory device according to an embodiment of the present disclosure.

FIG. 39b is a schematic view of structure at specific operation of a manufacturing method of a memory device according to an embodiment of the present disclosure.

FIG. 40 is a schematic view of structure at specific operation of a manufacturing method of a memory device according to an embodiment of the present disclosure.

FIG. 41 is a schematic view of structure at specific operation of a manufacturing method of a memory device according to an embodiment of the present disclosure.

FIG. 42 is a schematic view of structure at specific operation of a manufacturing method of a memory device according to an embodiment of the present disclosure.

FIG. 43 is a schematic structural view of a memory block according to some embodiments of the present disclosure.

FIG. 44 is a schematic structural view of a well-lead-out region in FIG. 43 according to some embodiments of the present disclosure.

FIG. 45 is a schematic cross-section structural view along A-A in FIG. 44.

FIG. 46 is a schematic view of a stepped structure in FIG. 45.

FIG. 47 is a schematic structural view of a well-lead-out region in FIG. 43 according to some embodiments of the present disclosure.

FIG. 48 is a schematic view of a stepped structure in FIG. 47.

FIG. 49 is a schematic partial structural view of a memory block according to some embodiments of the present disclosure.

FIG. 50 is a schematic flow chart of a manufacture method of a memory block according to some embodiments of the present disclosure.

FIG. 51 is a schematic view of a semiconductor structure at operation S100.

FIG. 52 is a schematic view of a stepped structure at operation S200.

FIG. 53 is a schematic view of covering an insulating dielectric layer at operation S211.

FIG. 54 is a schematic view of covering an insulating dielectric on a second surface of each step at operation S212.

FIG. 55 is a schematic view of forming a connecting layer on a stepped structure at operation S310.

FIG. 56 is a schematic view of forming a protective layer on a connecting layer at operation S311.

FIG. 57 is a schematic view of removing a protective layer on a connecting layer at operation S312.

FIG. 58 is a schematic view of forming a metal layer on a connecting layer at operation S321.

FIG. 59 is a schematic view of forming a connection-improvement layer on a connecting layer at operation S322.

### DETAILED DESCRIPTION

Technical solutions in the embodiments of the present disclosure will be described clearly and completely in combination with figures in the embodiments of the present disclosure. It is understood that the specific embodiments described herein are only used to explain the present disclosure, but not to limit the present disclosure. In addition, it should be noted that, for the convenience of description, only a part of structures which related to the present disclosure are shown in the figures, but not all structures. Based on the embodiments in the present disclosure, all other embodiments obtained by those skilled in the art without doing any creative work are within the protection scope of the present disclosure.

The present disclosure is described in detail below in conjunction with the accompanying drawings and embodiments.

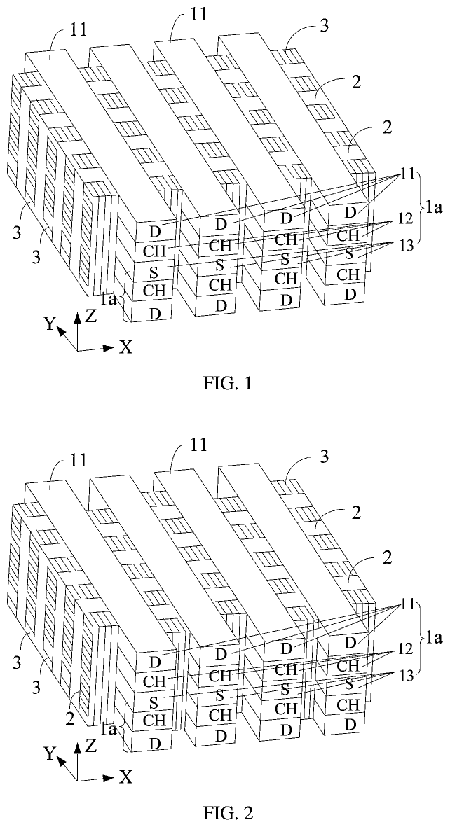

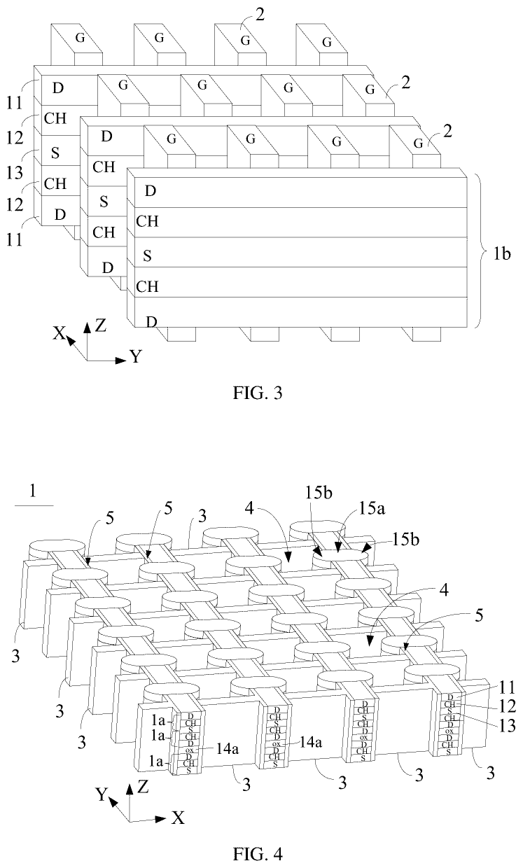

In some embodiments, a memory device is provided, which may specifically be a non-volatile memory device. FIGS. 1-3 are schematic perspective structural views of a memory array according to some embodiments of the present disclosure. The memory device may include a substrate 81 and one or more memory arrays 1 arranged on the substrate. The memory array 1 includes a structure in which multiple memory cells are arranged in a three-dimensional array; and the memory device may include, in addition to the memory array 1 formed by arranging the memory cells in an array, other components, such as various types of wires (or connection lines), etc., enabling the memory device to implement various memory operations.

For example, the number of the one or more memory arrays 1 is one. The memory array 1 includes a plurality of memory cells distributed in a three-dimensional array. As shown in FIG. 1, the memory array 1 includes multiple memory subarray layers 1a sequentially stacked along a height direction Z. Each memory subarray layer 1a includes a drain-region semiconductor layer, a channel semiconductor layer, and a source-region semiconductor layer stacked along the height direction Z. The drain-region semiconductor layer, the channel semiconductor layer, and the source-region semiconductor layer may each be a single-crystal semiconductor layer grown by epitaxy. The height direction Z is a direction perpendicular to the substrate 81. Herein, the term “sequentially stacked” indicates an arrangement from bottom to top on the substrate, while the term “stacked” indicates an arrangement and does not express or imply an upper/lower relationship between the layers or structures.

In each memory subarray layer 1a, the drain-region semiconductor layer (D) includes multiple drain-region semiconductor strips 11 spaced along a row direction X, each drain-region semiconductor strip 11 extending along a column direction Y. The channel semiconductor layer (CH) includes multiple channel semiconductor strips 12 spaced along the row direction X, each channel semiconductor strip 12 extending along the column direction Y. The source-region semiconductor layer (S) includes multiple source-region semiconductor strips 13 spaced along the row direction X, each source-region semiconductor strip 13 extending along the column direction Y. Each drain-region semiconductor strip 11, channel semiconductor strip 12, and source-region semiconductor strip 13 is a single-crystal semiconductor strip, respectively. It is understood by those skilled in the art that each drain-region semiconductor strip 11, channel semiconductor strip 12, and source-region semiconductor strip 13 may be a single-crystal semiconductor strip formed by processing the drain-region semiconductor layer, channel semiconductor layer, and source-region semiconductor layer formed by epitaxy generation, respectively. As shown in FIGS. 1-3, multiple gate strips 2 (G) are arranged on each side of each column of drain-region semiconductor strips 11, channel semiconductor strips 12, and source-region semiconductor strips 13, respectively, the multiple gate strips 2 distributed on a side of each column of drain-region semiconductor strips 11, channel semiconductor strips 12, and source-region semiconductor strips 13 are spaced along the column direction Y, and each gate strip 2 extends along the height direction Z, such that corresponding parts of the multiple drain-region semiconductor strips 11, channel semiconductor strips 12, and source-region semiconductor strips 13 in the same column in the multiple memory subarray layers 1a share a same gate strip 2.

As shown in FIG. 2, among the multiple gate strips 2, each gate strip in the column and the gate strip in the adjacent column are staggered in the row direction X. Of course, as shown in FIG. 1, each gate strip 2 in the same column and a corresponding gate strip 2, in an adjacent column, corresponding to the gate strip 2 in the row direction X, may be aligned with each other in the column direction Y. The staggered arrangement may reduce the influence of an electric field between the corresponding two gate strips 2 in adjacent columns.

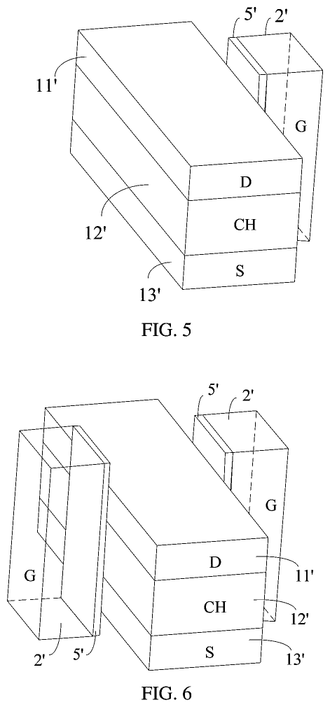

In the height direction Z, a projection of at least a part of each gate strip 2 coincides with a projection of a part of a corresponding channel semiconductor strip 12 in each memory subarray layer 1a on a projection plane. The projection plane is a plane defined by the height direction Z and the column direction Y, i.e., the projection plane extends along the height direction Z and the column direction Y. As shown in FIGS. 1-3, for the purpose of description, it is defined that a column of drain-region semiconductor strip 11, channel semiconductor strip 12, and source-region semiconductor strip 13 in each memory subarray layer 1a constitutes a semiconductor strip structure; two adjacent memory subarray layers 1a may share a common source, i.e., the two adjacent memory subarray layers 1a share a same source-region semiconductor layer (S). Therefore, two semiconductor strip structures corresponding to the two memory subarray layers 1a share a same source-region semiconductor strip 13. Of course, it is understood by those skilled in the art that the two adjacent memory subarray layers 1a may be arranged with a non-common source design, i.e., each memory subarray layer 1a has an independent source-region semiconductor layer, such that the two semiconductor strip structures corresponding to the two adjacent memory subarray layers 1a each has its own independent source-region semiconductor strip 13. In the multiple memory subarray layers 1a, the drain-region semiconductor strips 11, channel semiconductor strips 12, and source-region semiconductor strips 13 in the same column constitute a semiconductor-strip-structure column 1b, i.e., a stacked structure 1b. The semiconductor-strip-structure column 1b includes multiple semiconductor strip structures, and the number of the semiconductor strip structures in the semiconductor-strip-structure column 1b is the same as the number of the memory subarray layers 1a. As shown in FIGS. 1-3, each semiconductor-strip-structure column 1b includes two semiconductor strip structures, but those skilled in the art can understand that a semiconductor-strip-structure column 1b may include multiple stacked semiconductor strips. As shown in FIG. 4, which is a sketch of a perspective structure of a memory array according to another embodiment of the present disclosure, where a semiconductor-strip-structure column 1b includes three semiconductor strip structures.

In other words, it is understood by those skilled in the art that the memory array 1 includes multiple stacked structures 1b distributed along the row direction X, each stacked structure 1b extending along the column direction Y. Each stacked structure 1b includes drain-region semiconductor strips 11, channel semiconductor strips 12, and source-region semiconductor strips 13 stacked along the height direction. Each drain-region semiconductor strip 11, channel semiconductor strip 12, and source-region semiconductor strip 13 extends along the column direction Y. Multiple gate strips 2 spaced apart from each other along the column direction Y are arranged on each of two sides of each stacked structure 1b, and each gate strip 2 extends along the height direction Z.

A projection of a part of each semiconductor-strip-structure column 1b coincides with a projection of a corresponding part of a corresponding gate strip 2 on the projection plane. In particular, a projection of a part of the channel semiconductor strip 12 in each semiconductor-strip-structure column 1b coincides with a projection of a part of a corresponding gate strip 2 on the projection plane. In this way, a part of the gate strip 2, a corresponding part of the channel semiconductor strip 12, a part of the drain-region semiconductor strip 11 adjacent to the corresponding part of the channel semiconductor bar 12, and a part of the source-region semiconductor strip 13 adjacent to the corresponding part of the channel semiconductor bar 12 are configured to form a memory cell. For example, as shown in FIGS. 1-3, for the gate strip 2 of the first column along the row direction X and the first row along the column direction Y, a projection of a part of the gate strip 2 coincides with a projection of a corresponding part of the channel semiconductor strip 12 of the first column of the drain-region semiconductor strip 11, the channel semiconductor strip 12, and the source-region semiconductor strip 13 (a semiconductor strip structure with a D/CH/S structure) of the first memory subarray layer 1a in the height direction Z. That is, the part of the gate strip 2 of the first column and the first row, the corresponding part of the first column of the channel semiconductor strip 12 of the first memory subarray layer 1a in the height direction Z, and a part of the drain-region semiconductor 11 and a part of the source-region semiconductor 13, that are matched with the corresponding part of the first column of the channel semiconductor strip 12 of the first memory subarray layer 1a in the height direction Z, are configured to form a memory cell.

It will be understood by those skilled in the art that, a channel is required to be formed in a semiconductor region between the semiconductor drain region and the semiconductor source region; and the gate is arranged on a side of the semiconductor region between the semiconductor drain region and the semiconductor source region for constituting a semiconductor device. Therefore, as shown in FIGS. 1-3, the part of each gate strip 2 whose projection overlaps with the projection of a channel semiconductor strip 12 in an adjacent stacked structure 1b on the above projection plane is configured as a gate, i.e., a control gate of the corresponding memory cell; the part of the channel semiconductor strip 12 whose projection overlaps with the projection of the gate strip 2 on the above projection plane, i.e., the corresponding part of the channel semiconductor strip 12, is configured as the channel region (well region) for forming a channel therein; and the drain-region semiconductor strip 11 and the source-region semiconductor strip 13 adjacent to the channel semiconductor strip 12 each has a part arranged just above or below the corresponding part of the channel semiconductor strip 12, i.e., the parts of the drain-region semiconductor strip 11 and the source-region semiconductor strip 13 exactly match the corresponding part of the channel semiconductor strip 12 as the semiconductor drain region and the semiconductor source region. Therefore, the parts of the drain-region semiconductor strip 11 and the source-region semiconductor strip 13, the corresponding part of the channel semiconductor strip 12 sandwiched between the parts of the drain-region semiconductor strip 11 and the source-region semiconductor strip 13, cooperating with the part of the gate strip 2 as the control gate, are configured to form a memory cell.

Therefore, as shown in FIGS. 1-3, the memory array 1 of the present disclosure is formed with multiple memory cells arranged in an array, and the multiple memory cells is comprised by the drain-region semiconductor strips 11, the channel semiconductor strips 12, the source-region semiconductor strips 13, and the gate strips 2. In particular, the memory array 1 of the present disclosure includes multiple memory subarray layers 1a sequentially stacked along the height direction Z. Each memory subarray layer 1a includes a layer of drain-region semiconductor strips 11, a layer of channel semiconductor strips 12, a layer of source-region semiconductor strips 13, and parts of gate strips 2 matching the above layers, such that each memory subarray layer 1a includes a layer of array-arranged memory cells along the height direction Z, and the stacked multiple memory subarray layers 1a constitute multiple layers of memory cells arrayed along the height direction Z.

In the present disclosure, each drain-region semiconductor strip 11 is a semiconductor strip of a first doping type, such as an N-type doped semiconductor strip. In some embodiments, each drain-region semiconductor strip 11 serves as a bit line (BL) of the memory device.

Each channel semiconductor strip 12 is a semiconductor strip of a second doping type, such as a P-type doped semiconductor strip. In some embodiments, each channel semiconductor strip 12 serves as a well region of a memory cell.

Each source-region semiconductor strip 13 is also a semiconductor strip of the first doping type, such as an N-type doped semiconductor strip. In some embodiments, each source-region semiconductor strip 13 serves as a source line (SL) of the memory device.

Of course, it is understood by those skilled in the art that in other types of memory devices, each drain-region semiconductor strip and each source-region semiconductor strip may also be a P-type doped semiconductor strip, while each channel semiconductor strip 12 is an N-type doped semiconductor strip. The present disclosure does not limit thereto.

Referring further to FIGS. 1-3, in the height direction Z, two adjacent memory subarray layers 1a include a drain-region semiconductor layer, a channel semiconductor layer, a source-region semiconductor layer, a channel semiconductor layer, and a drain-region semiconductor layer stacked in sequence to share the common source-region semiconductor layer. As shown in FIGS. 1-3, the common source-region semiconductor strip 13 is arranged between two adjacent channel semiconductor strips 12 in the height direction Z in the same column, and two drain-region semiconductor strips 11 are arranged on two sides of the two adjacent channel semiconductor strips 12. That is, in the height direction Z, the same semiconductor-strip-structure column 1b of two adjacent memory subarray layers 1a includes the drain-region semiconductor strip 11, the channel semiconductor strip 12, the source-region semiconductor strip 13, the channel semiconductor strip 12, and the drain-region semiconductor strip 11 stacked in sequence, thereby forming two semiconductor strip structures which share the common source-region semiconductor strip 13. In this way, the memory density of the memory device may be further increased while reducing cost and process.

Referring together to FIG. 4, the memory array 1 includes multiple memory subarray layers 1a sequentially stacked along the height direction Z. Each memory subarray layer 1a includes a drain-region semiconductor layer, a channel semiconductor layer, and a source-region semiconductor layer stacked along the height direction Z.

In each memory subarray layer 1a, the drain-region semiconductor layer, the channel semiconductor layer, and the source-region semiconductor layer include multiple drain-region semiconductor strips 11, multiple channel semiconductor strips 12, and multiple source-region semiconductor strips 13, respectively, spaced along the row direction X.

Two adjacent memory subarray layers 1a include a drain-region semiconductor layer, a channel semiconductor layer, a source-region semiconductor layer, a channel semiconductor layer, and a drain-region semiconductor layer sequentially stacked to share the same source-region semiconductor layer.

An interlayer isolation layer is arranged between every two adjacent memory subarray layers 1a and another two adjacent memory subarray layers 1a to isolate every two adjacent memory subarray layers 1a from another two adjacent memory subarray layers 1a. For example, along the height direction Z, one interlayer isolation layer is arranged between a first group consisting of a first memory subarray layer 1a and a second memory subarray layer 1a and a second group consisting of a third memory subarray layer 1a and a fourth memory subarray layer 1a; another interlayer isolation layer is arranged between a third group consisting of the third memory subarray layer 1a and the fourth memory subarray layer 1a and a fourth group consisting of a fifth memory subarray layer 1a and a sixth memory subarray layer 1a, and so on. It is understood that the one interlayer isolation layer is disposed between the second memory subarray layer 1a and the third memory subarray layer 1a; and the other interlayer isolation layer is disposed between the fourth memory subarray layer 1a and the fifth memory subarray layer 1a.

Specifically, as shown in FIG. 4, one interlayer isolation strip 14a is arranged between every two adjacent semiconductor strip structures and another two adjacent semiconductor strip structures in the same semiconductor-strip-structure column 1b in the height direction Z. Similarly, another interlayer isolation strip 14a is arranged between every two adjacent semiconductor strip structures and another two adjacent semiconductor strip structures in another semiconductor-strip-structure column 1b. It is understood by those skilled in the art that multiple interlayer isolation strips 14a in the same horizontal plane constitute an interlayer isolation layer to isolate the semiconductor strip structures in every two adjacent memory subarray layers 1a from the semiconductor strip structures in another two adjacent memory subarray layers 1a.

In other words, in the present disclosure, each stacked structure 1b may include multiple stacked substructure, and each stacked substructure includes a drain-region semiconductor strip 11, a channel semiconductor strip 12, a source-region semiconductor strip 13, a channel semiconductor strip 12, and a drain-region semiconductor strip 11 sequentially stacked along the height direction Z, thereby sharing the same source-region semiconductor strip 13. In the stacked structure 1b, an interlayer isolation strip 14a is arranged between two adjacent stacked substructures to isolate them from each other. That is, in two adjacent memory subarray layers 1a, the drain-region semiconductor strip 11, channel semiconductor strip 12, source-region semiconductor strip 13, channel semiconductor strip 12, and drain-region semiconductor strip 11 in the same column form a stacked substructure, such that two adjacent memory subarray layers 1a share a common source-region semiconductor strip 13.

Referring further to FIG. 4 or FIG. 1, multiple isolation walls 3 are distributed in the memory array 1, and the multiple isolation walls 3 are arranged in a matrix in the row direction X and the column direction Y. As shown in FIG. 1, multiple isolation walls 3 distributed along the column direction Y are arranged on each of two sides of each semiconductor-strip-structure column 1b. Each isolation wall 3 extends along the height direction Z and the row direction X to separate at least parts of two adjacent columns of drain-region semiconductor strips 11, channel semiconductor strips 12, and source-region semiconductor strips 13. That is, the multiple isolation walls 3 distributed along the column direction Y are arranged on each of the two sides of each stacked structure 1b to separate at least parts of the two adjacent columns of stacked structures 1b. In some embodiments, particularly during the manufacturing process of the memory device, the isolation walls 3 may further serve as support structures that may support two adjacent columns of the stacked structures 1b during and/or after the manufacturing process. In addition, a part of each side of each stacked structure 1b may be arranged with support pillars (not shown and described in detail below), respectively, to support the two adjacent columns of the stacked structures 1b during and/or after the manufacturing process of the memory array 1.

A region between two adjacent isolation walls 3 in the same column in the column direction Y is configured to define a word-line hole 4. That is, any two adjacent isolation walls 3 in the same column, cooperating with two semiconductor-strip-structure columns 1b (i.e., stacked structures 1b) on both sides thereof, may define multiple regions for the word-line holes 4, and these regions may be processed such that corresponding word-line holes 4 may be defined. That is, the multiple columns of drain-region semiconductor strips 11, channel semiconductor strips 12, and source-region semiconductor strips 13 extending along the column direction Y pass through the multiple rows of isolation walls 3 extending along the row direction X, to define the multiple word-line holes 4 cooperating with the multiple isolation walls 3. Each word-line hole 4 extends along the height direction Z.

Each word-line hole 4 is configured to fill a gate material to form a corresponding gate strip 2. That is, a gate strip 2 is filled between two adjacent isolation walls 3 in the same column direction Y.

FIG. 5 is a perspective structural schematic view of a memory cell according to an embodiment of the present disclosure. As shown in FIG. 5, the memory cell includes a drain region portion 11′, a channel portion 12′, a source region portion 13′, and a gate portion 2′. The drain region portion 11′, the channel portion 12′, and the source region portion 13′ are stacked along the height direction Z, respectively. The channel portion 12′ is disposed between the drain region portion 11′ and the source region portion 13′. The gate portion 2′ is disposed on a side of the drain region portion 11′, the channel portion 12′, and the source region portion 13′. The drain region portion 11′, the channel portion 12′, and the source region portion 13′ are each a single-crystal semiconductor.

In addition, a projection of the gate portion 2′ at least partially coincides with a projection of the channel portion 12′ on a projection plane in the height direction Z. The projection plane is located on a side of the drain region portion 11′, the channel portion 12′, and the source region portion 13′, and extends along the height direction Z and the column direction Y.

As shown in FIG. 5, it is easily understood by those skilled in the art that the drain region portion 11′ is a part of one of the drain-region semiconductor strips 11 shown in FIGS. 1-4, the channel portion 12′ is a part of one of the channel semiconductor strips 12 shown in FIGS. 1-4, and the source region portion 13′ is a part of one of the source-region semiconductor strips shown in FIGS. 1-4. The gate portion 2′ is a part of one of the gate strips shown in FIGS. 1-4. Therefore, in the height direction Z, the multiple memory subarray layers 1a includes multiple memory cells.

In addition, as shown in FIG. 5, a storage structure portion 5′ is arranged between the gate portion 2′ and the drain region portion 11′, the channel portion 12′, and the source region portion 13′. The storage structure portion 5′ may be configured to store electric charges; the gate portion 2′, the drain region portion 11′, the channel portion 12′, the source region portion 13′, and the storage structure portion 5′ sandwiched between the gate portion 2′ and the channel portion 12′, constitutes a memory cell. The memory cell may indicate logical data 1 or logical data 0 by a state of storing or not storing electric charges in the storage structure portion 5′, thereby enabling storage of data. The storage structure portion 5′ may include a charge trapping storage structure portion, a floating gate storage structure portion, or other types of capacitive storage structure portions.

Therefore, it will be understood by those skilled in the art that in the memory array 1 shown in FIGS. 1-4, a storage structure 5 is also arranged between the gate strip 2 and the drain-region semiconductor strip 11, the channel semiconductor strip 12, and the source-region semiconductor strip 13, such that each memory cell can store electric charges by the corresponding storage structure portion 5′.

In addition, it should be noted that for the convenience of the accompanying drawings showing the storage structure portion 5′, the drain region portion 11′, the channel portion 12′, the source region portion 13′, the gate portion 2′, and the storage structure portion 5′ shown in FIG. 5 are shown for illustrative purposes only and do not represent actual dimensions or proportions.

It will be understood by those skilled in the art that, as above, the part of the gate strip 2 whose projection coincides with the projection of the adjacent channel semiconductor strip 12 on the above projection plane is configured as the control gate of the memory cell, such that the part of the gate strip 2 as the gate portion 2′ is the part whose projection coincides with the projection of the channel semiconductor strip 12 on the projection plane; the part of the channel semiconductor strip 12 whose projection coincides with the projection of the gate strip 2 on the above projection plane is the corresponding part of the channel semiconductor strip 12 as the well region, such that the part of the channel semiconductor strip 12 as the channel portion 12′ is the part of the channel semiconductor strip 12 whose projection coincides with the projection of the gate strip 2 on the projection plane; the parts of the drain-region semiconductor strip 11 and the source-region semiconductor strip 13 as the drain region portion 11′ and the source region portion 13′, i.e., the part of the drain-region semiconductor strip 11 or the source-region semiconductor strip 13 arranged above or below the channel portion 12′, are configured as the semiconductor drain region and the semiconductor source region, respectively.

Similarly, the storage structure portion 5′ is a part of the storage structure 5 disposed between the channel portion 12′ and the gate portion 2′.

Referring further to FIGS. 1-4, a gate strip 2 is flanked by two adjacent columns of drain-region semiconductor strips 11, channel semiconductor strips 12, and source-region semiconductor strips 13. Therefore, these two adjacent columns of drain-region semiconductor strips 11, channel semiconductor strips 12, and source-region semiconductor strips 13 share the same gate strip 2. That is, for a gate strip 2, in a memory subarray layer 1a, the gate strip cooperates with corresponding parts of the drain-region semiconductor strip 11, channel semiconductor strip 12, and source-region semiconductor strip 13 on the left side of the gate strip 2 to form a memory cell, and cooperates with corresponding parts of the drain-region semiconductor strip 11, channel semiconductor strip 12, and source-region semiconductor strip 13 on the right side of the gate strip 2 to form another memory cell. In other words, in a same row, two gate strips 2 are arranged on the left and right sides of one column of drain-region semiconductor strip 11, channel semiconductor strip 12, and source-region semiconductor strip 13 in one memory subarray layer 1a. In this way, the one column of drain-region semiconductor strip 11, channel semiconductor strip 12, and source-region semiconductor strip 13 cooperates with a part of the gate strip 2 on the left side to constitute a memory cell, and cooperates with a part of the gate strip 2 on the right side to constitute another memory cell. That is, in the same row, a column of drain-region semiconductor strip 11, channel semiconductor strip 12, and source-region semiconductor strip 13 in one memory subarray layer 1a is shared by two gate strips 2 on its left and right sides.

Specifically, further referring to FIG. 6, FIG. 6 is a perspective schematic view of a structure in which two memory cells share the same column of drain-region semiconductor strip, channel semiconductor strip, and source-region semiconductor strip. As shown in FIG. 6, the source region portion 13′, channel portion 12′, and drain region portion 11′ stacked along the height direction Z′ cooperate with the gate portion 2′ on the left side and the storage structure portion 5′ between them to constitute a memory cell; similarly, the drain region portion 11′, the channel portion 12′, and the source region portion 13′ cooperate with the gate portion 2′ on the right side and the storage structure portion 5′ between them to constitute another memory cell. In this way, both the two memory cells share the same drain region portion 11′, channel portion 12′, and the source region portion 13′.

For ease of understanding, it may be considered that the drain region portion 11′, the channel portion 12′, and the source region portion 13′ cooperate with the gate portion 2′ on the left side and the storage structure portion 5′ between them to form a memory cell (bit); the drain region portion 11′, the channel portion 12′, and the source region portion 13′ cooperate with the gate portion 2′ on the right side and the storage structure portion 5′ between them to form another memory cell (bit).

Therefore, returning to FIGS. 1-4, it will be understood by those skilled in the art that a storage structure 5 is first arranged on each of the left and right sides in each word-line hole 4, and the gate material is filled in the word-line hole 4 to form the gate strip 2. That is, the two adjacent columns of drain-region semiconductor strips 11, channel semiconductor strips 12, and source-region semiconductor strips 13 in conjunction with the storage structures 5 share the same gate strip 2.

In conjunction with FIGS. 1-3 and 5-6, in some embodiments, each of the above drain-region semiconductor strip 11, channel semiconductor strip 12, and source-region semiconductor strip 13 is a standard strip structure. That is, each drain-region semiconductor strip 11, channel semiconductor strip 12, and source-region semiconductor strip 13 has a standard rectangular cross-section at each position along the respective extension direction. The memory cell corresponding to the embodiments may be illustrated specifically in FIGS. 5 and 6.

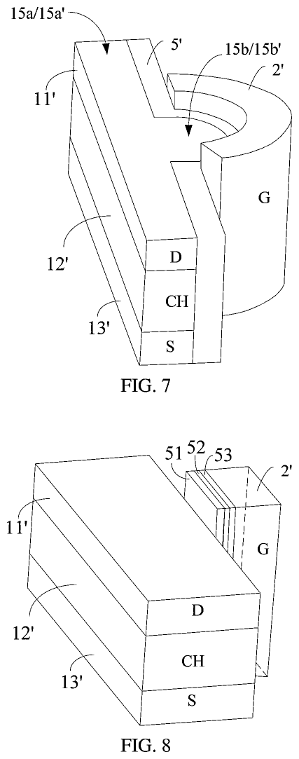

In other embodiments, in conjunction with FIG. 4 and FIG. 7, FIG. 7 is a perspective structural schematic view of a memory cell according to another embodiment of the present disclosure. Each drain-region semiconductor strip 11, channel semiconductor strip 12, and source-region semiconductor strip 13 includes a body structure 15a and multiple protrusions 15b, respectively. The body structure 15a extends along the column direction Y and is in the shape of a strip. The multiple protrusions 15b are distributed on both sides of the body structure in two columns, and each column includes multiple protrusions 15b spaced apart, each protrusion 15b extending from the body structure 15a in the row direction X toward a corresponding gate strip 2 (word-line hole 4) in a direction deviating from the body structure 15a. In other words, in each column of drain-region semiconductor strips 11, channel semiconductor strips 12, and source-region semiconductor strips 13, two columns of protrusions 15b extend from the strip-shaped body structure 15a toward the gate strips 2 (word-line holes 4) on each side. Therefore, it is understood by those skilled in the art that a surface of the storage structure 5 formed in the word-line hole 4 and a surface of the gate strip 2 near the drain-region semiconductor strip 11, the channel semiconductor strip 12, and the source-region semiconductor strip 13 are curved concave surfaces.

As shown in FIG. 7, for each memory cell, the drain region portion 11′, the channel portion 12′, and the source region portion 13′ include a body portion 15a′ and a protrusion portion 15b′, and each of the storage structure portion 5′ and the gate portion 2′ includes a concave surface corresponding to the protrusion portion 15b′ to wrap a surface of the protrusion 15b away from the body structure 15a.

In the present disclosure, by making each drain-region semiconductor strip 11, channel semiconductor strip 12, and source-region semiconductor strip 13 include multiple protrusions 15b that are raised toward the two sides, it is possible to increase the surface area of each drain-region semiconductor strip 11, channel semiconductor strip 12, and source-region semiconductor strip 13, thereby increasing the area of a corresponding region of the channel portion 12′ and the gate portion 2′ in each memory cell, thereby enhancing the performance of the memory device.

Specifically, the convex surface of the protrusion 15b away from the body structure 15a may be an arc or other form of convex surface, where the arc may include a columnar semicircular surface. The protrusions 15b of each column of drain-region semiconductor strip 11, channel semiconductor strip 12, and source-region semiconductor strip 13 form a columnar semicircle. The gate strip 2 corresponding to the protrusions 15b is arranged with a concave surface toward the drain-region semiconductor strip 11, the channel semiconductor strip 12, and the source-region semiconductor strip 13, and the concave surface is a curved surface corresponding to the convex surface of the protrusions 15b to ensure that the gate strip 2 matches the channel semiconductor strip 12 at the corresponding position.

In some embodiments, as shown in FIG. 4, the storage structure 5 extends inside the word-line hole 4 in the height direction Z and is arranged between the gate strip 2 and the adjacent drain-region semiconductor strip 11, the channel semiconductor strip 12, and the source-region semiconductor strip 13, such that the storage structures 5 may form the multiple memory cells together with the parts of the drain-region semiconductor strips 11, the channel semiconductor strips 12, and the source-region semiconductor strips 13 at corresponding positions. In the present disclosure, the storage structure 5 may be a charge trapping storage structure, a floating gate storage structure, or other types of capacitive dielectric structures.

FIG. 8 is a perspective structural schematic view of a memory cell according to further another embodiment of the present disclosure. In the embodiments, the storage structure 5 is a charge trapping storage structure. As shown in FIG. 8, the storage structure portion 5′ of the memory cell includes a first dielectric portion 51, a charge storage portion 52, and a second dielectric portion 53. The first dielectric portion 51 is disposed between the charge storage portion 52 and the stacked drain region portion 11′, the channel portion 12′, and the source region portion 13′; the charge storage portion 52 is disposed between the first dielectric portion 51 and the second dielectric portion 53; and the second dielectric portion 53 is disposed between the charge storage portion 52 and the gate portion 2′. The charge storage portion 52 is configured to store electrical charges to enable the memory cell to store data.

Therefore, with reference to FIG. 8, it will be understood by those skilled in the art that the storage structure 5 in the memory array shown in FIGS. 1-4 of the present disclosure includes a first dielectric layer, a charge storage layer, and a second dielectric layer, the first dielectric layer being disposed between the charge storage layer and the drain-region semiconductor strip 11, the channel semiconductor strip 12, and the source-region semiconductor strip 13, the charge storage layer being disposed between the first dielectric layer and the second dielectric layer, and the second dielectric layer being disposed between the charge storage layer and the gate strip 2.

The first dielectric layer (first dielectric portion 51) and the second dielectric layer (second dielectric portion 53) may be made of an insulating material, such as silicon oxide. The charge storage layer (charge storage portion 52) may be made of a storage material with charge trapping properties, in particular, the charge storage layer may be made of silicon nitride. Therefore, the first dielectric layer (first dielectric portion 51), the charge storage layer (charge storage portion 52), and the second dielectric layer (second dielectric portion 53) form an ONO storage structure. Specifically, reference thereto may be made to a manufacturing method of a memory device involving a charge trapping storage structure in the following embodiments.

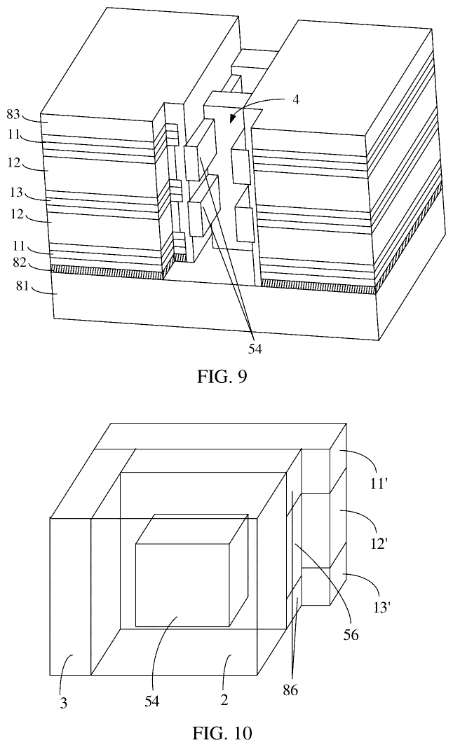

FIG. 9 is a perspective schematic view of a partial structure of a memory device according to another embodiment of the present disclosure. In the embodiments, the storage structure 5 is a floating gate storage structure, and the floating gate storage structure extends at least partially within the word-line hole 4 in the height direction Z and is arranged between the gate strip 2 and the drain-region semiconductor strip 11, the channel semiconductor strip 12, and the source-region semiconductor strip 13.

Specifically, in conjunction with FIG. 9, FIG. 10 is a perspective structural schematic view of a memory cell according to further another embodiment of the present disclosure. For each memory cell, the floating gate storage structure includes multiple floating gates 54 and an insulation dielectric wrapping each floating gate 54. As shown in FIG. 9, as can be seen through the word-line hole 4, the multiple floating gates 54 are spaced along the height direction Z, and each floating gate 54 is arranged on a side of the channel semiconductor strip 12 along the row direction X and faces a corresponding part of the channel semiconductor strip 12. As shown in FIG. 10, the insulation dielectric wrapping the floating gate 54 includes a first insulation dielectric layer 56 between the channel semiconductor strip 12 and the floating gate 54 (referring also to the first insulation dielectric layer 85a shown in FIG. 41 below), and a second insulation dielectric layer covering several other faces of the floating gate 54 (not shown in FIG. 10, referring to the second insulation dielectric layer 85b shown in FIG. 41 below). That is, the insulation dielectric is present between the floating gate 54 and the corresponding part of the channel semiconductor strip 12, between two adjacent floating gates 54, and between the floating gate 54 and the gate strip 2. The insulation dielectric wraps every surface of the floating gate 54 to completely isolate the floating gate 54 from the rest of the structure.

Among them, the floating gate 54 may be made of polycrystalline silicon. The insulation dielectric may be made of an insulating material such as silicon oxide. Specifically, reference thereto may be made to a manufacturing method of a memory device involving a floating gate storage structure in the following embodiments.

In the memory cell of the charge trapping storage structure shown in FIG. 8 and FIGS. 1-4, the storage structure 5 is adopted with a first dielectric layer (first dielectric portion 51), a charge storage layer (charge storage portion 52), and a second dielectric layer (second dielectric portion 53) to form an ONO storage structure.

The ONO storage structure is characterized by the fact that the charges injected into can be fixed near an injection point, while the floating gate storage structure (e.g., FIGS. 9-11 is adopted with polysilicon as a floating gate) is characterized by the fact that the charges injected into can be uniformly distributed in over the entire floating gate 54. In other words, in the ONO storage structure, the charges can only move in the injection/removal direction, i.e., the stored charges can only be fixed near the injection point and cannot move arbitrarily in the charge storage layer, especially cannot move in the extension direction of the charge storage layer. Therefore, for the ONO storage structure, the charge storage layer only needs to have an insulation dielectric on its front and back side, and the charges stored in each memory cell will be fixed near the injection point of the charge storage portion 52 and will not move along the same layer of the charge storage layer to the charge storage portion 52 in another memory cell. While in the floating gate storage structure, the charge can not only move in the injection/removal direction, but also can move arbitrarily in the floating gate 54. Therefore, when the floating gate 54 is a continuous structure, the stored charges can move in the direction of extension of the floating gate 54 and thus move to the floating gate 54 in another memory cell. Therefore, for the floating gate storage structure, the floating gates 54 of each memory cell are independent, and each surface of each floating gate needs to be covered by an insulation dielectric, and need to be isolated from each other, to prevent the charges stored in the floating gates 54 in one memory cell from moving to the floating gates 54 in the other memory cells.

That is, for the memory cell and memory device with the charge trapping storage structure shown in FIGS. 8 and 1-4, the storage structure 5 may extend from top to bottom in the word-line hole 4, and it is sufficient to arrange a first dielectric layer and a second dielectric layer on both sides of the charge storage layer, respectively.

In contrast, in the floating gate storage structure shown in FIGS. 9-11, the floating gates 54 of each memory cell are independent, and each surface of each floating gate 54 needs to be covered by an insulation dielectric, and need to be isolated from each other, to prevent the charges stored in the floating gates 54 in one memory cell from moving to the floating gates in other memory cells.

It will be understood by those skilled in the art that some parts of the insulation dielectric (e.g., the second insulation dielectric layer 85b mentioned above) are interconnected with each other, as long as it is possible to ensure that the floating gates 54 of each memory cell are independent of each other and that the surfaces of each floating gate 54 are wrapped with the insulation dielectric. Therefore, parts of the insulation dielectric (e.g., the second insulation dielectric layer 85b mentioned above) that wraps the floating gates 54 in the word-line hole 4 may extend substantially in the height direction, thereby wrapping the floating gates 54 of each memory cell. Specifically, reference to the memory device with a floating gate storage structure may be made to a manufacturing method of a memory device involving a floating gate storage structure in the following embodiments.

In addition, it will be understood by those skilled in the art that the storage structure 5 may be adopted with other types of storage structures, such as ferroelectric, variable resistance, or other types of capacitive storage structures.

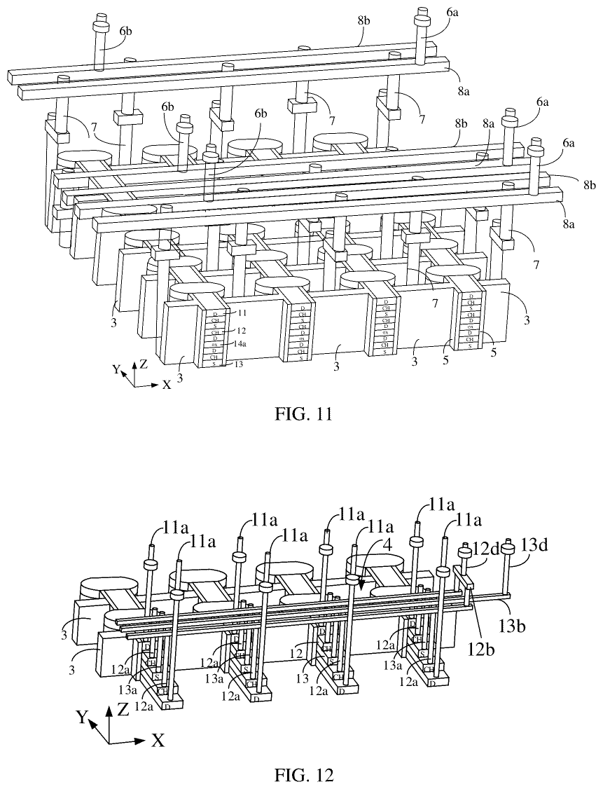

FIG. 11 is a perspective structural schematic view of a memory device according to further another embodiment of the present disclosure. In FIG. 11, only three layers of memory subarray layers 1a are shown, which are merely schematic, and it will be understood by those skilled in the art that the memory device includes multiple layers of memory subarray layers 1a, and every two adjacent memory subarray layers 1a is isolated from another two adjacent memory subarray layers by an interlayer isolation layer (formed by multiple interlayer isolation strips 14a). The memory device further includes multiple word lines (WL) and multiple word line connection lines 7.

As above, the part of the gate strip 2 whose projection overlaps with the projection of the channel semiconductor strip 12 in an adjacent stacked structures 1b on the above projection plane is configured as the control gate of the corresponding memory cell. Therefore, each gate strip 2 is configured to form the control gate (CG) of multiple memory cells. As is known, the control gates of a row of memory cells need to be connected to a corresponding word line, through which a voltage is applied to the control gates of the row of the memory cells, thereby controlling the memory cells to perform various memory operations.

In the present disclosure, as shown in FIG. 11, multiple word lines are arranged on top of multiple memory subarray layers 1a and are spaced apart in the column direction Y, with each word line extending along the row direction X. Each word line is connected to multiple word line connection lines 7. The multiple word line connection lines 7 connected to the same word line extend along the height direction Z, respectively, and extend to the gate strips 2 in the multiple word-line holes 4 in the same row, respectively, to be connected to the gate strips 2 in the corresponding word-line holes 4, thereby realizing the connection of the word line to the control gates of the multiple memory cells in the same row of the multiple memory subarray layers 1a. It can be understood that the multiple word-line holes 4 and the multiple word line connection lines 7 are arranged in a one-to-one correspondence.

Specifically, the word line of the same row may be an individual word line connected to the gate strip 2 in each word-line hole 4 of the same row. Of course, the word line of the same row may include multiple different types of word lines; the gate strips 2 in multiple word-line holes 4 of the same row may each be connected to the multiple different types of word lines of the corresponding row. In some embodiments, as shown in FIG. 11, multiple gate strips 2 in the same row are configured to be connected to two corresponding word lines, i.e., each row of word lines include an odd word line 8a and an even word line 8b. It should be noted that one odd word line 8a and one even word line 8b connected to the multiple gate strips 2 of the same row in the present disclosure are defined as one row of word line corresponding to one row of gate strips 2.

Specifically, a part of the memory cells of the same row in the multiple memory subarray layers 1a are connected to the odd word line 8a of the corresponding row through the odd word-line holes 4 of the same row, respectively; the others of the memory cells of the same row in the multiple memory subarray layers 1a are connected to the even word line 8b of the corresponding row through the even word-line holes 4 of the same row, respectively. For example, a first part of the memory cells of the first row are connected to the odd word line 8a of the first row through the first word-line hole 4, the third word-line hole 4, the fifth word-line hole 4 . . . respectively; a second part of the memory cells of the first row are connected to the even word line 8b of the first row through the second word-line hole 4, the fourth word-line hole 4, the sixth word-line hole 4 . . . , respectively. That is, the odd word line 8a of the word line of the same row is connected to multiple memory cells (the first part of the memory cells) in the multiple memory subarray layers 1a corresponding to the odd word-line holes 4 of this row; the even word line 8b of the word line of the same row are connected to multiple memory cells (the second part of the memory cells) in the multiple memory subarray layers 1a corresponding to the even word-line holes 4 of this row.

As above, each drain-region semiconductor strip 11, channel semiconductor strip 12, and source-region semiconductor strip 13 has odd word-line holes 4 distributed on one side thereof and even word-line holes 4 distributed on the other side thereof. Therefore, a part of the drain-region semiconductor strip 11, channel semiconductor strip 12, and source-region semiconductor strip 13 in each same column in each memory subarray layer 1a may cooperate with an odd number gate strip 2 in an odd word-line hole 4 on one side thereof and a storage structure 5 arranged between the gate strip 2 and the drain-region semiconductor strip 11, channel semiconductor strip 12, and source-region semiconductor strip 13, to form a memory cell, i.e., a first memory cell; and may cooperated with an even word-line hole 4 on the other side thereof and a storage structure 5 arranged therebetween, to form another memory cell, i.e., a second memory cell.

In other words, the gate strip 2 filled in each word-line hole 4 may be configured to form a memory cell (bit) in conjunction with the drain-region semiconductor strip 11, the channel semiconductor strip 12, the source-region semiconductor strip 13, and the storage structure 5 on the left side in each memory subarray layer 1a; and may be configured to form another memory cell (bit), i.e., a second memory cell, in conjunction with the drain-region semiconductor strip 11, the channel semiconductor strip 12, the source-region semiconductor strip 13, and the storage structure 5 on the right side in each memory subarray layer 1a.

Therefore, for an odd word-line hole 4, the left half or right half of each drain-region semiconductor strip 11, channel semiconductor strip 12, and source-region semiconductor strip 13 in the same column in each memory subarray layer 1a may cooperate with the corresponding gate strip 2 in the odd word-line hole 4 to form a first memory cell. Specifically, in each memory subarray layer 1a, for example, word-line holes 4 on the left side of the first column of drain-region semiconductor strip 11, channel semiconductor strip 12, and source-region semiconductor strip 13 counting from left to right are odd word-line holes, and a part of the drain-region semiconductor strip 11, channel semiconductor strip 12, and source-region semiconductor strip 13 of that column cooperate with a gate strip 2 in a corresponding odd word-line hole 4 on its left side for forming a first memory cell. Word-line holes 4 on the right side of the second column of the drain-region semiconductor strip 11, channel semiconductor strip 12, and source-region semiconductor strip 13 counting from left to right are odd word-line holes, and a part of the drain-region semiconductor strip 11, channel semiconductor strip 12, and source-region semiconductor strip 13 of this column cooperate with a gate strip 2 in a corresponding odd word-line hole 4 on its right side also for constituting a first memory cell.

Similarly, for an even word-line hole 4, the other half of each drain-region semiconductor strip 11, channel semiconductor strip 12, and source-region semiconductor strip 13 in the same column in each memory subarray layer 1a may cooperate with a corresponding gate strip 2 in the even word-line hole 4 to form a second memory cell. Specifically, in each memory subarray layer 1a, for each column of drain-region semiconductor strip 11, channel semiconductor strip 12, and source-region semiconductor strip 13: for example, word-line holes 4 on the right side of the first column of drain-region semiconductor strip 11, channel semiconductor strip 12, and source-region semiconductor strip 13 from left to right are even word-line holes, and a part of the drain-region semiconductor strip 11, channel semiconductor strip 12, and source-region semiconductor strip 13 of that column cooperate with a gate strip 2 in a corresponding even word-line hole 4 on its right side for forming a second memory cell. Word-line holes 4 on the left side of the second column of the drain-region semiconductor strip 11, channel semiconductor strip 12, and source-region semiconductor strip 13 from left to right are even word-line holes, and a part of the drain-region semiconductor strip 11, channel semiconductor strip 12, and source-region semiconductor strip 13 of this column cooperate with a gate strip 2 in a corresponding even word-line hole 4 on its left side also for forming a second memory cell.

Therefore, in the present disclosure, each gate strip 2 in the memory array 1 is connected to a corresponding word line, and the gate strips 2 in the same row are connected to the corresponding row of word line. The gate strips 2 in the odd word-line holes 4 in the same row are connected to the odd word lines 8a in the corresponding row of word line, and the gate strips 2 in the even word-line holes 4 in the same row are connected to the even word line 8b in the corresponding row of word line. In other words, all the first memory cells of the same row in the multiple memory subarray layers 1a are each connected to an odd word line 8a of the corresponding row through odd number gate strips 2 in odd word-line holes 4 of the same row, and all the second memory cells of the same row in the multiple memory subarray layers 1a are each connected to an even word line 8a of the corresponding row through even number gate strips 2 in even word-line holes 4 of the same row.

Of course, in other embodiments, it may be, in the same row, every adjacent three, four or five word-line holes 4, etc. are configured as a group, then each line word line includes three, four, five, etc. different types of word lines, and the gate strip 2 in each word-line hole 4 in each group is connected to a different type of word line.

Furthermore, as shown in FIG. 11, in the present disclosure, the number of rows of word lines may be defined to be the same as the number of rows of word-line holes 4. That is, as shown in FIG. 11, although the gate strips 2 in the word-line holes 4 of the same row are connected to a corresponding odd word line 8a and a corresponding even word line 8b, one odd word line 8a and one even word line 8b corresponding to the word-line holes 4 of the same row may be defined as one row of word lines corresponding to the row of gate strips 2 (word-line holes 4). That is, each row of word line includes one odd word line 8a and one even word line 8b, and the number of rows of word lines is the same as the number of rows of the word-line holes 4. It should also be noted that, as shown in FIG. 11, in each row, each of the left side and right side of a word-line hole 4 not disposed on ends of the memory array correspond to a column of drain-region semiconductor strips 11, channel semiconductor strips 12, and source-region semiconductor strips 13. However, from left to right, for a word-line hole 4 disposed on a left terminal of the memory array (first terminal), only the right side of the word-line hole 4 corresponds to a column of drain-region semiconductor strips 11, channel semiconductor strips 12, and source-region semiconductor strips 13; for a word-line hole 4 disposed on a right terminal of the memory array (last terminal), only the left side of the word-line hole 4 corresponds to a column of drain-region semiconductor strips 11, channel semiconductor strips 12, and source-region semiconductor strips 13. Therefore, it is understood by those skilled in the art that in each row, the word-line hole 4 at the first terminal and the word-line hole 4 at the last terminal functionally constitute a complete word-line hole.

As shown in FIG. 11, in the embodiments, multiple word lines may be arranged above the multiple memory subarray layers 1a in the memory device, each of which is connected to corresponding word-line holes 4 through word line connection lines 7.

Of course, it is understood by those skilled in the art that multiple word lines may be arranged on another stacked chip, and the stacked chip may be stacked with and electrically connected to a chip in which the memory device is located. For example, the stacked chip may be stacked with the chip in which the device is located by hybrid bonding. A terminal of each word line connection line 7 in the memory device away from the corresponding gate strip 2 serves as a word line connection terminal of the device for connecting to the stacked chip stacked together in the height direction Z of the memory device.

In addition, as shown in FIG. 11, in another embodiment, the memory device may further include multiple word line lead-out lines 6a or 6b, each word line further corresponding to a word line lead-out line 6a or 6b, respectively, with the word line lead-out line 6a or 6b extending in the height direction Z and away from the gate strips 2 with respect to the word line connection lines 7. A terminal of the word line lead-out line 6a or 6b away from the word line is configured as a word line connection terminal for connection to the stacked chip stacked together in the height direction Z of the memory device. That is, the word lines are arranged on the memory array chip and the control circuit is arranged on the other chip. Of course, those skilled in the art can understand that each word line may be connected to the control circuit on the chip on which the memory device is located through a corresponding word line lead-out line 6a or 6b, i.e., the relevant lines, memory array, and control circuit are arranged on the same chip.

FIG. 12 is a structural schematic view of a circuit connection of part of memory cells of a memory device according to an embodiment of the present disclosure. As shown in FIG. 12, for each column of drain-region semiconductor strips 11, channel semiconductor strips 12, and source-region semiconductor strips 13 of the multiple memory subarray layers 1a: the multiple drain-region semiconductor strips 11 in the same column are led out through different bit line connection lines 11a arranged on an end of each drain-region semiconductor strip 11, the bit line connection lines 11a extending along in the height direction Z as shown in FIG. 12. For example, for the drain-region semiconductor strips 11, the channel semiconductor strips 12, and the source-region semiconductor strips 13 in the first column, the drain-region semiconductor strip 11 in the first memory subarray layer 1a is led out at its terminal by a bit line connection line 11a, where an terminal of the bit line connection line 11a away from the drain-region semiconductor strip 11 may be configured as a bit line connection terminal; the drain-region semiconductor strip 11 in the second memory subarray layer 1a is led out at its terminal by another bit line connection line 11a, and an terminal of the another bit line connection line 11a away from the corresponding drain-region semiconductor strip 11 is configured as another bit line connection terminal, and so on. Therefore, each drain-region semiconductor strip 11 may serve as a bit line and receive a bit line voltage through the each bit line connection terminal.

It will be understood by those skilled in the art that the memory device may be connected to another stacked chip stacked together in the height direction Z of the memory device 10 through the bit line connection terminal, and provide a bit line voltage to each drain-region semiconductor strip 11 in the memory device as a bit line through the bit line connection terminal by means of another stacked chip. Of course, the bit line connection terminal may be further configured to be connected to the control circuit on the chip where the memory device is located, i.e., the relevant lines, the memory array 1, and the control circuit are arranged on the same chip.

Similarly, for each column of drain-region semiconductor strips 11, channel semiconductor strips 12, and source-region semiconductor strips 13 of the multiple memory subarray layers 1a, the multiple source-region semiconductor strips 13 in the same column are led out through different source line connection lines 13a disposed on a terminal of each source-region semiconductor strip, and the source connection lines 13a extend along the height direction Z.

As shown in FIG. 12, all of the source connection lines 13a in the memory device may be connected to the same common source line 13b, respectively, and a source voltage is applied to the source-region semiconductor strips 13 in the memory device through the common source line 13b and the source connection lines 13a.

Of course, it is understood by those skilled in the art that in other embodiments, the memory device may include multiple common source lines 13b, such as a predetermined number of the multiple common source lines 13b, and the source-region semiconductor strips 13 in the multiple memory subarray layers 1a may be connected to different multiple common source lines 13b via corresponding source connection lines 13a according to a predetermined rule. In addition, also similar to the bit line connection line 11a corresponding to the drain semiconductor strip 11, a terminal of the source connection line 13a corresponding to each source semiconductor strip 13 away from the source semiconductor strip 13 may be configured as a source connection terminal to receive the source voltage.

Referring further to FIG. 12, the memory device may further include a common source lead-out line 13d connected to the common source line 13b, where the common source line 13b is connected to all source connection lines 13a in the memory device. The common source lead-out line 13d extends away from the memory array 1 in the memory device and in the height direction Z. A terminal of the common source lead-out line 13d away from the common source line 13b may be configured as a common source connection terminal for connecting to another stacked chip stacked together in the height direction Z in the memory device. Of course, the common source connection terminal may further be configured to connect to the control circuit on the chip on which the memory device is located, i.e., the relevant lines, the memory array, and the control circuit are arranged on the same chip.

Of course, it can be understood by those skilled in the art that the common source line 13b may be arranged in another stacked chip stacked with the memory device in the height direction Z. That is, a terminal of the source connection line 13a away from the corresponding source-region semiconductor strip 13 may be configured as a source connection terminal for connection with another stacked chip stacked with the memory device in the height direction Z, such that the common source line 13b are arranged in another stacked chip.

As above, for each column of drain-region semiconductor strips 11, channel semiconductor strips 12, and source-region semiconductor strips 13 of the multiple memory subarray layers 1a, the multiple channel region semiconductor strips 12 in the same column are led out through different well region connection lines 12a disposed on a terminal of each channel semiconductor strip 12, and the well region connection lines 12a extends along the height direction Z.

As shown in FIG. 12, all of the well region connection lines 12a in the memory device are each connected to the same common well-region line 12b, thereby uniformly applying a well region voltage to all the channel semiconductor strips 12 in the memory device through the common well-region line 12b.

Of course, it will be understood by those skilled in the art that the corresponding well region connection line 12a of each channel semiconductor strip 12 in the memory device may be connected to multiple separate well voltage lines 12b to apply a well voltage to each channel semiconductor strip 12 separately. For example, similar to the above, a terminal of the well region connection line 12a corresponding to each channel semiconductor strip 12 away from the channel semiconductor strip 12 serves as a well connection terminal which is configured to receive a separate well voltage.

Referring further to FIG. 12, all of the well region connection lines 12a in the memory device are each connected to the same common well-region line 12b; the memory device may further include a common well region lead-out line 12d connected to the common well-region line 12b, with the common well region lead-out line 12d extending away from the memory array 1 in the memory device and along the height direction Z. A terminal of the common well region lead-out line 12d away from the common well-region line 12b may be configured as a common well region connection terminal for connection to another stacked chip stacked with the memory device in the height direction Z. Of course, the common well region connection terminal may further be configured for connection to the control circuit on the chip on which the memory device is located, i.e., the associated lines, the memory array 1, and the control circuit are arranged on the same chip. That is, through the common well-region line 12b it is possible to connect all the channel semiconductor strips 12 in the memory device together to receive the same well voltage. In the embodiments, the channel semiconductor strip 12 may be a p-type semiconductor strip forming a p-well, and all the channel semiconductor strips 12 in the memory device are connected together through the common well-region line 12b, receiving the same well voltage through the common well-region line 12b. In addition, in the embodiments, the memory device may read signals through the same common source line 13b.

Of course, it will be understood by those skilled in the art that the common well-region line 12b may be arranged in another stacked chip stacked together with the memory device in the height direction Z. That is, a terminal of the well region connection line 12a away from the corresponding channel semiconductor strip 12 may be configured as a well region connection terminal for connection to another stacked chip stacked together with the memory device in the height direction Z, thereby arranging the common well-region line 12b in another stacked chip.

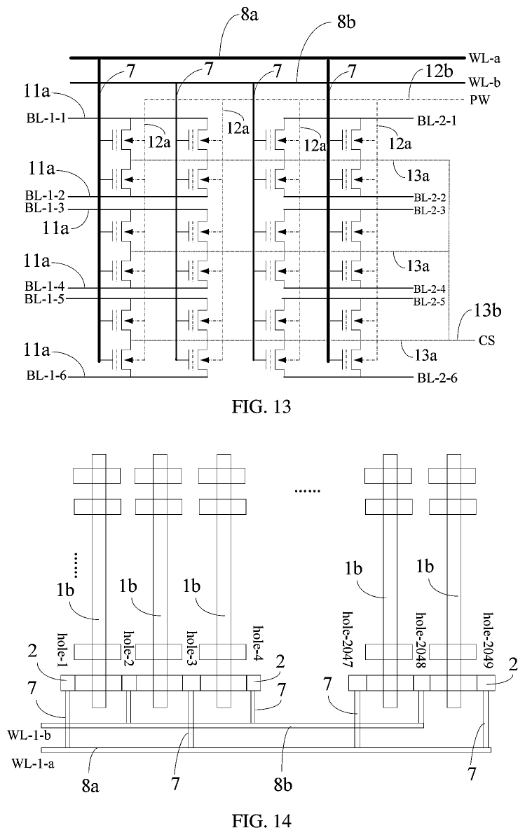

In some embodiments, it is noted that, as shown in FIGS. 11 and 13, in the present disclosure, connecting wires, such as word line 8a or 8b, word line connection line 7, word line lead-out line 6a or 6b, common source line 13b, common well-region line 12b, etc. are arranged in the memory device, especially on a same side of the memory array 1 in the memory device, i.e., arranged above the memory array 1. Therefore, it may be ensured that the drain-region semiconductor strips 11, the channel semiconductor strips 12, and the source-region semiconductor strips 13 in the memory array 1 may be each formed as single-crystal semiconductor strips by epitaxial growth, while only polycrystalline semiconductor strips can be formed by the deposition method. Compared to polycrystalline semiconductor strips formed by deposition, the drain-region semiconductor strips 11, channel semiconductor strips 12, and source-region semiconductor strips 13 formed by epitaxial growth of the present disclosure may have better device performance and greatly improve the related performance of the memory device. Specifically, when comparing the memory cell adopted with a single-crystal semiconductor (single-crystal drain-region semiconductor strip 11, channel semiconductor strip 12, and source-region semiconductor strip 13) to the memory cell adopted with a polycrystalline semiconductor, the memory cell with the polycrystalline semiconductor has more interfaces, along which electrons move when passing through the polycrystalline semiconductor, i.e., the distance of electron movement increases and the current decreases significantly. According to a practical empirical test, the current of the memory cell with a polycrystalline semiconductor is only 1/10 of the current of the memory cell with a single-crystal semiconductor. Therefore, the memory device of the present disclosure, with the memory cell with a single-crystal semiconductor, may greatly improve the performance of the memory device. In addition, the low current of the memory cell with the polycrystalline semiconductor affects the read window between the read/write operation (PGM) and the erase operation (ERS) of the memory cell, which has a great impact on the reliability of the memory device, especially for the NOR memory device. In addition, for NOR memory devices, when a hot carrier injection (HCl) method is applied for read/write operations, a single-crystal semiconductor must be adopted to accomplish this.

In addition, since the connecting wires in the present disclosure are arranged on the same side of the memory array 1 in the memory device, it is more convenient to perform the bonding stacking process in three dimensions with the stacked chips, thereby improving the related performance of the memory device, and manufacturing the chips separately is conducive to optimizing the process and reducing the manufacturing time.

It can be understood by those skilled in the art that in some embodiments, in order for the memory device to obtain better performance, the outermost memory cell may generally serve as a virtual memory cell (dummy cell) and does not perform actual storage works. For example, the memory cells included in the lowermost memory subarray layer 1a may be configured as virtual memory cells. In addition, in some embodiments, the leftmost and rightmost columns of the memory device are each arranged with a column of drain-region semiconductor strips 11, channel semiconductor strips 12, and source-region semiconductor strips 13, respectively. The memory cells formed by the leftmost column of the drain-region semiconductor strips 11, the channel semiconductor strips 12, and the source-region semiconductor strips 13, together with the gate strips 2 in the word-line holes 4 on the right side and the storage structures 5 between them, and the memory cells formed by the rightmost column of drain-region semiconductor strips 11, channel semiconductor strips 12 and source-region semiconductor strips 13, together with the gate strips 2 in the word-line hole 4 on the left side and the storage structures 5 between them, are also taken as virtual memory cells not participating in the actual storage work.

Therefore, in the present disclosure, unless intentionally pointed out, the memory subarray layers 1a in the entire specification do not include the lowermost memory subarray layer involved in the virtual memory cells (dummy cells); nor do the drain-region semiconductor strips 11, the channel semiconductor strips 12, and the source-region semiconductor strips 13 include the leftmost column of drain-region semiconductor strips 11, channel semiconductor strips 12, and source-region semiconductor strips 13, and the rightmost column of drain-region semiconductor strips 11, channel semiconductor strips 12, and source-region semiconductor strips 13, involved in the virtual memory cells (dummy cells).

Therefore, as above, in a same row, from left to right, the first word-line hole 4 only corresponds to a column of drain-region semiconductor strips 11, channel semiconductor strips 12, and source-region semiconductor strips 13 on the right side; the last word-line hole 4 only corresponds to a column of drain-region semiconductor strips 11, channel semiconductor strips 12, and source-region semiconductor strips 13 on the left side. Therefore, those skilled in the art can understand that the first and last word-line holes functionally constitute a complete word-line hole.

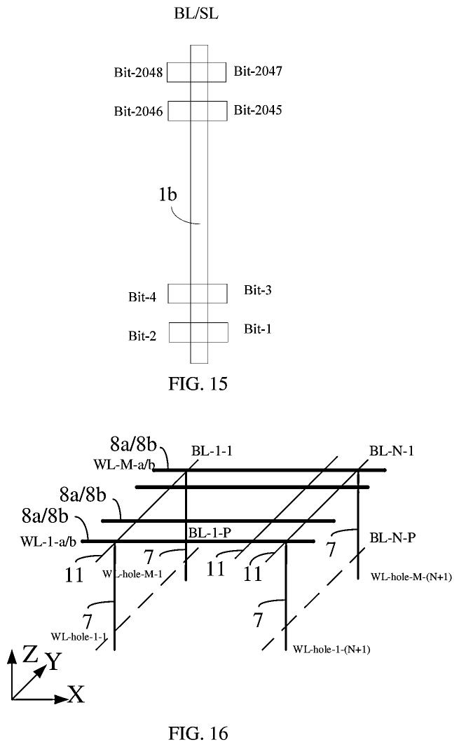

FIG. 13 is a schematic view of a circuitry of the memory device shown in FIG. 11, FIG. 14 is a schematic sketch of a plan view of the memory device shown in FIG. 11, FIG. 15 is a schematic view of a memory cell corresponding to each layer of bit lines, and FIG. 16 is a schematic view of a three-dimensional distribution of word lines and bit lines.

As shown in FIG. 13, the memory device includes multiple memory subarray layers 1a (six layers herein illustrated in FIG. 13), and the drain-region semiconductor strips 11 in the multiple memory subarray layers 1a serve as bit lines, such as BL-1-1, BL-1-2, BL-1-3, BL-1-4, BL-1-5, BL-1-6; multiple columns of drain-region semiconductor strips 11 in each memory subarray layer 1a constitute multiple columns of bit lines, such as BL-1-1, BL-2-1, . . . ; the source-region semiconductor strips 13 in the multiple memory subarray layers 1a in memory device are connected to a common source line 13b; the channel semiconductor strips 12 in the multiple memory subarray layers 1a in memory device are connected to a common well-region line 12b. In addition, the gate strip 2 in the same word-line hole 4, together with the drain-region semiconductor layers 11, the channel semiconductor layers 12, and the source-region semiconductor layers 13 on the left and right sides, forms two columns of memory cells (as shown in the middle two columns of memory cells), respectively. The gate strips 2 corresponding to the odd number word holes 4 are connected to an odd word line WL-a, such as the first, fourth column memory cells, which correspond to the first word-line holes and third word-line holes, respectively; and the gate strips 2 corresponding to the even number word holes 4 are connected to an even word line WL-b, such as the second, third column memory cells, which correspond to the second word-line holes.

As shown in FIGS. 14-16, in each memory subarray layer 1a, for the drain-region semiconductor strips 11, channel semiconductor strips 12, and source-region semiconductor strips 13 extending along the column direction, i.e., one semiconductor-strip-structure column 1b, forms a memory cell (bit) with the gate strip 2 in the left word-line hole 4 and another memory cell (bit) with the gate strip 2 in the right word-line hole 4. The first row of odd word-line holes 4, such as hole-1, hole-3, . . . , are connected to the first row of odd word line WL-1-a, and the first row of even word-line holes, such as hole-2, hole-4, . . . , are connected to the first row of even word line WL-1-b.

As shown in FIG. 16, assume that the memory device includes P layers of memory subarray layers 1a, M rows of word lines, and N columns of bit lines. Then, each memory subarray layer 1a includes N columns of drain-region semiconductor strips 11 as bit lines, such as shown as BL-1-1, . . . , BL-N-1; for the P-th memory subarray layer 1a, such as BL-1-1, . . . , BL-N-P as shown, the memory device includes N*P drain-region semiconductor strips 11 as bit lines. M rows of word lines, e.g., WL-1-a/b, . . . , WL-M-a/b, each have a projection crossed with a projection of each of the N columns of bit lines on a projection plane defined by the row direction X and column direction Y, respectively, to form multiple memory cells. P, M and N are all natural numbers greater than 0.

According to the above conditions, it is understood by those skilled in the art that in the same row direction X, the memory device includes (N+1) word-line holes 4, such as shown as WL-hole-1-1, . . . , WL-hole-1-(N+1); and in the same column direction Y, the memory device includes M word-line holes 4, such as shown as WL-hole-1-(N+1), . . . , WL-hole-M-(N+1). A side of each column of drain-region semiconductor strips 11, channel semiconductor strips 12, and source-region semiconductor strips 13 corresponds to M word-line holes 4. Each row of word lines (one odd word line 8a and one even word line 8b) corresponds to (N+1) word-line holes 4. As above, in the same row, the word-line holes 4 at the first and last ends each correspond to only one memory cell in each memory subarray layer 1a, and therefore the word-line holes 4 at the first and last ends can be functionally regarded as a complete word-line hole; while other word-line holes 4 correspond to two memory cells (one on each of the left and right sides) in each memory subarray layer 1a. Therefore, each row of word lines corresponds to N*2*P memory cells. When N is an even number, an odd word line 8a corresponds to (N/2+1) word-line holes, which includes word-line holes 4 at the first and last ends of the same row, that is, an odd word line 8a also corresponds to N/2 complete word-line holes 4, corresponding to (N/2)*P*2 memory cells. An even word line 8b corresponds to N/2 word-line holes 4, corresponding to (N/2)*P*2 memory cells. In other words, the number of memory cells corresponding to an odd word lines 8a and the number of memory cells corresponding to an even word lines 8b are the same.

In some embodiments, assume that the memory device specifically includes 8 layers of the memory subarray layers 1a and 1024 rows of word lines, each row of word lines includes an odd word line 8a and an even word line 8b, each layer of the memory subarray layer 1a includes 2048 columns of the drain-region semiconductor strips 11 as bit lines, and the memory device includes 2048*8 of the drain-region semiconductor strips 11 as bit lines.

In the same row direction X, the memory device includes (2048+1=2049) word-line holes 4; in the same column direction Y, the memory device includes 1024 word-line holes 4. Each drain-region semiconductor strip 11 as a bit line corresponds to 1024 word-line holes 4, corresponding to 1024*2 memory cells. Each row of word lines corresponds to (2048+1=2049) word-line holes 4. The word-line holes 4 at the first and last terminals each correspond to only one memory cell in each memory subarray layer 1a, which functionally constitutes a complete word-line hole 4, which corresponds to 2048*2*8=32K memory cells. N is an even number 2048, then an odd word line 8a corresponds to (2048/2+1=1025) word-line holes, which includes the word-line holes 4 at the first and last ends of the same row, that is, an odd word line 8a also corresponds to 1024 complete word-line holes 4, which corresponds to (2048/2)*8*2 memory cells; an even word line 8b corresponds to 2048/2 word-line holes 4, which corresponds to (2048/2)*8*2 memory cells.

In the memory device, ⅛ of the memory cells corresponding to a word line, that is, 1024*2 memory cells, may be defined as one memory page (128 complete word-line holes 4). In the memory device, 32K memory cells corresponding to one row of word lines may be defined as a sector, which can be understood that one sector corresponds to 2 word lines, (2048+1) word-line holes 4 (2048 complete word-line holes 4), and 2048*2*8 memory cells (bit).

In the memory device, 16 sectors may be defined to form a sub memory device (eblk) including 0.5M memory cells (2048*2*8*16=1024*2*2*8*16=1024*1024*0.5). In specific embodiments, the memory device includes 64 sub memory devices including 32M memory cells. Each memory device shares a common source line 13b and a common well-region line 12b.

The memory device provided in the embodiments includes a memory array 1, and the memory array 1 includes multiple memory cells distributed in a three-dimensional array; the memory array 1 includes multiple memory subarray layers 1a sequentially stacked along a height direction Z, and each memory subarray layer 1a includes a drain-region semiconductor layer, a channel semiconductor layer, and a source-region semiconductor layer stacked along the height direction Z; the drain-region semiconductor layer, channel semiconductor layer, and source-region semiconductor layer in each memory subarray layer 1a include multiple drain-region semiconductor strips 11, channel semiconductor strips 12, and source-region semiconductor strips 13, respectively, distributed along a row direction X, and each drain-region semiconductor strip 11, channel semiconductor strip 12, and source-region semiconductor strip 13 extends along a column direction Y; multiple gate strips 2 distributed along the column direction Y are arranged on each side of each column of drain-region semiconductor strips 11, channel semiconductor strips 12, and source-region semiconductor strips 13, each gate strip 2 extending along the height direction Z; in the height direction Z, a projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain-region semiconductor strip 11 adjacent to the corresponding part of the channel semiconductor strip 12, and a part of the source-region semiconductor strip 13 adjacent to the corresponding part of the channel semiconductor strip 12 are configured to form a memory cell. The memory device has a higher memory density compared to a two-dimensional memory array.

As above, the memory device provided in some embodiments of the present disclosure further includes connecting wires. Specifically, each row of word lines is connected to gate strips arranged in a corresponding same row separately; each of the drain-region semiconductor strips of each of the memory subarray layers is served as a bit line. The common well-region line is connected to each channel semiconductor strip in each memory subarray layer.

As above, the memory device of the present disclosure includes at least two structures of memory cells. In some embodiments, in combination with FIG. 5, FIG. 7, FIG. 8 and FIG. 10, a memory cell is provided that includes a drain region portion 11′, a channel portion 12′, a source region portion 13′ and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and extends along the height direction Z. In the height direction Z, a projection of the gate portion 2′ partially overlaps with a projection of the channel portion 12′ on a projection plane extending along the height direction Z. A storage structure portion 5′ is arranged between the gate portion 2′ and the drain region portion 11′, the channel portion 12′, and the source region portion 13′.

The drain region portion 11′ is a part of the drain-region semiconductor layer, the channel portion 12′ is a part of the channel semiconductor layer, and the source region portion 13′ is a part of the source-region semiconductor layer of the memory device provided in the above embodiments. The specific structures, functions, and lamination methods of the drain region portion 11′, the channel portion 12′, the source region portion 13′, and the storage structure portion 5′ can be found in those of the drain-region semiconductor layer, the channel semiconductor layer, the source-region semiconductor layer, and the storage structure 5′ in each of the memory subarray layers 1a described above, and the same or similar technical effects can be achieved, which will not be repeated herein.

When the drain region portion 11′, the channel portion 12′, and the source region portion 13′ are each in a strip structure and the storage structure portion 5′ is a charge trapping storage structure portion, the specific structure of the memory cell can be seen in FIG. 5, and other structures of the memory cell can be seen in the relevant description of FIG. 5 above. When the drain region portion 11′, the channel portion 12′, and the source region portion 13′ each include the body structure 15a and multiple protrusions 15b, and the storage structure portion 5′ is a charge trapping storage structure portion, the specific structure of the memory cell can be seen in FIG. 7, and other structures of the memory cell can be found in the above description of FIG. 7. When the storage structure portion 5′ is a floating gate storage structure portion, the specific structure of the memory cell can be seen in FIG. 10 and FIG. 11, and other structures of the memory cell can be seen in the above description of FIG. 10 and FIG. 11.

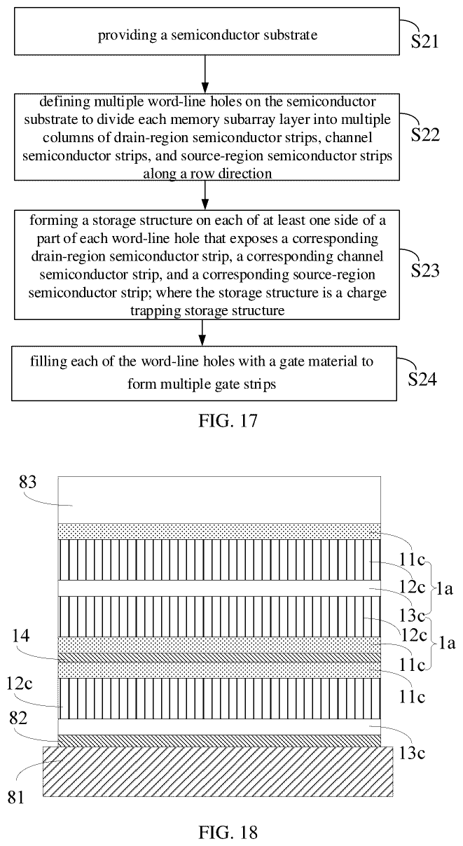

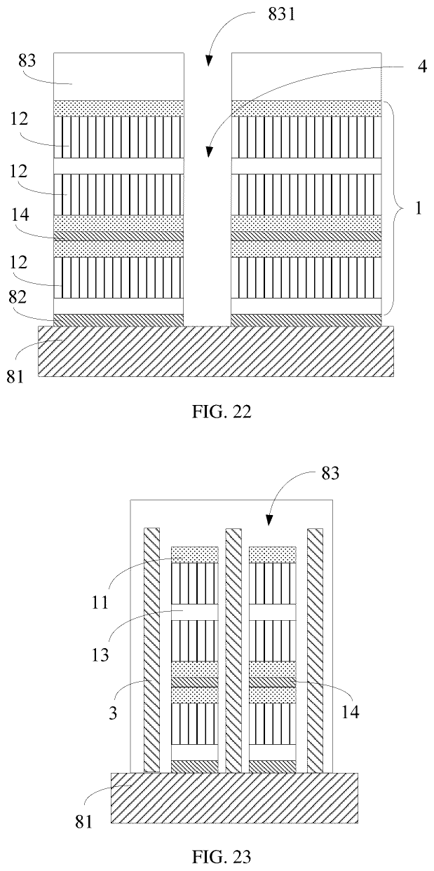

FIG. 17 is a flowchart of a manufacturing method of a memory device according to an embodiment of the present disclosure. In the embodiments, a manufacturing method of a memory device is provided that may be configured to prepare the memory device provided in FIGS. 1-4 of the above embodiments, and the storage structure 5 of the memory device is a charge trapping storage structure. Specifically, the method includes operations at blocks illustrated in FIG. 22.

At step S21: providing a semiconductor substrate.

FIG. 18 is a cross-sectional view of a semiconductor substrate according to an embodiment of the present disclosure. The semiconductor substrate includes a substrate 81, a first single-crystal sacrificial semiconductor layer 82 arranged on the substrate 81, and two memory subarray layers 1a and a second single-crystal sacrificial semiconductor layer 14 stacked and formed alternately in sequence on the first single-crystal sacrificial semiconductor layer 82, until another two memory subarray layers 1a are formed uppermost.

The substrate 81 may be a single-crystal substrate 81; specifically, it may be made of single-crystal silicon. The first single-crystal sacrificial semiconductor layer 82 and/or the second single-crystal sacrificial semiconductor layer 14 may be made of silicon germanium (SiGe). The multiple memory subarray layers 1a are sequentially layered in a height-direction Z perpendicular to the substrate 81. Each memory subarray layer 1a includes a drain-region semiconductor layer 11c, a channel semiconductor layer 12c, and a source-region semiconductor layer 13c stacked along the height direction Z. Two adjacent memory subarray layers 1a in the height direction Z may share a common source region. The two adjacent memory subarray layers 1a may include sequentially stacked drain-region semiconductor layer 11c, channel semiconductor layer 12c, source-region semiconductor layer 13c, channel semiconductor layer 12c, and drain-region semiconductor layer 11c, to achieve sharing the common source-region semiconductor layer 13c. Therefore, for common-source memory subarray layers 1a, a second single-crystal sacrificial semiconductor layer 14 is arranged on every two adjacent memory subarray layers 1a to isolate every two adjacent memory subarray layers 1a from another two adjacent memory subarray layers 1a. The second single-crystal sacrificial semiconductor layer 14 may be made of silicon germanium (SiGe).

It should be noted that the structure shown in FIG. 18 only exemplarily illustrates part of the structure of the semiconductor substrate; it is understood by those skilled in the art that between the first single-crystal sacrificial semiconductor layer 82 and the second single-crystal sacrificial semiconductor layer 14 shown in FIG. 23, two memory subarray layers 1a sharing a common source-region semiconductor layer 13c are arranged. For the sake of brevity of the accompanying drawings, one layer of the memory subarray layer 1a is shown schematically only for illustrative purposes only.

In some embodiments, step S21 may specifically include the following.

Step S211a: providing a substrate 81.

The substrate 81 may be a single-crystal substrate 81; specifically, it may be single-crystal silicon.

Step S212a: forming multiple memory subarray layers 1a sequentially on the substrate 81 along the height direction Z.

Step S212a may specifically include the following.

Step a: forming the first single-crystal sacrificial semiconductor layer 82 on the substrate 81 in epitaxial growth.

The first single-crystal sacrificial semiconductor layer 82 may be silicon germanium (SiGe).

Step b: forming two memory subarray layers 1a and a second single-crystal sacrificial semiconductor layer 14 alternately in sequence by epitaxial growth on the first single-crystal sacrificial semiconductor layer 82; continuing to form another two memory subarray layers 1a, optionally continuing to repeatedly stack another second single-crystal sacrificial semiconductor layer 14 and another two common-source memory subarray layers 1a, until forming uppermost two common-source memory subarray layers.

The material of the second single-crystal sacrificial semiconductor layer 14 is the same as the material of the first single-crystal sacrificial semiconductor layer 82, which may also be silicon germanium (SiGe).

It is understood by those skilled in the art that the purpose of providing the first single-crystal sacrificial semiconductor layer 82 on the substrate 81 first is to avoid electrical leakage caused by the multiple memory subarray layers 1a directly contacting the substrate 81. However, as above, the device performance of the lowermost memory subarray layer 1a in the memory device of the present disclosure is poor, and therefore, the memory cells in the lowermost memory subarray layer 1a are generally configured as virtual memory cells and do not participate in the actual memory work. Therefore, it is understood by those skilled in the art that the first single-crystal sacrificial semiconductor layer 82 may not be arranged on the substrate 81, and a single memory subarray layer 1a or two common-source memory subarray layers 1a are formed directly on the substrate 81 as virtual memory cells, on which the second single-crystal sacrificial semiconductor layer 14 and two common-source memory subarray layers 1a are alternately formed by epitaxial growth until the uppermost layer of two common-source memory subarray layers 1a are formed. That is, the lowermost one memory subarray layer 1a or two common-source memory subarray layers 1a, as a virtual memory cell(s), does not participate in the actual memory work, and therefore, it can also prevent electrical leakage to the substrate 81.

Two adjacent memory subarray layers 1a share a common source region, and every two common-source memory subarray layers may be formed in a manner including the following.

Step b1: forming a first single-crystal semiconductor layer of a first doping type by epitaxial growth on the first single-crystal sacrificial semiconductor layer 82 or the second single-crystal sacrificial semiconductor layer 14 of the lower layer.

Specifically, a semiconductor material gas and a first type of dopant ion gas may be simultaneously introduced to form one layer of the first single-crystal semiconductor layer of the first doping type on the first single-crystal sacrificial semiconductor layer 82 or the second single-crystal sacrificial semiconductor layer 14 of the lower layer by epitaxial growth. The first single-crystal semiconductor layer serves as a drain-region semiconductor layer 11c (or a source-region semiconductor layer 13c). The first type of dopant ion may be an arsenic ion. The semiconductor material may be an existing semiconductor material for forming the drain region (or source region).

Step b2: forming a second single-crystal semiconductor layer of a second doping type on the first single-crystal semiconductor layer by epitaxial growth.

Specifically, a semiconductor material gas and a second type of dopant ion gas may be simultaneously fed to form one layer of the second single-crystal semiconductor layer of the second doping type on the first single-crystal semiconductor layer by epitaxial growth. The second single-crystal semiconductor layer serves as a channel semiconductor layer 12c. The second type of dopant ion may be a BF2+ ion. The semiconductor material may be an existing semiconductor material for forming a well region.

Step b3: forming a third single-crystal semiconductor layer of the first doping type on the second single-crystal semiconductor layer by epitaxial growth.

Specifically, a semiconductor material gas and a first type of dopant ion gas may be simultaneously fed to form one layer of the third single-crystal semiconductor layer of the first doping type on the second single-crystal semiconductor layer by epitaxial growth. The third single-crystal semiconductor layer serves as a source-region semiconductor layer 13c (or a drain-region semiconductor layer 11c). The first type of dopant ion may be an arsenic ion. The semiconductor material may be an existing semiconductor material for forming the source drain region (or drain region).

In a specific implementation of step S212a, the second single-crystal sacrificial semiconductor layer 14 is further formed between every two adjacent memory subarray layers 1a and another two adjacent memory subarray layers 1a. Every two adjacent memory subarray layers 1a separated from another two adjacent memory subarray layers 1a by the second single-crystal sacrificial semiconductor layer 14 in the height direction Z includes sequentially stacked drain-region semiconductor layer 11c, channel semiconductor layer 12c, source-region semiconductor layer 13c, channel semiconductor layer 12c, and drain-region semiconductor layer 11c to share the same source-region semiconductor layer 13c.

Step b4: forming a fourth single-crystal semiconductor layer of a second doping type on the third single-crystal semiconductor layer by epitaxial growth.

This step b4 is performed in a similar manner to step b2. The fourth single-crystal semiconductor layer serve as the channel semiconductor layer 12c.

Step b5: forming a fifth single-crystal semiconductor layer of a first doping type on the fourth single-crystal semiconductor layer by epitaxial growth.

This step b5 is performed in a similar manner as step b1. The fifth single-crystal semiconductor layer serve as the drain-region semiconductor layer 11c (or source-region semiconductor layer 13c).

The first single-crystal semiconductor layer, the second single-crystal semiconductor layer, and the third single-crystal semiconductor layer form a memory subarray layer 1a; the third single-crystal semiconductor layer, the fourth single-crystal semiconductor layer, and the fifth single-crystal semiconductor layer form another memory subarray layer 1a; and the two memory subarray layers 1a share the third single-crystal semiconductor layer as the shared source-region semiconductor layer 13c.

It is understood that, in the embodiments, after step b5, one layer of the second single-crystal sacrificial semiconductor layer 14 is formed on the fifth single-crystal semiconductor layer, after which steps b1-b5 may be repeated on the second single-crystal sacrificial semiconductor layer 14 until a predetermined number of layers of the memory subarray layers 1a is formed.

That is, a second single-crystal sacrificial semiconductor layer 14 is formed between every two adjacent memory subarray layers 1a and another two adjacent memory subarray layers. Moreover, every two adjacent memory subarray layers 1a separated from another two adjacent memory subarray layers by the second single-crystal sacrificial semiconductor layer 14 in the height direction Z includes sequentially stacked drain-region semiconductor layer 11c, channel semiconductor layer 12c, source-region semiconductor layer 13c, channel semiconductor layer 12c, and drain-region semiconductor layer 11c to share the same source-region semiconductor layer 13c.

Step S213a: forming a first hard mask layer 83 on the multiple memory subarray layers 1a, and defining multiple isolation wall holes 31 in the first hard mask layer 83 and the multiple memory subarray layers 1a, and filling the multiple isolation wall holes 31 with an isolation material to form multiple isolation walls 3 to form a semiconductor substrate.

The first hard mask layer 83 may be made of silicon dioxide or silicon nitride.

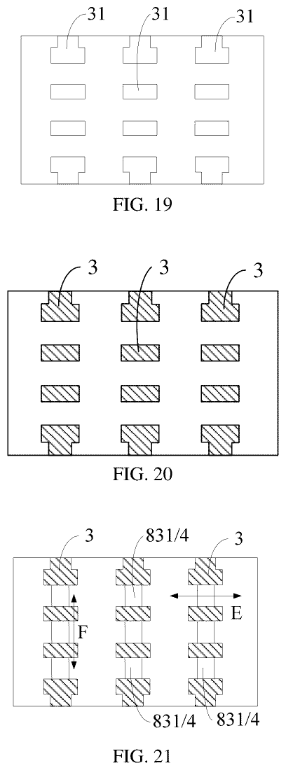

Specifically, referring to FIG. 19, FIG. 19 is a top view of defining multiple isolation wall holes 31 in the memory subarray layers 1a. The multiple isolation wall holes 31 may be formed etching, and the isolation wall holes 31 are arranged in a matrix in the row direction X and column direction Y, with each isolation wall hole 31 extending in the height direction Z to a surface of the substrate 81. The specific structure of forming the isolation walls 3 in the isolation wall holes 31 can be seen in FIG. 20, which is a top view of the multiple isolation walls 3 formed in the isolation wall holes 31 shown in FIG. 19. Specifically, the isolation wall 3 near an edge of the memory device in the column direction Y extends further in the column direction Y to the edge of the memory device to ensure that the isolation wall 3 at the edge of the column direction Y can completely isolate two adjacent columns stacked structures 1b. Specifically, in some embodiments, the isolation wall 3 near the edge of the memory device in the column direction Y is a T-shaped isolation wall 3, i.e., the isolation wall 3 includes a lateral portion and a protruding portion toward the edge of the memory device in the column direction Y, and the protruding portion is in contact with the edge of the memory device in the column direction Y to completely isolate the two adjacent column stack structures 1b to prevent a short circuit between the two columns of the drain-region semiconductor strips 11, the channel semiconductor strips 12, and the source-region semiconductor strips 13. The isolation wall 3 and the first hard mask layer 83 may be made of the same material.

In other embodiments, step S21 specifically includes the following operations.

Step S211b: providing the substrate 81.

Step S212b: forming multiple isolation walls 3 on the substrate 81, where the multiple isolation walls 3 are arranged in a matrix in the row direction X and the column direction Y, each isolation wall 3 extending along the height direction Z perpendicular to the substrate 81.

Step S213b: forming multiple memory subarray layers 1a sequentially on the substrate 81 and between the multiple isolation walls 3 along the height direction Z.

The specific implementation process of forming the multiple memory subarray layers 1a is the same or similar to the specific implementation process of forming the multiple memory subarray layers 1a in step S212a above, and the same or similar technical effect can be achieved, as described above.

Step S214b: forming a first hard mask layer 83 on the above structure to form the semiconductor substrate.

Specifically, the first hard mask layer 83 may be formed on the product structure after being processed by step S213b, with the first hard mask layer 83 being disposed on a side surface of the multiple memory subarray layers 1a back from the substrate 81.

At step S22: defining multiple word-line holes on the semiconductor substrate to divide each memory subarray layer into multiple columns of drain-region semiconductor strips, channel semiconductor strips, and source-region semiconductor strips along a row direction.

In some embodiments, step S22 specifically includes the following.

Step S221: forming the multiple word line openings 831 on the first hard mask layer 83.

Referring to FIG. 21, FIG. 21 is a top view of forming the multiple word line openings 831 and word-line holes 4 on the semiconductor substrate. The multiple word line openings 831 may be formed on the first hard mask layer 83 by etching. The multiple word line openings 831 are arranged in a matrix in the row direction X and the column direction Y.

Step S222: etching the multiple memory subarray layers 1a under the first hard mask layer 83 to form multiple word-line holes 4.

FIG. 22 is a cross-sectional view in the E direction of the product corresponding to FIG. 21, and FIG. 23 is a cross-sectional view in the F direction of the product corresponding to FIG. 21. Specifically, the word-line holes 4 may be formed by etching, and as shown in FIG. 21, the multiple word-line holes 4 are spaced apart from the isolation walls 3; and the multiple word-line holes 4 are arranged in a matrix in the row direction X and column direction Y, and each memory subarray layer 1a is divided into multiple columns of drain-region semiconductor strips 11, channel semiconductor strips 12, and source-region semiconductor strips 13 along the row direction X. As shown in FIG. 22, each word-line hole 4 extends along the height direction Z, and the left and right sides (such as the left and right sides in the orientation of FIG. 22) of each word-line hole 4 at a non-edge position expose parts of two columns of drain-region semiconductor strips 11, channel semiconductor strips 12, and source-region semiconductor strips 13 of the multiple memory subarray layers 1a, respectively. Each word-line hole 4's both sides in the left-right direction are the drain-region semiconductor strips 11, channel semiconductor strips 12 and, source-region semiconductor strips 13; both sides in the front-rear direction are isolation walls 3. In this step, an etchant with a high etch ratio for the semiconductor material and a low etch ratio for the isolation wall 3 may be applied to process the formation of the word-line holes 4. In addition, as shown in FIGS. 2-4, the leftmost edge word-line holes 4 correspond to only one column of the drain-region semiconductor strips 11, channel semiconductor strips 12 and, source-region semiconductor strips 13 on right side; similarly, the rightmost edge word-line holes 4 correspond to only one column of the drain-region semiconductor strips 11, channel semiconductor strips 12 and, source-region semiconductor strips 13 on left side. However, it is understood by those skilled in the art that the leftmost edge line holes 4 and the rightmost edge line holes 4 can be considered as a combination to form a complete word-line hole, and the differences in the edge word-line holes 4 will not be specifically noted subsequently.

As shown in FIGS. 2 and 4, the multiple word-line holes 4 together with the multiple isolation walls 3 divide the drain-region semiconductor layer 11c in each memory subarray layer Ta into multiple drain-region semiconductor strips 11 spaced at intervals along the row direction X; the channel semiconductor layer 12c into multiple channel semiconductor strips 12 spaced at intervals along the row direction X; and the source-region semiconductor layer 13c into multiple source-region semiconductor strips 13 spaced at intervals along the row direction X. The other specific structures and functions of each drain-region semiconductor strip 11, channel semiconductor strip 12, and source-region semiconductor strip 13 can be found in the above description and will not be repeated here. In addition, as shown in FIG. 23, the interior of the isolation wall 3 may be silicon oxide with a layer of silicon nitride wrapped around the outside, and the silicon nitride wrapped around the outside may be the same as the material of the first hard mask layer 83.

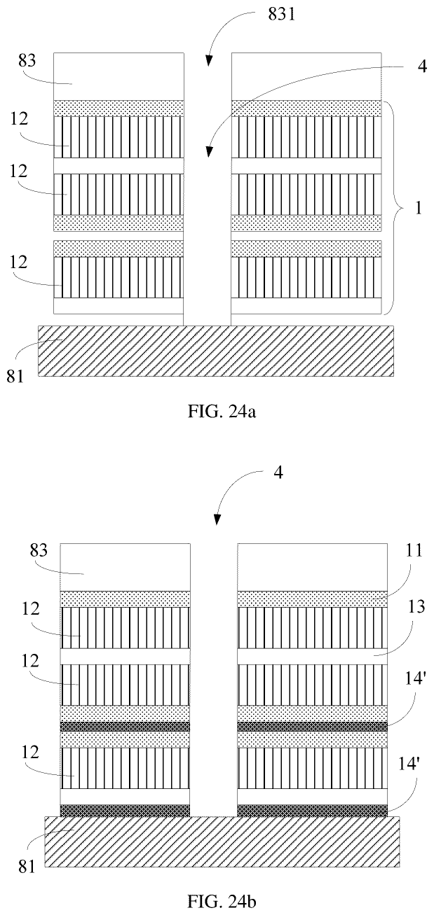

In a specific implementation, FIG. 24a is a schematic view of the structure shown in FIG. 21 after being processed by step S223, and FIG. 24b is a schematic view of the structure shown in FIG. 24a after being filled with the insulating material. After step S222, the method may further include the following.

Step S223: removing the first single-crystal sacrificial semiconductor layer 82 and the second single-crystal sacrificial semiconductor layer 14 through the word-line holes 4.

Specifically, the first single-crystal sacrificial semiconductor layer 82 and the second single-crystal sacrificial semiconductor layer 14 may be removed by etching.

Step S224: depositing on regions where the removed first single-crystal sacrificial semiconductor layer 82 and the second single-crystal sacrificial semiconductor layer 14 were located to fill the regions with an insulating material, thereby replacing the first single-crystal sacrificial semiconductor layer 82 and the second single-crystal sacrificial semiconductor layer 14 with an insulating isolation layer 14′.

The insulating material may be filled by means of atomic layer deposition. The insulating material may specifically be silicon oxide. It will be understood by those skilled in the art that after step S223 removing the first single-crystal sacrificial semiconductor layer 82 and the second single-crystal sacrificial semiconductor layer 14, the isolation walls 3 may provide sufficient support to the adjacent stacked structures 1b to facilitate subsequent execution of step S224.

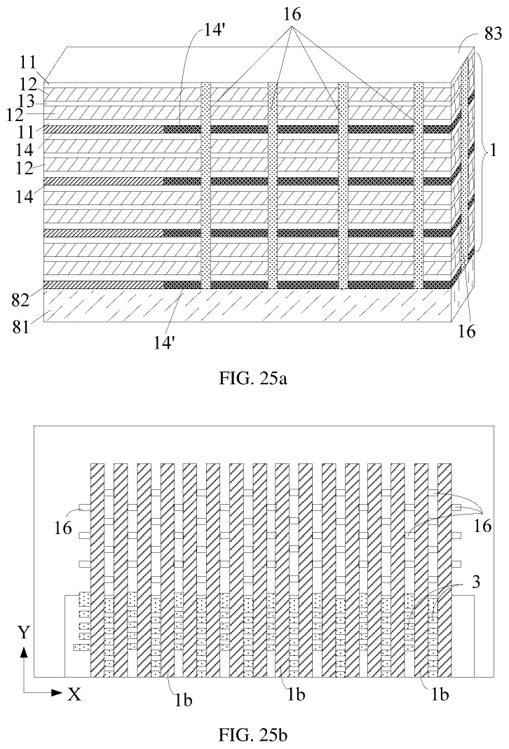

Further, it will be understood by those skilled in the art that in some embodiments, the memory array 1 further includes multiple support pillars 16. FIG. 25a is a schematic view of a perspective structure of a memory array according to an embodiment of the present disclosure, and FIG. 25b is a partial plan schematic view of a memory array according to an embodiment of the present disclosure.

As shown in FIGS. 25a and 25b, the memory array 1 further includes multiple support pillars 16, each of which extends along the height direction Z of the memory array 1.

As described above, the first single-crystal sacrificial semiconductor layer 82 and the second single-crystal sacrificial semiconductor layer 14 are required to be replaced with the insulating isolation layer 14′. In this step, the first single-crystal sacrificial semiconductor layer 82 and the second single-crystal sacrificial semiconductor layer 14 are partially replaced with the insulating isolation layer 14′, but in subsequent steps, all of the first single-crystal sacrificial semiconductor layer 82 and the second single-crystal sacrificial semiconductor layer 14 are replaced with the insulating isolation layer 14′ as required for electrical isolation. That is, during the manufacturing of the memory array 1, after etching off the first single-crystal sacrificial semiconductor layer 82 and/or the second single-crystal sacrificial semiconductor layer 14, the memory subarray layers 1a in the relevant regions are overhanging. In these relevant regions, when the isolation walls 3 are provided, the isolation walls 3 can provide sufficient support to the overhanging memory subarray layers 1a in these regions to prevent the memory subarray layers 1a from collapsing.

However, the isolation walls 3 may not present in some regions. For example, in a drain/source lead region, the memory subarray layers 1a in this region are not required to manufacture the memory cells, and the drain-region semiconductor strips 11, source-region semiconductor strips 13, and/or channel semiconductor strips 12 in the memory subarray layers 1a in this region are required to be led out to be connected with corresponding wires. Therefore, in these regions, multiple support pillars 16 are required to be arranged between two columns of the stacked structures 1b. In this way, after etching the first single-crystal sacrificial semiconductor layer 82 and/or the second single-crystal sacrificial semiconductor layer 14 in the stacked structures 1b in these regions during the manufacturing of the memory array 1, the support pillars 16 can provide sufficient support to the overhanging memory subarray layers 1a to prevent the memory subarray layers 1a from collapsing, and support the frame of the memory array 1 and maintain the structural stability of the memory array 1.

It will be understood by those skilled in the art that the support pillars 16 may be made of the same material as the isolation wall 3 and manufactured in the same process steps as the isolation wall 3. That is, the isolation wall 3 and the support pillar 16 are similar in nature, except that the isolation wall 3 is arranged in the region of the memory array 1 where the memory cells are required to be manufactured, and it serves to support and form the word-line holes 4 during the manufacturing of the memory array 1; whereas the support pillar 16 is formed in another region of the memory array 1 where the memory cell is not required to be manufactured, for example, the drain/source lead region, and it serves to support the memory array 1 during the manufacturing process. Of course, in other embodiments, the support pillar 16 may be arranged in the region of the memory array 1 where the memory cells are required to be manufactured. For example, when the distance between two adjacent isolation walls 3 is far, and the isolation wall 3 does not provide sufficient support, then the support pillar 16 may be arranged in this region as needed to assist the isolation wall 3 to provide support. That is, the support pillar 16 may be arranged according to the actual needs, which is not limited by the present disclosure.

The material of the support pillar 16 may be silicon oxide or silicon nitride.

Step S23: forming a storage structure on each of at least one side of a part of each word-line hole that exposes a corresponding drain-region semiconductor strip, a corresponding channel semiconductor strip, and a corresponding source-region semiconductor strip, where the storage structure is a charge trapping storage structure.

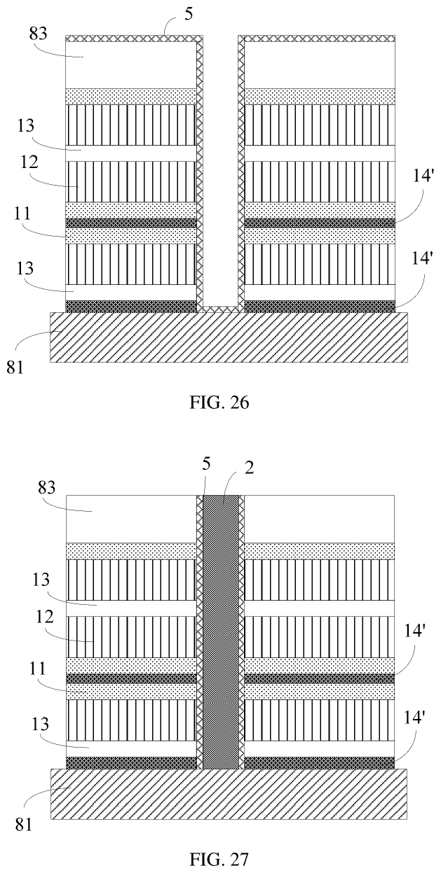

The product structure after processing by step S23 can be seen specifically in FIG. 26, which is a schematic view of the structure shown in FIG. 24b after processing by step S23. In some embodiments, step S23 specifically includes the following.

Step S231: depositing a first dielectric layer on the semiconductor substrate defining the word-line holes 4.

Specifically, one layer of the first dielectric layer is deposited within each word-line hole 4 and on a surface of the first hard mask layer 83 back from the substrate 81. The first dielectric layer within each word-line hole 4 covers surfaces of the parts of the drain-region semiconductor strips 11, channel semiconductor strips 12, and source-region semiconductor strips 13 that are exposed on both sides of the word-line hole 4. For example, in conjunction with FIG. 4, parts of the first stacked structures 1b and the second stacked structures 1b are exposed through word-line hole 4 of the first row and the second column (hereinafter referred to as a first word-line hole 4), the first dielectric layer in the first word-line hole 4 covers the part of the first semiconductor-strip-structure column 1b exposed through the first word-line hole 4, and the part of the second semiconductor-strip-structure column 1b exposed through the first word-line hole 4.

Step S232: depositing a charge storage layer on the first dielectric layer.

The charge storage layer is disposed on a side surface of the first dielectric layer back from a corresponding semiconductor strip structure 1b.

Step S233: depositing a second dielectric layer on the charge storage layer.

The second dielectric layer is disposed on a side surface of the charge storage layer back from the first dielectric layer.

At block S24: filling each of the word-line holes with a gate material to form multiple gate strips.

The product structure after processing by step S24 is specified in FIG. 5 and FIG. 27, where FIG. 27 is a schematic view of the structure shown in FIG. 26 after processing by step S24. As shown in FIG. 5, a projection of at least a part of each gate strip 2 coincides with a projection of a part of a corresponding channel semiconductor strip 12 in each memory subarray layer 1a on a projection plane extending along the height direction Z and the column direction Y. A part of the gate strip 2, a corresponding part of the channel semiconductor strip 12, a part of the drain-region semiconductor strip 11 adjacent to the corresponding part of the channel semiconductor strip 12, a part of the source-region semiconductor strip 13 adjacent to the corresponding part of the channel semiconductor strip 12, and a part of the charge trapping storage structure form a memory cell.

As above, in the embodiments, the storage structure 5 is a charge trapping storage structure, such as an ONO type charge trapping storage structure, such that it can hold the electric charges injected into near the injection point. The electric charges can only move in the injection/removal direction (substantially perpendicular to the extension direction of the charge storage layer 52), and cannot move freely in the charge storage layer 52, especially not in the extension direction of the charge storage layer 52. For the charge trapping storage structure, the charge storage layer 52 is only required to have an insulation dielectric arranged on its front and back side, and the charge stored in each memory cell will be fixed near the injection point of the charge storage portion and will not move to the charge storage portion in other memory cells along the same layer of the charge storage layer 52. Therefore, in its corresponding manufacturing method, it is only necessary to form a first dielectric layer 51 and a second dielectric layer 53 on both sides of the charge storage layer 52, respectively, to separate the charge storage layer 52 from the drain-region semiconductor strip 11, the channel semiconductor strip 12, the source-region semiconductor strip 13 and the gate strip 2, and its manufacturing method is relatively simple.

Specifically, the above manufacturing method of memory device may be configured to prepare the memory device involved in the following embodiments. As shown in FIGS. 1 to 4, the memory device includes a memory array 1, which includes multiple memory cells distributed in a three-dimensional array. The memory array 1 includes multiple stacked structures 1b distributed along the row direction X, each stacked structure 1b extending along the column direction Y, and each stacked structure 1b includes drain-region semiconductor strips 11, channel semiconductor strips 12, and source-region semiconductor strips 13 stacked along the height direction Z. Each drain-region semiconductor strip 11, channel semiconductor strip 12, and source-region semiconductor strip 13 extends along column direction Y, and each drain-region semiconductor strip 11, channel semiconductor strip 12, and source-region semiconductor strip 13 is a single-crystal semiconductor strip.

Multiple gate strips 2 are arranged on each of two sides of each stacked structure 1b along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain-region semiconductor strip 11 adjacent to the corresponding part of the channel semiconductor bar 12, and a part of the source-region semiconductor strip 13 adjacent to the corresponding part of the channel semiconductor bar 12 form a memory cell. Specifically, a charge trapping storage structure is arranged between each gate strip 2 and corresponding drain-region semiconductor strips 11, channel semiconductor strips 12, and source-region semiconductor strips 13 in the multiple memory subarray layers 1a. The specific structure and function of the charge trapping storage structure, and the position relationship with the memory array 1, etc., can be found in the relevant description above.

Specifically, each stacked structure 1b includes multiple stacked substructures, each stacked substructure including a drain-region semiconductor strip 11, a channel semiconductor strip 12, a source-region semiconductor strip 13, a channel semiconductor strip 12, and a drain-region semiconductor strip 11 sequentially stacked along the height direction Z to share the same source-region semiconductor strip 13. Specifically, an interlayer isolation layer is arranged between two adjacent stacked substructures (i.e., the above-mentioned insulating isolation layer 14′) to isolate the two adjacent stacked substructures from each other.

Multiple isolation walls 3 distributed along the column direction Y are arranged on each side of each stacked structure 1b, and each isolation wall 3 extends along the height direction Z and the row direction X to separate at least part of the two adjacent columns of the stacked structures 1b. The isolation walls 3 further serve as support structures to support the two adjacent columns of the stacked structures 1b in the manufacturing process as shown above to facilitate the subsequent manufacturing process. Of course, after the manufacturing process, the isolation walls 3 may be further configured as support structures to support the two adjacent columns of the stacked structures 1b. The isolation wall 3 near an edge of the memory device in the column direction Y is a T-shaped wall to completely isolate the two adjacent columns of the stacked structures 1b. Of course, the isolation wall 3 at the edge in the column direction Y may take other shapes, such as extending in the column direction Y to the edge of the memory device in the column direction Y, etc., as long as it can completely isolate the two adjacent columns of the stacked structures 1b at the edge of the memory device in the column direction Y.

In the column direction Y, a gate strip 2 is arranged between two adjacent isolation walls 3 on the same column; parts of two adjacent columns of the stacked structures 1b share the same gate strip 2.

Other structures and functions of the memory device provided in the embodiments can be found in the specific description of the memory device provided in any of the above embodiments where the storage structure is a charge trapping storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ at least partially coincides with a projection of the channel portion 12′ on a projection plane, the projection plane extending along the height direction Z and the drain region portion 11′. A charge trapping storage structure portion is arranged between the gate portion 2′ and the drain region portion 11′, the channel portion 12′, and the source region portion 13′.

The specific structure and position of the charge trapping storage structure portion can be found in the above description. Other structures and functions of the memory cell can be found in the description of the memory cell with the charge trapping storage structure portion 5′ involved in the above embodiments, which will not be repeated herein.

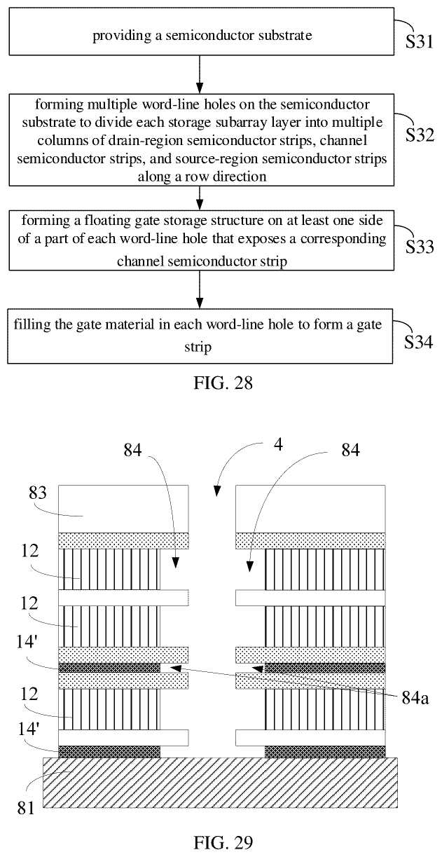

In other embodiments, referring FIG. 28, FIG. 28 is a flowchart of a manufacturing method of a memory device according to another embodiment of the present disclosure. A storage structure of the memory device herein is a floating gate storage structure. Another manufacturing method of a memory device is provided, which may be configured to prepare the memory device corresponding to FIGS. 9-11 above. The method specifically includes the following operations.

At step S31: providing a semiconductor substrate.

At step S32: forming multiple word-line holes on the semiconductor substrate to divide each memory subarray layer into multiple columns of drain-region semiconductor strips, channel semiconductor strips, and source-region semiconductor strips along a row direction.

The specific implementation process of step S31-step S32 is the same or similar to the specific implementation process of step S21-step S22 above, and can achieve the same or similar technical effect, as can be seen above, which will not be repeated herein.

It should be noted that the subsequent steps are the relevant steps after the first single-crystal sacrificial semiconductor layer 82 and the second single-crystal sacrificial semiconductor layer 14 are replaced by the insulating isolation layer 14′ using the word-line holes 4. The relevant process steps of the embodiments are the same as the relevant process steps of the previous embodiments, and will not be repeated herein.

At step S33: forming a floating gate storage structure on at least one side of a part of each word-line hole that exposes corresponding channel semiconductor strips.

Step S33 may specifically include the following.

Step S331: forming a first insulation dielectric layer 85a on at least one side of a part of each word-line hole 4 that exposes a corresponding drain-region semiconductor strip 11, channel semiconductor strip 12, and source-region semiconductor strip 13.

In some embodiments, step S331 specifically includes the following.

Step A: removing a part of the corresponding channel semiconductor strip 12 exposed by each word-line hole 4 to define a first recess 84.

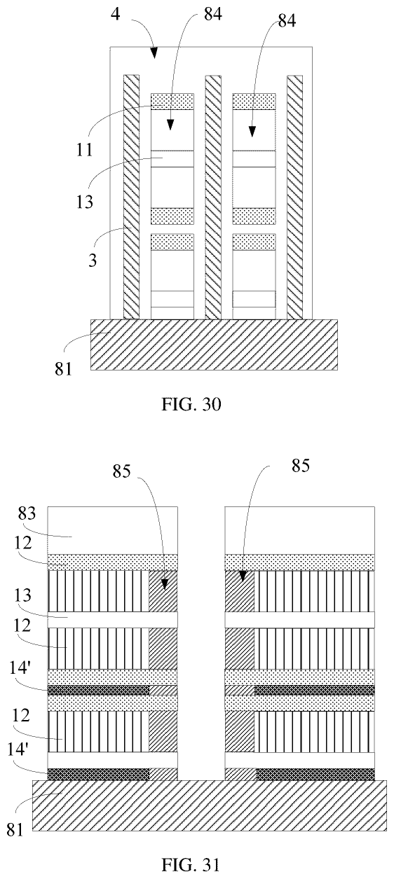

Referring to FIGS. 29-30, FIG. 29 is a schematic view of the structure shown in FIG. 24b defining the first recess 84; FIG. 30 is a cross-sectional view of the product corresponding to FIG. 29 in another direction. Specifically, parts of the channel semiconductor strips 12 exposed on both sides of each word-line hole 4 may be removed by etching to define the first recesses 84, for example by acid etching.

In the embodiments, etching may be performed using an etchant with a high etch ratio for the channel semiconductor strips 12 and the insulating isolation layers 14′, and an etchant with a low etch ratio for the drain-region semiconductor strips 11 and the source-region semiconductor strips 13. For example, when the drain-region semiconductor strips 11 and the source-region semiconductor strips 13 are N-type semiconductor strips and the channel semiconductor stripes 12 are P-type semiconductor strip, then an etchant with a high etch ratio for the P-type semiconductor and with a low etch ratio for the N-type semiconductor may be applied for selective etching, such that only the parts of the channel semiconductor strips 12 and the insulating isolation layers 14′ exposed on both sides of the word-line hole 4 are etched, thereby defining the first recesses 84.

It will be understood by those skilled in the art that when acid etching is performed on a part of the channel semiconductor strips 12, the etchant etches a part of the insulating isolation layers 14′ while etching the part of the channel semiconductor strips 12, defining third recesses 84a, as shown in FIG. 29. Although this etching is unfavorable, the third recess 84a will be backfilled in subsequent steps, in particular with the same material as the insulating isolation layer 14′.

Although in FIG. 29, the third recesses 84a are formed by etching, in other embodiments, the third recesses 84a may not be necessarily defined formed when the etching selection ratio is well controlled.

Step B: filling the multiple first recesses 84 each with a first insulation dielectric 85.

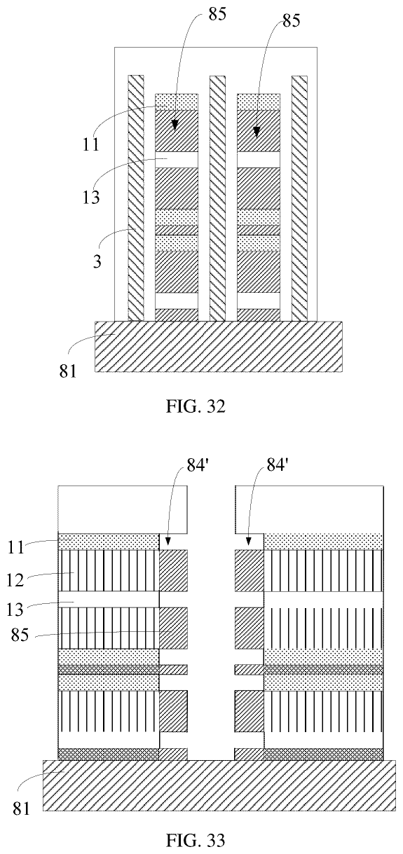

FIG. 31 is a schematic view of the formation of the first insulation dielectric 85 on the structure shown in FIG. 29, and FIG. 32 is a cross-sectional view in the F-direction of the product corresponding to FIG. 31. Specifically, the first insulation dielectric 85 may be filled in the first recesses 84 by deposition. The third recesses 84a may be also filled with the first insulation dielectric 85 by means of deposition. The first insulation dielectric 85 may be the same material as the insulating layer 14′, e.g., silicon oxide.

When the first recesses 84 are filled with the first insulation dielectric 85, the third recesses 84a, formed by etching off parts of the insulating layers 14′, are also filled with the first insulation dielectric 85. Since the material of the first insulation dielectric 85 is silicon oxide, which is the same material as the insulating isolation layers 14′, the device performance will not be affected.

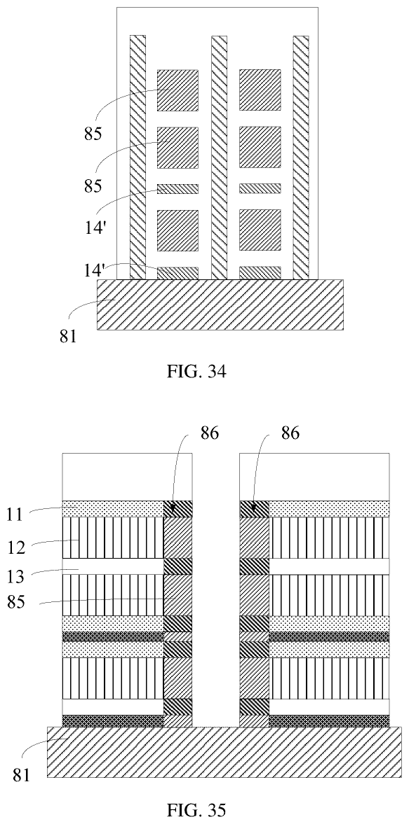

In some embodiments, FIG. 33 is a schematic view of the structure shown in FIG. 31 after defining the second recesses 84′, FIG. 34 is a cross-sectional view of the F-direction of the product corresponding to FIG. 33, and FIG. 35 is a schematic view of the structure shown in FIG. 33 after forming a second insulation dielectric 86. After step B, the method may further include the following.

Step C: removing parts of corresponding drain-region semiconductor strips 11 and parts of corresponding source-region semiconductor strips 13 exposed on both sides of each word-line hole 4 to define multiple second recesses 84′; where each second recess 84′ exposes at least a part of a corresponding first insulation dielectric 85.

The second recesses 84′ may be defined by etching. A vertical cross-sectional view of the product after removing the parts of the drain-region semiconductor strips 11 and the parts of the source-region semiconductor strips 13 exposed on both sides of each word-line hole 4 to define the multiple second recesses 84′ can be seen in FIG. 33. Specifically, in this step, an etchant with a low etch ratio for the channel semiconductor strips 12 and with a high etch ratio for the drain-region semiconductor strips 11 and source-region semiconductor strips 13 may be applied. For example, when the drain-region semiconductor strip 11 and the source-region semiconductor strip 13 are N-type semiconductor strips and the channel semiconductor strip 12 are P-type semiconductor strips, an etchant with a high etch ratio for the N-type semiconductor and with a low etch ratio for the P-type semiconductor may be applied for selective etching, such that only the parts of the drain-region semiconductor strips 11 and the parts of the source-region semiconductor strips 13 exposed on both sides of the exposed line hole 4 are etched to define the second recesses 84′.

Step D: forming a second insulation dielectric 86 in each second recess 84′.

The second insulation dielectric 86 may be formed by deposition. The second insulation dielectric 86 may be made of silicon nitride. After Step D, step E is performed.

Step E: removing the first insulation dielectric 85 in the first recesses 84 to empty the first recesses 84, and depositing a first insulation dielectric layer 85a on walls of the corresponding first recesses 84.

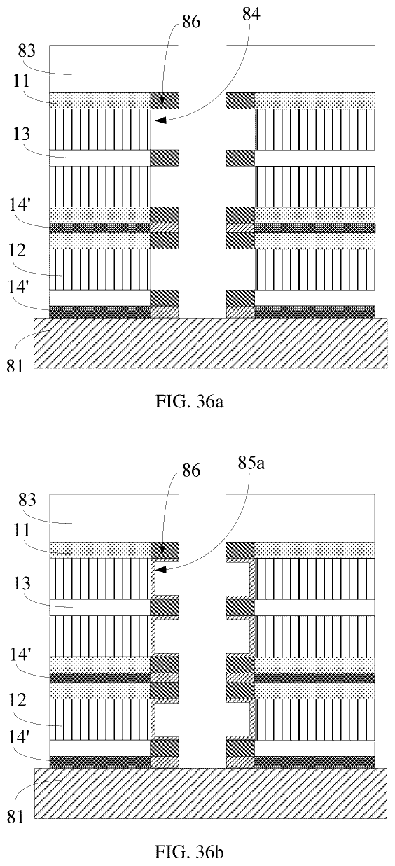

FIG. 36a is a schematic view of the structure after removing the first insulation dielectric 85 in the first recesses 84, and FIG. 36b is a schematic view of the structure shown in FIG. 35 forming the first insulation dielectric layer 85a. In this step, etching may be performed using an etchant with a high etch ratio for the first insulation dielectric 85 and with a low etch ratio for the second insulation dielectric 86, e.g., an etchant with a high etch ratio for silicon oxide and with a low etch ratio for silicon nitride. Further, by controlling the amount of etchant, etch speed, and etch time to etch off the first insulation dielectric 85. Thereafter, a first insulation dielectric layer 85a is formed by deposition or growth in the first recesses 84 where the first insulation dielectric 85 was etched off; the first insulation dielectric layer 85a has a gate-shaped (U-shaped) cross-section for defining a floating gate slot.

Step S332: forming a floating gate 54 on a side surface of a part of the first insulation dielectric layer 85a back from a corresponding channel semiconductor strip 12.

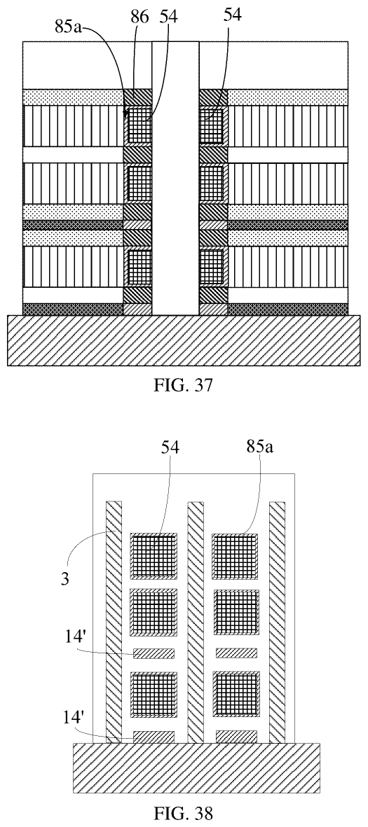

The structure of the product after step S332 can be seen in FIGS. 37-38. FIG. 37 is a schematic view of the structure shown in FIG. 36b forming the floating gates 54; FIG. 38 is a cross-sectional view of the product corresponding to FIG. 37 in another direction.

Specifically, a floating gate material may be deposited in the floating gate slots to form the floating gate 54, and the floating gate material may include polycrystalline silicon material.

Step S333: forming a second insulation dielectric layer 85b on a side wall of each word-line hole, and the second insulation dielectric layer 85b cooperates with the first insulation dielectric layer 85a to wrap any surface of each floating gate 54.

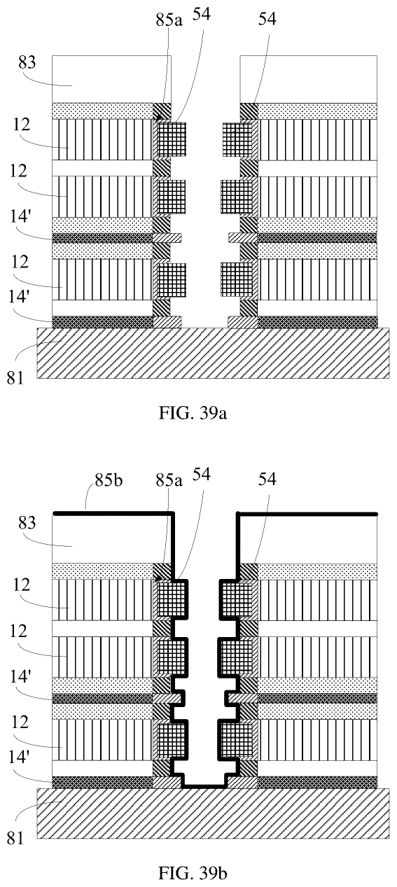

FIG. 39a is a schematic view of the structure after removing a part of the first hard mask layer around each word-line hole and a part of the second insulation dielectric in each second recess. Step S333 may specifically include the following.

Step 3331: removing a part of the first hard mask layer 83 around each word-line hole 4 and a part of the second insulation dielectric 86 in each second recess 84′, to widen the word-line hole 4 and expose at least a part of each floating gate 54.

It will be understood that after Step 3331, the first insulation dielectric layer 85a wraps only a part of the floating gate 54.

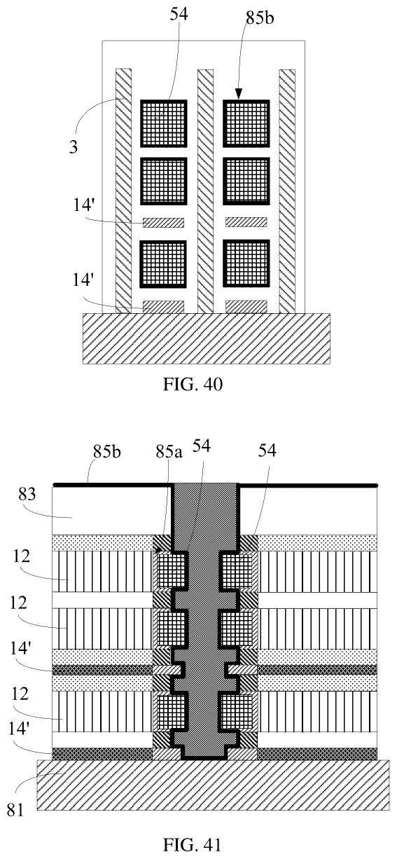

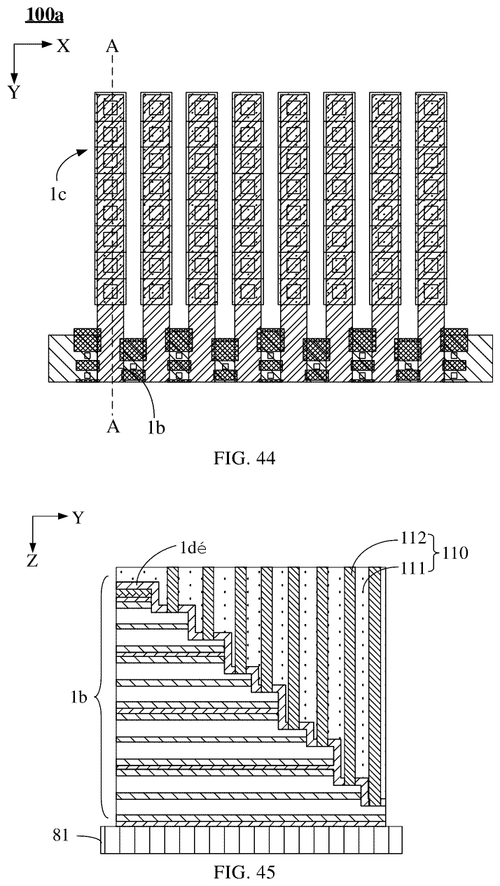

Referring to FIGS. 39b-40, FIG. 39b is a schematic view of the second insulation dielectric layer 85b; FIG. 40 is a cross-sectional view of the F-direction of the product corresponding to FIG. 44b.

Step 3332: forming the second insulation dielectric layer 85b on the side wall of each of widened word-line hole 4 such that the second insulation dielectric layer 85b wraps around an exposed portion of each floating gate 54.

As can be seen in FIG. 39b, the first insulation dielectric layer 85a and the second insulation dielectric layer 85b completely wrap and isolate various surfaces of the floating gates 54. The second insulation dielectric layer 85b includes a multilayer structure including a silicon oxide layer, a silicon nitride layer, and another silicon oxide layer. By widening the word-line hole 4, it is ensured that the second insulation dielectric layer 85b partially covers each of five surfaces of the floating gate 54. In this way, the second insulation dielectric layer 85b and the first insulation dielectric layer 85a can wrap any surface of the floating gate 54. Specifically, as shown in FIG. 39b, a part of the second insulation dielectric layer 85b covers the five surfaces of each floating gate 54, where four of each five surfaces of the floating gate 54 are at least partially covered by the part of the second insulation dielectric layer 85b and the remaining one of the five surfaces is fully covered by the second insulation dielectric layer 85b. Further, the first insulation dielectric layer 85a, in addition to covering the surface of the floating gate 54 near the channel semiconductor strip 12, also covers parts of the other four surfaces of the floating gate 54. Therefore, the first insulation dielectric layer 85a, in conjunction with the second insulation dielectric layer 85b, may wrap all surfaces of the floating gates 54.

Step S34: filling the gate material in each word-line hole to form a gate strip.

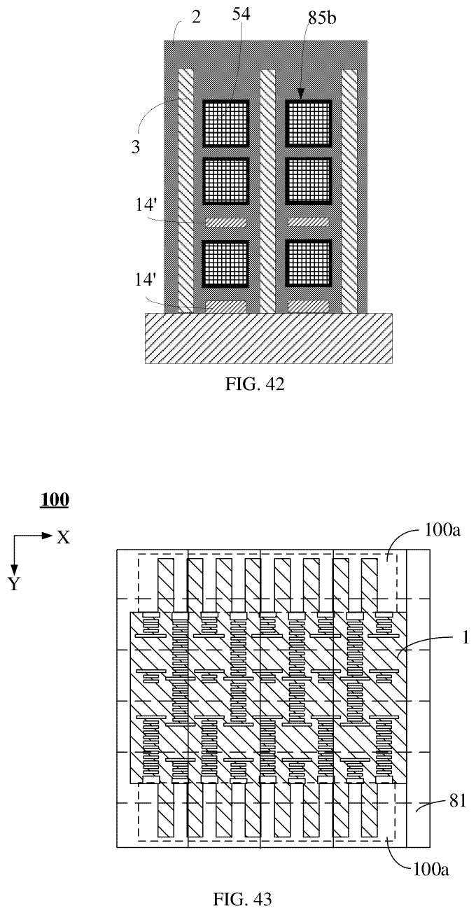

The structure of the product after step S34 can be seen in FIGS. 41-42, where FIG. 41 is a schematic view of the formation of gate strips 2; FIG. 42 is a cross-sectional view of the product corresponding to FIG. 41 in another direction. The gate strip 2 wraps all other surfaces of the floating gate 54 other than those wrapped by the first insulation dielectric layer 85a to improve the coupling rate. That is, a surface of the gate strip 2 extends in the extension direction of the second insulation dielectric layer 85b, thereby sandwiching the second insulation dielectric layer 85b and wrapping the five surfaces of the floating gate 54, and four of the five surfaces of the floating gate 54 are at least partially wrapped by the gate strip 2 through the second insulation dielectric layer 85b. The specific structure of each memory cell in the memory device produced by this manufacturing method can be seen in FIG. 10.

A projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain-region semiconductor strip 11 adjacent to the corresponding part of the channel semiconductor strip 12, a part of the source-region semiconductor strip 13 adjacent to the corresponding part of the channel semiconductor strip 12, and a part of a corresponding floating gate storage structure, form a memory cell.

In the embodiments, the storage structure 5 is a floating gate storage structure, as above, and the floating gate storage structure is characterized by the fact that the charge injected in can be uniformly distributed in the entire floating gate 54, and the charges can move not only in the injection/removal direction (substantially perpendicular to the extension direction of the floating gate), but also in the floating gate 54, particularly in the extension direction of the floating gate 54. Therefore, in the floating gate storage structure, the floating gate 54 of each memory cell is independent, and each surface of each floating gate 54 is required to be covered by an insulation dielectric to be isolated from each other, thereby preventing the charges stored in the floating gates 54 in one memory cell from moving to the floating gates 54 in other memory cells. Therefore, in the manufacturing method thereof, the floating gate 54 of each memory cell is independent, and the insulation dielectric formed by the first insulation dielectric layer 85a and the second insulation dielectric layer 85b can completely wrap and isolate the various surfaces of the floating gates 54, such that the floating gates 54 of each memory cell are independent and the charge stored in each floating gate 54 cannot move to the floating gates 54 of other memory cells.

Specifically, the manufacturing method may be configured to prepare the memory device involved in the following embodiments. The memory device includes a memory array 1, which includes multiple memory cells distributed in a three-dimensional array. The memory array 1 includes multiple stacked structures 1b distributed along the row direction X, each stacked structure 1b extending along the column direction Y, and each stacked structure 1b includes drain-region semiconductor strips 11, channel semiconductor strips 12, and source-region semiconductor strips 13 stacked along the height direction Z. Each drain-region semiconductor strip 11, channel semiconductor strip 12, and source-region semiconductor strip 13 extends along column direction Y, and each drain-region semiconductor strip 11, channel semiconductor strip 12, and source-region semiconductor strip 13 is a single-crystal semiconductor strip.

Multiple gate strips 2 are arranged on each of two sides of each stacked structure 1b along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain-region semiconductor strip 11 adjacent to the corresponding part of the channel semiconductor bar 12, and a part of the source-region semiconductor strip 13 adjacent to the corresponding part of the channel semiconductor bar 12 form a memory cell. Specifically, a floating gate storage structure is arranged between each gate strip 2 and corresponding drain-region semiconductor strips 11, channel semiconductor strips 12, and source-region semiconductor strips 13 in the multiple memory subarray layers 1a. The floating gate storage structure includes multiple first insulation dielectric layers 85a, multiple floating gates 54, and the second insulation dielectric layer 85b. Each first insulation dielectric layer 85a is disposed between at least a corresponding channel semiconductor strip 12 and a corresponding floating gate 54, the floating gate 54 is located disposed a corresponding first insulation dielectric layer 85a and the second insulation dielectric layer 85b, and the second dielectric layer 85b is disposed between the floating gates 54 and the gate strip 2.

Specifically, each stacked structure 1b includes multiple stacked substructures, each stacked substructure including a drain-region semiconductor strip 11, a channel semiconductor strip 12, a source-region semiconductor strip 13, a channel semiconductor strip 12, and a drain-region semiconductor strip 11 sequentially stacked along the height direction Z to share the same source-region semiconductor strip 13. Specifically, an interlayer isolation layer is arranged between two adjacent stacked substructures to isolate the two adjacent stacked substructures from each other.

Multiple isolation walls 3 distributed along the column direction Y are arranged on each side of each stacked structure 1b, and each isolation wall 3 extends along the height direction Z and the row direction X to separate at least part of the two adjacent columns of the stacked structures 1b. The isolation walls 3 further serve as support structures to support the two adjacent columns of the stacked structures 1b. The isolation wall 3 near an edge of the memory device in the column direction Y is a T-shaped wall to completely isolate the two adjacent columns of the stacked structures 1b.

In the column direction Y, a gate strip 2 is arranged between two adjacent isolation walls 3 on the same column; parts of two adjacent columns of the stacked structures 1b share the same gate strip 2.

Other structures and functions of the memory device provided in the embodiments can be found in the specific description of the memory device provided in any of the above embodiments where the storage structure is a floating gate storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ and a projection the channel portion 12′ on a projection plane extending along the height direction Z at least partially coincide, the projection plane being located on a side of the drain region portion 11′, the channel portion 12′, and the source region portion 13′ and extending along the height direction Z and the column direction Y. A floating gate storage structure portions arranged between the gate portion 2′ and the drain region portion 11′, the channel portion 12′, and the source region portion 13′.

The floating gate storage structure portion specifically includes a corresponding first insulation dielectric layer 85a, a corresponding floating gate 54, and a part of the second insulation dielectric layer 85b. The first insulation dielectric layer 85a is disposed between the channel portion 12′ and the floating gate 54, the floating gate 54 is disposed between the first insulation dielectric layer 85a and the part of the second insulation dielectric layer 85b, and the part of the second insulation dielectric layer 85b is disposed between the floating gate 54 and the gate strip 2. The part of the second insulation dielectric layer 85b covers five surfaces of the floating gate 54. One of the five surfaces of the floating gate 54 is fully covered by the second insulation dielectric layer 85b. The part of the second insulation dielectric layer 85b includes a multilayer structure including a part of a silicon oxide layer, a part of a silicon nitride layer, and a part of another silicon oxide layer.

Other structures and functions of the memory cell can be found in the description of the memory cell for which the storage structure portion 5′ is a floating gate storage structure portion involved in the above-described embodiments, and will not be repeated herein.

On the other hand, some embodiments of the present disclosure further provide a memory block. FIG. 43 is a schematic structural view of a memory block according to some embodiments of the present disclosure. The memory block 100 may include a substrate 81, a memory array 1 arranged on the substrate 81, and a well-lead-out region 100a arranged on the substrate 81. In addition, the memory block 100 may also include various types of wires (or connecting lines), etc., so as to enable the memory block 100 to perform various memory operations.

Firstly, the specific structure of the memory array 1 is described. As shown in FIGS. 1-4, FIGS. 1-3 is schematic perspective structural views of the memory array shown in FIG. 43 according to some embodiments of the present disclosure; FIG. 4 is a schematic perspective structural view of the memory array shown in FIG. 43 according to some embodiments of the present disclosure.

The memory array 1 includes a plurality of memory cells distributed in a three-dimensional array. As shown in FIG. 1, the memory array 1 includes a plurality of memory subarray layers 1a sequentially stacked along a height direction Z. Each memory subarray layer 1a includes a drain-region semiconductor layer, a channel semiconductor layer, and a source-region semiconductor layer stacked along the height direction Z. The drain-region semiconductor layer, the channel semiconductor layer, and the source-region semiconductor layer may be single-crystal semiconductor layers formed by epitaxial growth. The height direction Z is perpendicular to the substrate 81. Herein, the term “sequentially stacked” indicates an arrangement from bottom to top on the substrate, while the term “stacked” indicates an arrangement and does not express or imply an upper/lower relationship between the layers or structures.

In each memory subarray layer 1a, the drain-region semiconductor layer (D) includes a plurality of drain-region semiconductor strips 11 spaced apart from each other along a row direction X, and each drain-region semiconductor strip 11 extends along a column direction Y. The channel semiconductor layer (CH) includes a plurality of channel semiconductor strips 12 spaced apart from each other along the row direction X, and each channel semiconductor strip 12 extends along the column direction Y. The source-region semiconductor layer (S) includes a plurality of source-region semiconductor strips 13 spaced apart from each other along the row direction X, and each source-region semiconductor strip 13 extends along the column direction Y. Due to the structural design of the memory array 1, the memory block 100 provided by some embodiments of the present disclosure has a higher memory density than a two-dimensional memory block in the related art.

Herein, each drain-region semiconductor strip 11, each channel semiconductor strip 12, and each source-region semiconductor strip 13 are single-crystal semiconductor strips respectively. Those skilled in the art may understand that, each drain-region semiconductor strip 11 may be a single-crystal semiconductor strip formed by processing the drain-region semiconductor layer formed by epitaxial growth, each channel semiconductor strip 12 may be a single-crystal semiconductor strip formed by processing the channel semiconductor layer formed by epitaxial growth, and each source-region semiconductor strip 13 may be a single-crystal semiconductor strip formed by processing the source-region semiconductor layer formed by epitaxial growth.

For convenience of description, a column of drain-region semiconductor strips 11, channel semiconductor strips 12, and source-region semiconductor strips 13 in the memory subarray layers 1a may be defined as a semiconductor-strip-structure column 1b (that is, in the memory subarray layers 1a, the drain-region semiconductor strips 11, the channel semiconductor strips 12, and the source-region semiconductor strips 13 in the same column may be defined as a semiconductor-strip-structure column 1b). A column of drain-region semiconductor strip 11, channel semiconductor strip 12, and source-region semiconductor strip 13 in each memory subarray layer 1a may be defined as a semiconductor strip structure (that is, in each memory subarray layer 1a, the drain-region semiconductor strip 11, the channel semiconductor strip 12, and the source-region semiconductor strip 13 in the same column may be defined as a semiconductor strip structure). That is, one semiconductor-strip-structure column 1b includes a plurality of semiconductor strip structures, and the number of the semiconductor strip structures in the semiconductor-strip-structure column 1b is the same as that of the memory subarray layers 1a.

As shown in FIGS. 1-3, one semiconductor-strip-structure column 1b includes two semiconductor strip structures. Those skilled in the art may understand that, one semiconductor-strip-structure column 1b may include a plurality of semiconductor strip structures stacked with each other, as shown in FIG. 4, one semiconductor-strip-structure column 1b may include three semiconductor strip structures.

Two adjacent memory subarray layers 1a may share a common source, that is, two adjacent memory subarray layers 1a share the same source-region semiconductor layer (S). Therefore, two semiconductor strip structures corresponding to two adjacent memory subarray layers 1a share the same source-region semiconductor strip 13. Those skilled in the art may understand that, in some embodiments, two adjacent memory subarray layers 1a may also use a non-common source design, that is, each memory subarray layer 1a has one independent source-region semiconductor layer. Therefore, two semiconductor strip structures 1b corresponding to two adjacent memory subarray layers 1a have source-region semiconductor strips 13 independent from each other.

As shown in FIG. 4, the memory array 1 includes a plurality of memory subarray layers 1a sequentially stacked along the height direction Z. Each memory subarray layer 1a includes a drain-region semiconductor layer, a channel semiconductor layer, and a source-region semiconductor layer stacked along the height direction Z. In each memory subarray layer 1a, the drain-region semiconductor layer includes a plurality of drain-region semiconductor strips 11 spaced apart from each other along the row direction X, the channel semiconductor layer includes a plurality of channel semiconductor strip 12 spaced apart from each other along the row direction X, and the source-region semiconductor layer includes a plurality of source-region semiconductor strip 13 spaced apart from each other along the row direction X. Two adjacent memory subarray layers 1a include one drain-region semiconductor layer, one channel semiconductor layer, one source-region semiconductor layer, another channel semiconductor layer, and another drain-region semiconductor layer sequentially stacked to share the same source-region semiconductor layer.

An interlayer isolation layer is arranged between every two adjacent memory subarray layers 1a and another two adjacent memory subarray layers 1a to isolate every two adjacent memory subarray layers 1a from another two adjacent memory subarray layers 1a. For example, along the height direction Z, one interlayer isolation layer is arranged between a first group consisting of a first memory subarray layer 1a and a second memory subarray layer 1a and a second group consisting of a third memory subarray layer 1a and a fourth memory subarray layer 1a; another interlayer isolation layer is arranged between a third group consisting of a third memory subarray layer 1a and a fourth memory subarray layer 1a and a fourth group consisting of a fifth memory subarray layer 1a and a sixth memory subarray layer 1a, and so on. It may be understood that, one interlayer isolation layer is arranged between the second memory subarray layer 1a and the third memory subarray layer Ta, and another interlayer isolation layer is arranged between the fourth memory subarray layer Ta and the fifth memory subarray layer Ta.

In some embodiments, as shown in FIG. 4, along the height direction Z, in the same semiconductor-strip-structure column, an interlayer isolation strip 14a is arranged between every two adjacent semiconductor strip structures and another two adjacent semiconductor strip structures. Similarly, in other semiconductor-strip-structure columns, another interlayer isolation strip 14a is also arranged between every two adjacent semiconductor strip structures and another two adjacent semiconductor strip structures. Those skilled in the art may understand that, a plurality of interlayer isolation strips 14a on the same horizontal plane form the interlayer isolation layer, to isolate the semiconductor strip structures in every two adjacent memory subarray layers 1a from the semiconductor strip structures in another two adjacent memory subarray layers 1a.

Other structures of the memory array 1 may be the same as or similar to the aforesaid embodiments, which will not be repeated herein.

The specific structure of the memory array 1 is detailed above, and the well-lead-out region 100a will be detailed next, so as to describe how each channel semiconductor strip 12 is led out.

FIG. 44 is a schematic structural view of a well-lead-out region in FIG. 43 according to some embodiments of the present disclosure, and FIG. 45 is a schematic cross-section structural view along A-A in FIG. 44. Each semiconductor-strip-structure column 1b extends to the well-lead-out region 100a, and in the well-lead-out region 100a, each semiconductor-strip-structure column 1b includes a stepped structure 1c with a plurality of steps, to enable each channel semiconductor strip 12 in the semiconductor-strip-structure column 1b to be at least partially exposed. The well-lead-out region 100a includes a plurality of well-connection structures 110. Each well-connection structure 110 corresponds to one semiconductor-strip-structure column 1b and leads out each channel semiconductor strip 12 in the semiconductor-strip-structure column 1b by using the stepped structure 1c in the semiconductor-strip-structure column 1b.

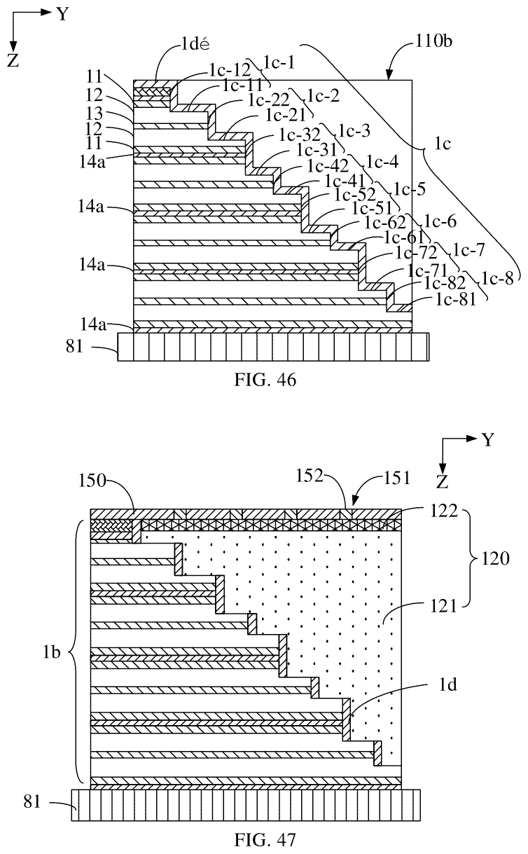

FIG. 46 is a schematic view of a stepped structure in FIG. 45. As shown in FIG. 46, one semiconductor-strip-structure column 1b includes 8 semiconductor strip structures stacked along the height direction Z. Every two adjacent semiconductor strip structures include one drain-region semiconductor strip 11, one channel semiconductor strip 12, one source-region semiconductor strip 13, another channel semiconductor strip 12, and another drain-region semiconductor strip 11 sequentially stacked along the height direction Z. That is, every two adjacent semiconductor strip structures share the same source-region semiconductor strip 13. Every two adjacent semiconductor strip structures is isolated from another two adjacent semiconductor strip structures by the interlayer isolation strip 14a.

Each step may be formed corresponding to one semiconductor strip structure. That is, the stepped structure 1c shown in FIG. 46 includes 8 steps (Tc-n, herein n may be any positive integer from 1 to 8), which are gradually arranged along the column direction Y. It should be noted that, some embodiments of the present disclosure do not limit the specific number of the steps, as long as the number of the steps included in each semiconductor-strip-structure column 1b is the same as the number of the semiconductor strip structures included in the semiconductor-strip-structure column 1b. At least part of each channel semiconductor strip 12 in each semiconductor-strip-structure column 1b is exposed through the stepped structure 1c, and the exposed part of each channel semiconductor strip 12 is parallel to the substrate 81. In some embodiments, the stepped structure 1c may formed by a multi-step etching process.

Each step (1c-n, herein n may be any positive integer from 1 to 8) includes a first surface (1c-n1, herein n may be any positive integer from 1 to 8) and a second surface (1c-n2, herein n may be any positive integer from 1 to 8). The first surface is parallel to the substrate 81 and the second surface is perpendicular to the substrate 81. In some embodiments, the first surface of each step exposes at least part of the corresponding channel semiconductor strip 12 in the semiconductor-strip-structure column 1b.

The dimensions of the first surfaces of the steps may be the same as each other. That is, along the column direction Y, the width of the first surfaces of the steps may be the same as each other, which may be between 0.2 um and 0.8 um, such as 0.2 um, 0.4 um, 0.6 um, and 0.8 um. The dimensions of the second surfaces of the steps may be the same as each other. That is, along the height direction Z, the heights of the second surfaces of the steps may be the same as each other, which is not limited by the embodiments of the present disclosure, and those skilled in the art may select according to actual requirements.

Except for the step closest to the substrate 81 and the step furthest from the substrate 81, each step includes at least part of the upper channel semiconductor strip 12, at least part of the lower channel semiconductor strip 12, and at least part of the drain-region semiconductor strip 11 and/or the source-region semiconductor strip 13 sandwiched therebetween. At least part of the lower channel semiconductor strip 12 serves as the first surface. The side surfaces of at least part of the upper channel semiconductor strip 12, at least part of the lower channel semiconductor strip 12, and at least part of the drain-region semiconductor strip 11 and/or the source-region semiconductor strip 13 serve as the second surface.

FIG. 46 shows 8 steps (1c-n, herein n may be any positive integer from 1 to 8) gradually arranged along the column direction Y from top to bottom. For convenience of description, the steps are respectively referred to as a first step 1c-1, a second step 1c-2, a third step 1c-3, a fourth step 1c-4, a fifth step 1c-5, a sixth step 1c-6, a seventh step 1c-7, and an eighth step 1c-8. FIG. 46 shows 8 channel semiconductor strips 12 sequentially stacked from top to bottom. For the convenience of description, the channel semiconductor strips 12 are respectively referred to as a first channel semiconductor strip 12, a second channel semiconductor strip 12, a third channel semiconductor strip 12, a fourth channel semiconductor strip 12, a fifth channel semiconductor strip 12, a sixth channel semiconductor strip 12, a seventh channel semiconductor strip 12, and an eighth channel semiconductor strip 12.

The first step 1c-1 is the step furthest from the substrate 81, and the eighth step 1c-8 is the step closest to the substrate 81. For example, the second step 1c-2 may include at least part of the first channel semiconductor strip 12, at least part of the second channel semiconductor strip 12, and at least part of the source-region semiconductor strips 13 sandwiched therebetween. At least part of the second channel semiconductor strip 12 serves as the first surface 1c-21. The side surfaces of at least part of the first channel semiconductor strip 12, at least part of the second channel semiconductor strip 12, and at least part of the source-region semiconductor strip 13 serve as the second surface 1c-22.

The third step 1c-3 may include at least part of the second channel semiconductor strip 12, at least part of the third channel semiconductor strip 12, at least part of two drain-region semiconductor strips 11 sandwiched therebetween, and at least part of the interlayer isolation strip 14a sandwiched between two drain-region semiconductor strips 11. At least part of the third channel semiconductor strip 12 serves as the first surface 1c-31. The side surfaces of at least part of the second channel semiconductor strip 12, at least part of the third channel semiconductor strip 12, at least part of the drain-region semiconductor strip 11, and at least part of the interlayer isolation strip 14a serve as the second surface 1c-32.

In some embodiments, the stepped structure 1c may be formed by the following process. A plurality of removing openings 110b (which are shown in FIGS. 46 and 49) are formed on the side of the well-lead-out region 100a away from the substrate 81. Each removing opening 110b corresponds to one semiconductor-strip-structure column 1b. At least part of the corresponding semiconductor-strip-structure column 1b is removed through each removing opening 110b by using a multi-step etching process, to enable each semiconductor-strip-structure column 1b to include the stepped structure 1c with the plurality of steps in the well-lead-out region 100a.

As shown in FIG. 45, the well-connection structure 110 includes a plurality of well-connection columns 112 spaced apart from each other along the column direction Y. The well-connection column 112 is arranged in one-to-one correspondence with the channel semiconductor strip 12 in the corresponding semiconductor-strip-structure column 1b. In some embodiments, one end of each well-connection column 112 is connected to the corresponding channel semiconductor strip 12 in the corresponding semiconductor-strip-structure column 1b, and the other end of each well-connection column 112 serves as a well-lead-out pad to lead out the corresponding channel semiconductor strip 12 in the corresponding semiconductor-strip-structure column 1b.

The well-connection structure 110 may further include a filling layer 111 filled in the removing opening 110b. The well-connection columns 112 may be spaced apart from each other along the column direction Y in the filling layer 111. In some embodiments, one end of each well-connection column 112 is connected to the corresponding channel semiconductor strip 12 in the corresponding semiconductor-strip-structure column 1b, and the other end of each well-connection column 112 is exposed outside the filling layer 111 to serve as the well-lead-out pad, so as to lead out the corresponding channel semiconductor strip 12 in the corresponding semiconductor-strip-structure column 1b.

In some embodiments, the filling layer 111 may be a polycrystalline silicon filling layer. An insulating dielectric layer 1d′ may be covered on the corresponding stepped structure 1c through the removing opening 110b. The insulating dielectric layer 1d′ covers the first surface and the second surface of each step in the stepped structure 1c. The polycrystalline silicon filling layer may cover the insulating dielectric layer 1d′. The material of the insulating dielectric layer 1d′ may be silicon oxide or silicon nitride, which is not limited by the embodiments of the present disclosure, and those skilled in the art may select according to actual requirements.

The well-connection column 112 may be a conductive material, such as metal and so on, and extends along the height direction Z. One end of the well-connection column 112 passes through the insulating dielectric layer 1d′ covered on the first surface to connect to the corresponding channel semiconductor strip 12, and the other end of the well-connection column 112 is exposed outside the polycrystalline silicon filling layer to serve as the well-lead-out pad.

In some embodiments, the well-connection column 112 may be formed by the following process. A plurality of contact holes spaced apart from each other along the column direction Y are formed in the polycrystalline silicon filling layer. Each contact hole passes through the insulating dielectric layer 1d′ covered on the first surface. Furthermore, the contact hole may be filled with the conductive material, such as metal and so on, to form the well-connection column 112. In this way, the end of the well-connection column 112 is connected to the corresponding channel semiconductor strip 12. The polycrystalline silicon filling layer is conductive, the well-connection column 112 is also conductive. Therefore, in order to prevent the polycrystalline silicon filling layer from contacting all the well-connection columns, after the contact holes spaced apart from each other along the column direction Y are formed in the polycrystalline silicon filling layer, and before the conductive material, such as metal and so on, is filled, it is necessary to form an isolating layer on the side wall of the contact hole. The isolating layer is an insulating material. That is, the isolating layer is arranged between the polycrystalline silicon filling layer and each well-connection column.

In some embodiments, the well regions of different memory cells may be controlled independently from each other, so as to prevent crosstalk between different well regions. In some embodiments, a metal block may be formed on the well-connection structure 110, all the well-connection columns 112 on the semiconductor-strip-structure column may be connected together through the metal block to control all the well-connection columns 112.

In the scheme of some embodiments, the polycrystalline silicon material has a good etching selection ratio. Therefore, when the contact hole is formed by etching in the polycrystalline silicon filling layer, the etching may be stopped above the corresponding channel semiconductor strip accurately, so as to reduce the process difficulty.

After the stepped structure 1c configured to lead out each channel semiconductor strip 12 is formed, a large number of other preceding processes (by which the structure configured to lead out each drain/source-region semiconductor strip 11/13 is formed) are still required. Therefore, it is difficult to form a metal silicide used to lead out each channel semiconductor strip 12 on the stepped structure 1c, and the impedance of each well-connection column 112 is large. In addition, the heights of the well-connection columns along the height direction Z are different from each other, and the impedance distribution of the well-connection columns is not convergent, which leads to different response durations of the channel semiconductor strips 12, and the memory performance of the memory block 100 may be affected.

It should be noted that, if other preceding processes (by which the structure configured to lead out each drain/source-region semiconductor strip 11/13 is formed) are performed firstly, and the stepped structure 1c configured to lead out each channel semiconductor strip 12 is formed finally, although a metal silicide may be formed on the stepped structure 1c configured to lead out each channel semiconductor strip 12, it is difficult to form another metal silicide on the structure configured to lead out each drain/source-region semiconductor strip 11/13. That is, the process of forming the metal silicide is required to be performed twice.

FIG. 47 is a schematic structural view of a well-lead-out region in FIG. 43 according to some embodiments of the present disclosure. Each semiconductor-strip-structure column 1b extends to the well-lead-out region 100a. In the well-lead-out region 100a, each semiconductor-strip-structure column 1b includes a stepped structure 1c with a plurality steps. The well-lead-out region 100a includes a plurality of well-connection structures 120. Each well-connection structure 120 corresponds to one semiconductor-strip-structure column 1b, for electrically connects the channel semiconductor strips 12 in the semiconductor-strip-structure column 1b together by using the stepped structure 1c in the semiconductor-strip-structure column 1b, and then leads out the channel semiconductor strips 12 in the semiconductor-strip-structure column 1b.

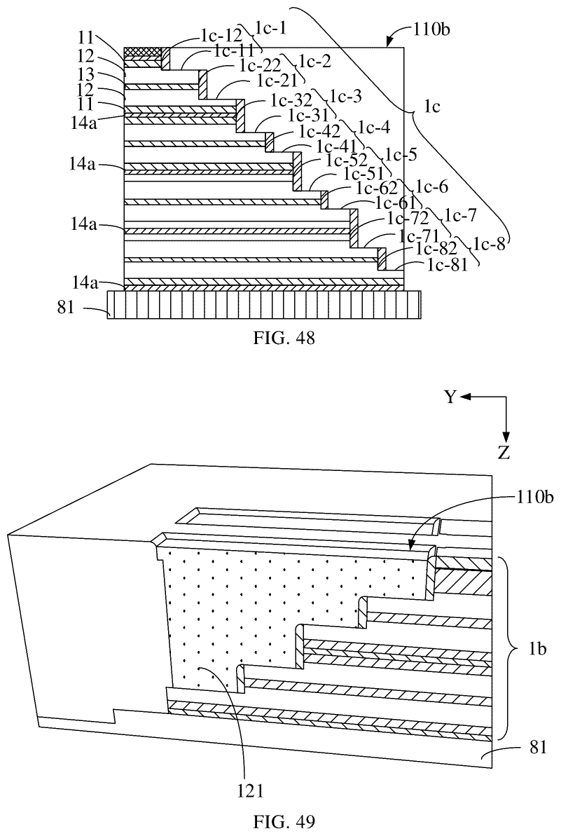

FIG. 48 is a schematic view of a stepped structure in FIG. 47. The stepped structure 1c in the embodiments is different from the stepped structure 1c in the embodiments shown in FIG. 45 in that, at least part of each channel semiconductor strip 12 in the semiconductor-strip-structure column 1b is exposed through the stepped structure 1c. In some embodiments, the first surface of each step exposes at least part of the corresponding channel semiconductor strip 12 in the semiconductor-strip-structure column 1b, and the second surface of each step is covered by an insulating dielectric 1d to avoid all the drain-region semiconductor strips 11 and all the source-region semiconductor strips 13 in the semiconductor-strip-structure column 1b from being exposed.

FIG. 48 shows 8 steps (1c-n, herein n may be any positive integer from 1 to 8) gradually arranged along the column direction Y from top to bottom. For convenience of description, the steps are respectively referred to as a first step 1c-1, a second step 1c-2, a third step 1c-3, a fourth step 1c-4, a fifth step 1c-5, a sixth step 1c-6, a seventh step 1c-7, and an eighth step 1c-8. FIG. 46 shows 8 channel semiconductor strips 12 sequentially stacked from top to bottom. For the convenience of description, the channel semiconductor strips 12 are respectively referred to as a first channel semiconductor strip 12, a second channel semiconductor strip 12, a third channel semiconductor strip 12, a fourth channel semiconductor strip 12, a fifth channel semiconductor strip 12, a sixth channel semiconductor strip 12, a seventh channel semiconductor strip 12, and an eighth channel semiconductor strip 12.

For example, at least part of the first channel semiconductor strip 12 is exposed through the first surface 1c-11 of the first step 1c-1, and the second surface 1c-12 of the first step 1c-1 is covered by the insulating dielectric 1d to avoid the drain-region semiconductor strip 11 located above the first channel semiconductor strip 12 from being exposed. At least part of the second channel semiconductor strip 12 is exposed through the first surface 1c-21 of the second step 1c-2, and the second surface 1c-22 of the second step 1c-2 is covered by the insulating dielectric 1d to avoid the source-region semiconductor strip 13 between the first channel semiconductor strip 12 and the second channel semiconductor strip 12 from being exposed. At least part of the third channel semiconductor strip 12 is exposed through the first surface 1c-31 of the third step 1c-3, and the second surface 1c-32 of the third step 1c-3 is covered by the insulating dielectric 1d to avoid two drain-region semiconductor strips 11 between the second channel semiconductor strip 12 and the third channel semiconductor strip 12 from being exposed. At least part of the fourth channel semiconductor strip 12 is exposed through the first surface 1c-41 of the fourth step 1c-4, and the second surface 1c-42 of the fourth step 1c-4 is covered by the insulating dielectric 1d to avoid the source-region semiconductor strip 13 between the third channel semiconductor strip 12 and the fourth channel semiconductor strip 12 from being exposed.

In some embodiments, the stepped structure 1c may be formed by the following process. A plurality of removing openings 110b (which are shown in FIGS. 48 and 49) are formed on the side of the well-lead-out region 100a away from the substrate 81. Each removing opening 110b corresponds to one semiconductor-strip-structure column 1b. At least part of the corresponding semiconductor-strip-structure column 1b is removed through each removing opening 110b by using a multi-step etching process, to enable each semiconductor-strip-structure column 1b to include the stepped structure 1c with the plurality of steps in the well-lead-out region 100a.

In some embodiments, an insulating dielectric layer 1d′ may be covered on the corresponding stepped structure 1c through the removing opening 110b. The insulating dielectric layer 1d′ covers the first surface and the second surface of each step in the stepped structure 1c. The insulating dielectric layer 1d′ covered on the first surface of each step is removed, in this way, at least part of the corresponding channel semiconductor strip 12 in the semiconductor-strip-structure column 1b is exposed through the first surface of each step. The material of the insulating dielectric layer 1d′ may be silicon oxide or silicon nitride, which is not limited by the embodiments of the present disclosure, and those skilled in the art may select according to actual requirements.

The well-connection structures 120 in the embodiments are different from the embodiments shown in FIG. 45. In the embodiments, each well-connection structure 120 includes a connecting layer 121, and the connecting layer 121 covers the stepped structure 1c of the corresponding semiconductor-strip-structure column 1b, so as to electrically connect the channel semiconductor strips 12 in the semiconductor-strip-structure column 1b together. In some embodiments, the connecting layer 121 covers the stepped structure 1c and contacts the part of the channel semiconductor strip 12 exposed through the first surface of each step (that is, the connecting layer 121 contact the exposed part of the channel semiconductor strip 12 through the first surface of each step). The connecting layer 121 is insulated from the drain-region semiconductor strip 11 and the source-region semiconductor strip 13 in the corresponding semiconductor-strip-structure column 1b through the insulating dielectric 1d.

FIG. 49 is a schematic partial structural view of a memory block according to some embodiments of the present disclosure. One semiconductor-strip-structure column 1b shown in FIG. 49 includes 4 semiconductor strip structures stacked along the height direction Z. Each step may be formed corresponding to one semiconductor strip structure. That is, the stepped structure 1c shown in FIG. 49 includes 4 steps. The removing opening 110b is shown in FIG. 49, and the connecting layer 121 may be filled in the removing opening 110b. The connecting layer 121 may be a polycrystalline silicon connecting layer, and the doping type thereof may be the same as that of the channel semiconductor strip 12, and opposite to those of the drain-region semiconductor strip 11 and the source-region semiconductor strip 13. For example, the channel semiconductor strip 12 may be P-type doped single-crystal silicon, the drain-region semiconductor strips 11 and the source-region semiconductor strips 13 may be N-type doped single-crystal silicon, and the connecting layer 121 may be P-type doped polycrystalline silicon, which is not limited by the embodiments of the present disclosure, and those skilled in the art may select according to actual requirements.

As shown in FIG. 47, each well-connection structure 120 may further include a connection-improvement layer 122. The connection-improvement layer 122 is arranged on the connecting layer 121. The material of the connection-improvement layer 122 may be a metal silicide, which is not limited by the embodiments of the present disclosure, and those skilled in the art may select according to actual requirements.

In some embodiments, the well-connection structure 120 includes a connecting layer 121 filled in the removing opening 110b and a connection-improvement layer 122 arranged on the connecting layer 121. The connection-improvement layer 122 may form an equipotential plane on the side of the connecting layer 121 away from the substrate, in this way, the impedance of the well-connection structure 120 is evenly distributed, and the response durations of the channel semiconductor strips 12 in each semiconductor-strip-structure column 1b are substantially the same as each other, and the memory performance of the memory block 100 may be improved.

It should be noted that, in some embodiments, the well-connection structure 120 may only include the connecting layer 121 filled in the removing opening 110b, but not include the connection-improvement layer 122. Each channel semiconductor strip 12 in the corresponding semiconductor-strip-structure column 1b may be led out only by using the connecting layer 121.

As shown in FIG. 47, the memory block 100 may further include an interlayer-dielectric layer 150 covering the memory array 1 and the well-lead-out region 100a. The interlayer-dielectric layer 150 may be silicon oxide, which is not limited by the embodiments of the present disclosure, and those skilled in the art may select according to actual requirements.

In the well-lead-out region 100a, the interlayer-dielectric layer 150 has at least one lead-out hole 151 corresponding to each well-connection structure 120. The lead-out hole 151 is filled with a conductive material to form a connecting column 152. One end of the connecting column 152 is connected to the corresponding well-connection structure 120, and the other end of the connecting column 152 is exposed outside the interlayer-dielectric layer 150 to serve as a lead-out pad. The material of the connecting column 152 may be metal, which is not limited by the embodiments of the present disclosure, and those skilled in the art may select according to actual requirements.

In some embodiments, as shown in FIG. 47, the lower end of the connecting column 152 may be connected to the connection-improvement layer 122. Since the conductivity of the connection-improvement layer 122 is good, the contact resistance between the connecting column 152 and the well-connection structure 120 may be reduced. The upper end of the connecting column 152 is exposed outside the interlayer-dielectric layer 150 to serve as a lead-out pad. It should be noted that, in the embodiments in which the well-connection structure 120 only includes the connecting layer 121 filled in the removing opening 110b and does not include the connection-improvement layer 122, the lower end of the connecting column 152 may be directly connected to the connecting layer 121.

As shown in FIG. 47, in the well-lead-out region 100a, the interlayer-dielectric layer 150 may have 4 connecting columns 152 corresponding to each well-connection structure 120. In this way, the potentials at various positions of the connecting layer 121 may be substantially the same as each other. In some embodiments, the end of each connecting column 152 close to the substrate 81 (i.e., the lower end) is connected to the well-connection structure 120. Therefore, the ends of the connecting columns 152 close to the substrate 81 (i.e., the lower ends) may be substantially maintained on the same horizontal plane, and the process difficulty may be reduced. It should be noted that, in some embodiments, the number of the connecting columns 152 may be 1, 2, 3, 5 or more, which is not limited by the present disclosure.

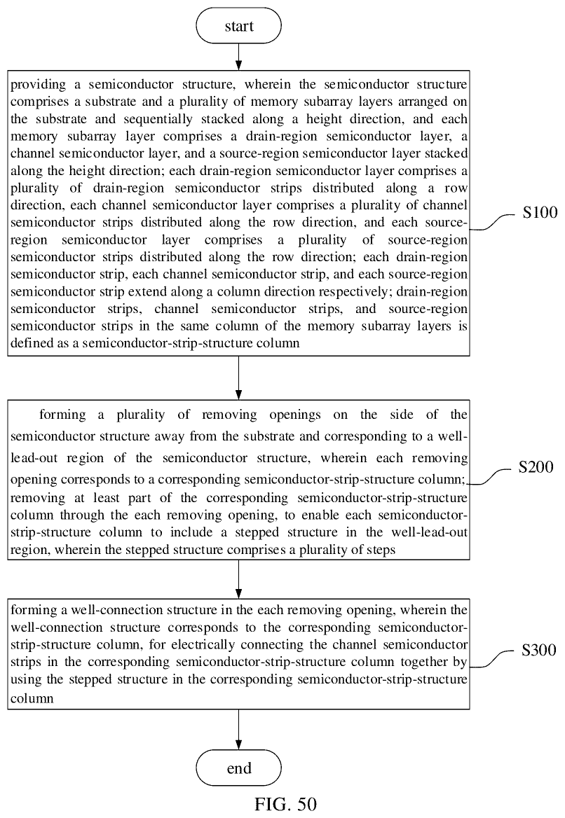

Some embodiments of the present disclosure provide a manufacture method of a memory block 100. The manufacture method may be configured to manufacture the memory block 100 shown in FIG. 47, and more specifically, to manufacture the well-connection structure shown in FIG. 47. FIG. 50 is a schematic flow chart of a manufacture method of a memory block according to some embodiments of the present disclosure. The manufacture method may include the following operations.

Operation S100, a semiconductor structure is provided; the semiconductor structure includes a substrate 81 and a plurality of memory subarray layers 1a arranged on the substrate 81 and sequentially stacked along a height direction Z, and each memory subarray layer 1a includes a drain-region semiconductor layer, a channel semiconductor layer, and a source-region semiconductor layer sequentially stacked along the height direction Z; each drain-region semiconductor layer includes a plurality of drain-region semiconductor strips 11 distributed along a row direction X, each channel semiconductor layer includes a plurality of channel semiconductor strips 12 distributed along the row direction X, and each source-region semiconductor layer includes a plurality of source-region semiconductor strips 13 distributed along the row direction X; each drain-region semiconductor strip 11, each channel semiconductor strip 12, and each source-region semiconductor strip 13 extend along a column direction Y respectively; a column of drain-region semiconductor strips 11, channel semiconductor strips 12, and source-region semiconductor strips 13 in the memory subarray layers 1a is defined as a semiconductor-strip-structure column 1b.

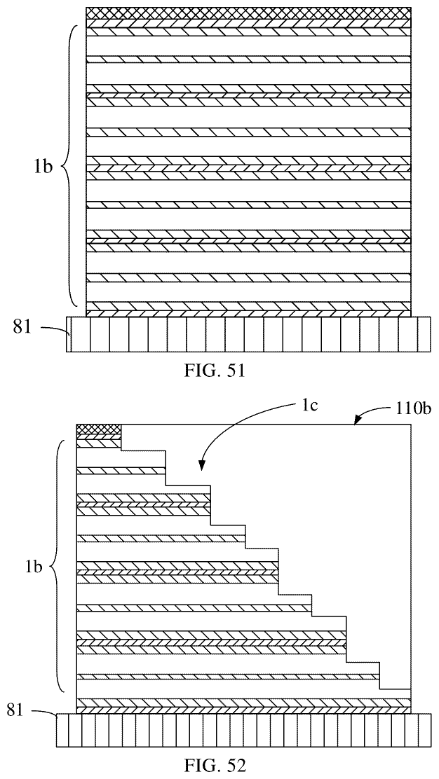

FIG. 51 is a schematic view of a semiconductor structure at operation S100. The specific structures of the substrate 81 and the memory subarray layers 1a of the semiconductor structure are detailed above, which will not be repeated herein.

Operation S200, a plurality of removing openings 110b are formed on the side of the semiconductor structure away from the substrate 81 and corresponding to a well-lead-out region 100a of the semiconductor structure, each removing opening 110b corresponds to one semiconductor-strip-structure column 1b, through each removing opening 110b, at least part of the corresponding semiconductor-strip-structure column 1b is removed, to enable each semiconductor-strip-structure column 1b to include a stepped structure 1c in the well-lead-out region 100a, and the stepped structure 1c includes a plurality of steps.

In some embodiments, the removing openings 110b may be formed on the side of the semiconductor structure away from the substrate 81 through an etching process. At least part of the corresponding semiconductor-strip-structure column 1b may be removed through each removing opening 110b by using the etching process. In this way, in the well-lead-out region 100a, each semiconductor-strip-structure column 1b may include the stepped structure 1c with a plurality of steps, which is within the scope that is easy for those skilled in the art to understand and will not be repeated herein.

FIG. 52 is a schematic view of a stepped structure at operation S200. Each step of the stepped structure 1c includes a first surface and a second surface. The first surface is parallel to the substrate 81. The second surface is perpendicular to the substrate 81. The first surface of each step exposes at least part of the corresponding channel semiconductor strip 12 in the semiconductor-strip-structure column 1b. The specific structure of each step is detailed above, which will not be repeated herein.

Operation S300, a well-connection structure 120 is formed in each removing opening 110b, and each well-connection structure 120 corresponds to one semiconductor-strip-structure column 1b, for electrically connects the channel semiconductor strips 12 in the semiconductor-strip-structure column 1b together by using the stepped structure 1c in the semiconductor-strip-structure column 1b, and then leads out the channel semiconductor strips 12 in the semiconductor-strip-structure column 1b.

In some embodiments, before operation S300, the method may include the following operations.

Operation S210, an insulating dielectric 1d is formed on the second surface of each step to avoid the drain-region semiconductor strip 11 and the source-region semiconductor strip 13 in the semiconductor-strip-structure column from being exposed.

In some embodiments, operation S210 may include the following operations.

Operation S211, an insulating dielectric layer 1d′ is deposited on the stepped structure 1c, and the insulating dielectric layer 1d′ covers the first surface and the second surface of each step.

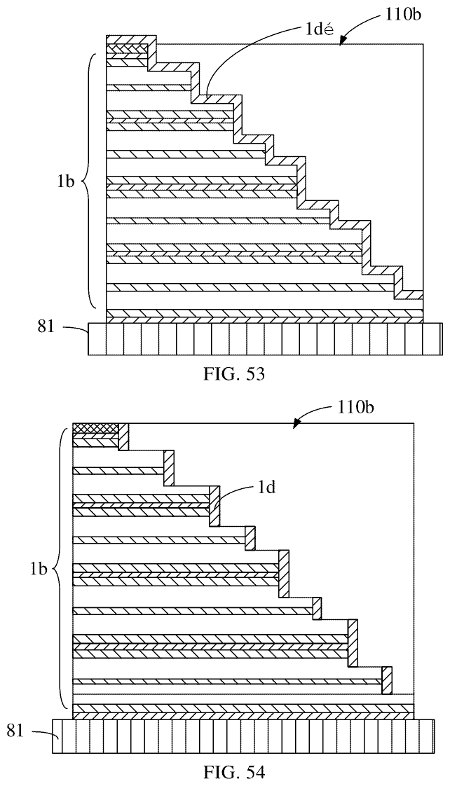

FIG. 53 is a schematic view of covering an insulating dielectric layer 1d′ at operation S211. In some embodiments, silicon oxide may be deposited on the stepped structure 1c through a deposition process, which is within the scope that is easy for those skilled in the art to understand and will not be repeated herein.

Operation S212, the insulating dielectric layer 1d′ covering the first surface of each step is removed.

FIG. 54 is a schematic view of covering an insulating dielectric on a second surface of each step at operation S212. FIG. 54 shows the stepped structure 1c after removing the insulating dielectric layer 1d′ covering the first surface of each step. In some embodiments, the insulating dielectric layer 1d′ covering the first surface of each step may be removed by an etching process. An anisotropic etching may be performed on the insulating dielectric layer 1d′. For example, reactive-ion etching may be performed along a vertical direction, to remove the lateral extending portion of the insulating dielectric layer 1d′, the vertical extending portion is retained to form an isolating side wall. That is, the insulating dielectric 1d covered on the first surface of each step is removed by a maskless etching, and the insulating dielectric 1d covered on the second surface of each step is retained. The insulating dielectric 1d covers the side walls of the source-region semiconductor strip and the drain-region semiconductor strip. In this way, the source-region semiconductor strip and the drain-region semiconductor strip are insulated from the well-connection structure 120 formed subsequently, which is within the scope that is easy for those skilled in the art to understand and will not be repeated herein.

Next, operation S300 will be detailed. In some embodiments, operation S300 may include the following operations.

Operation 310, the connecting layer 121 is formed in each removing opening 110b, the connecting layer 121 covers the stepped structure 1c of the corresponding semiconductor-strip-structure column 1b, to electrically connects the channel semiconductor strips 12 in the semiconductor-strip-structure column 1b together.

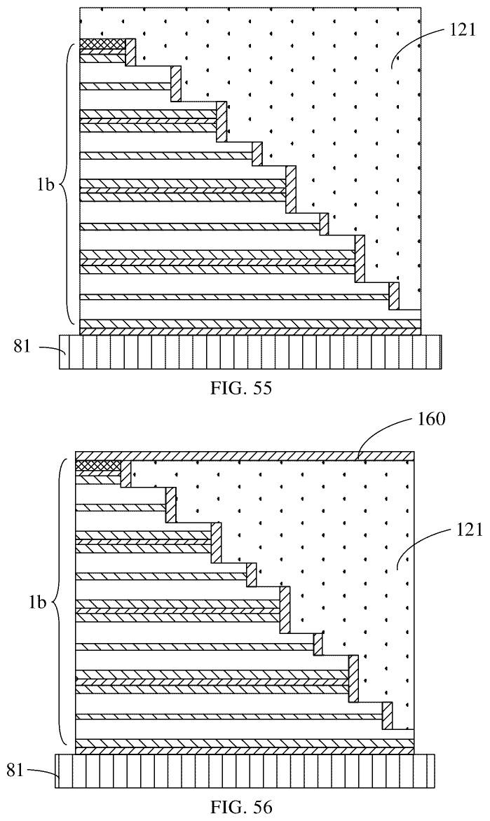

As shown in FIG. 55, FIG. 55 is a schematic view of forming a connecting layer on a stepped structure at operation S310. In some embodiments, polycrystalline silicon may be filled in the removing opening 110b to form the connecting layer 121 by deposition. The connecting layer 121 may be a polycrystalline silicon connecting layer, and the doping type thereof may be the same as that of the channel semiconductor strip 12, and opposite to those of the drain-region semiconductor strip 11 and the source-region semiconductor strip 13. For example, the channel semiconductor strip 12 may be P-type doped single-crystal silicon, the drain-region semiconductor strip 11 and the source-region semiconductor strips 13 may be N-type doped single-crystal silicon, and the connecting layer 121 may be P-type doped polycrystalline silicon, which is not limited by the embodiments of the present disclosure, and those skilled in the art may select according to actual requirements.

Operation 320, a connection-improvement layer 122 is formed on the side of each connecting layer 121 away from the substrate 81.

As shown in FIG. 55, in some embodiments, the connecting layer 121 formed at operation S310 covers at least part of the surface of the semiconductor structure, and the method may include the following operations between operation S310 and operation S320.

Operation S311, at least part of the connecting layer 121 is removed, the side surface of the connecting layer 121 away from the substrate 81 is flush with the side surface of the semiconductor structure away from the substrate 81, a protective layer 160 is formed on the side of each connecting layer 121 away from the substrate 81, to avoid the interference of other preceding processes on the connecting layer 121.

In some embodiments, at least part of the connecting layer 121 may be removed by chemical mechanical polishing, and the side surface of the connecting layer 121 away from the substrate 81 is flush with the side surface of the semiconductor structure away from the substrate 81.

FIG. 56 is a schematic view of forming a protective layer on a connecting layer at operation S311. The protective layer 160 may be silicon oxide and is configured to protect the connecting layer 121 during other preceding processes, which is within the scope that is easy for those skilled in the art to understand and will not be repeated herein. It should be noted that the terms “other preceding processes” in some embodiments of the present disclosure mainly refers to the processes by which the structure configured to lead out each drain/source-region semiconductor strip 11/13 is formed.

Operation S312, the protective layer 160 is removed.

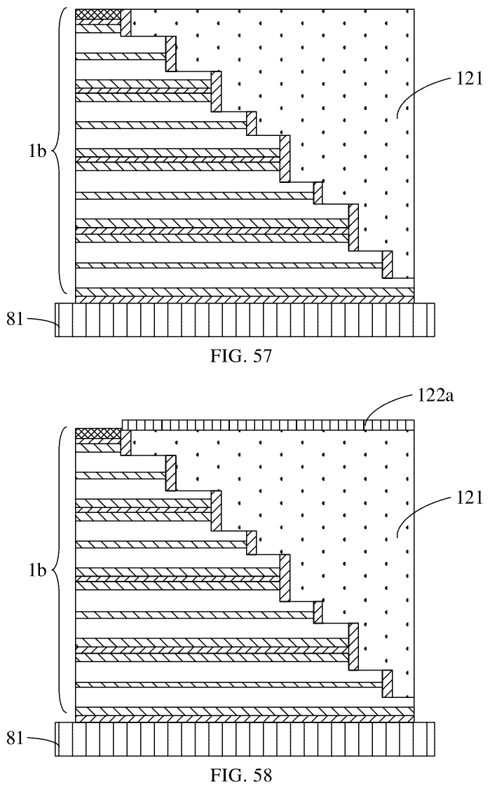

FIG. 57 is a schematic view of removing a protective layer on a connecting layer at operation S312. In some embodiments, the protective layer 160 may be removed by an etching process to expose the connecting layer 121, which is not limited by the embodiments of the present disclosure, and those skilled in the art may select according to actual requirements.

Next, operation S320 will be detailed. In some embodiments, operation S320 may include the following operations.

Operation S321, a metal layer 122a is deposited on the connecting layer 121.

FIG. 58 is a schematic view of forming a metal layer on a connecting layer at operation S321. The specific deposition process is not limited by the embodiments of the present disclosure, and those skilled in the art may select according to actual requirements.

Operation S322, annealing is performed, a silicification reaction occurs between the deposited metal layer 122a and the silicon on the surface of the connecting layer 121, conductive metal silicide is generated, the unreacted metal is removed, and the connection-improvement layer 122 is formed.

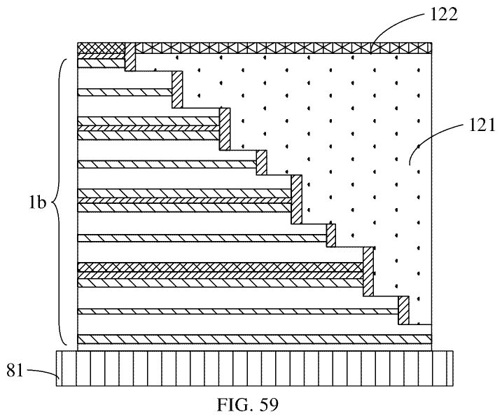

FIG. 59 is a schematic view of forming a connection-improvement layer on a connecting layer at operation S322. In some embodiments, the connection-improvement layer 122 may also be formed through other processes, which is not limited by the present disclosure, and those skilled in the art may select according to actual requirements.

In some embodiments, after operation S300, the method further includes the following operations.

Operation S400, an interlayer-dielectric layer 150 is formed on the side of the semiconductor structure away from the substrate 81, in the well-lead-out region 100a of the semiconductor structure, the interlayer-dielectric layer 150 has at least one lead-out hole 151 corresponding to each well-connection structure 120, a connecting column 152 is provided in the lead-out hole 151, one end of the connecting column 152 is connected to the corresponding well-connection structure 120, and the other end of the connecting column 152 is exposed outside the interlayer-dielectric layer 150 to serve as a lead-out pad.

The interlayer-dielectric layer 150 may be silicon oxide, which is within the scope that is easy for those skilled in the art to understand and will not be repeated herein. As shown in FIG. 47, in the well-lead-out region 100a, the interlayer-dielectric layer 150 may have 4 connecting columns 152 corresponding to each well-connection structure 120. In this way, the potentials at various positions of the connecting layer 121 may be substantially the same as each other. In some embodiments, the end of each connecting column 152 close to the substrate 81 (i.e., the lower end) is connected to the well-connection structure 120. Therefore, the ends of the connecting columns 152 close to the substrate 81 (i.e., the lower ends) may be substantially maintained on the same horizontal plane, and the process difficulty may be reduced. It should be noted that, in some embodiments, the number of the connecting columns 152 may be 1, 2, 3, 5 or more, which is not limited by the present disclosure.

In the above description of the present disclosure, unless otherwise specified and limited, the terms “fixed”, “installed”, “linked”, or “connected” should be understood broadly. For example, the term “connected” may be a fixed connection, a detachable connection, or an integrated structure, may be a mechanical connection or an electrical connection, may be a direct connection or an indirect connection through an intermediate media, or may be an internal connection between two components or an interaction between two components. Therefore, unless otherwise explicitly defined in the present disclosure, those skilled in the art may understand the specific meaning of the above terms in the present disclosure according to specific situations.

According to the above description of the present disclosure, those skilled in the art may also understand that the following terms, such as “up”, “down”, “front”, “back”, “left”, “right”, “length”, “width”, “thickness”, “vertical”, “horizontal”, “top”, “bottom”, “inside”, “outside”, “axial”, “radial”, “circumferential”, “center”, “longitudinal”, “transverse”, “clockwise” or “anticlockwise” indicating an orientation or a position relationship are based on the orientation or the position relationship shown in the figures of the present disclosure, which is only for the purpose of explaining the scheme of the present disclosure and simplifying the present disclosure, rather than indicating or implying that the device or element involved must have a specific orientation, and must be configured and operated in the specific orientation, so that the aforementioned terms indicating an orientation or a position relationship cannot be understood or interpreted as a limitation to the scheme of the present disclosure.

In addition, the terms “first” or “second” used in the present disclosure referring to the number or ordinal number are only for description purposes and cannot be understood as indicating or implying a relative importance or implying the number of the indicated technical features. Therefore, features defined by the “first” or “second” may explicitly or implicitly indicate that at least one such feature is included. In the description of the present disclosure, “a plurality” means at least two, such as two, three or more, unless otherwise specified.

The above is only the implementation modes of the present disclosure, which does not limit the patent scope of the present disclosure. Any equivalent structure or equivalent process transformation made by using the contents of the description and figures of the present disclosure, or directly or indirectly applied in other related technical fields, is similarly included in the patent protecting scope of the present disclosure.

What is claimed is:

1. A memory block, comprising:
a substrate;
a memory array, arranged on the substrate and comprising a plurality of memory cells distributed in a three-dimensional array, wherein the memory array comprises a plurality of memory subarray layers sequentially stacked along a height direction, and each memory subarray layer comprises a drain-region semiconductor layer, a channel semiconductor layer, and a source-region semiconductor layer stacked along the height direction; each drain-region semiconductor layer comprises a plurality of drain-region semiconductor strips distributed along a row direction, each channel semiconductor layer comprises a plurality of channel semiconductor strips distributed along the row direction, and each source-region semiconductor layer comprises a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column; and
a well-lead-out region, comprising a plurality of well-connection structures, wherein each semiconductor-strip-structure column extends to the well-lead-out region; in the well-lead-out region, each semiconductor-strip-structure column comprises a stepped structure with a plurality of steps; and each well-connection structure corresponds to a corresponding semiconductor-strip-structure column, for electrically connecting the channel semiconductor strips in the corresponding semiconductor-strip-structure column together by using the stepped structure in the corresponding semiconductor-strip-structure column, and then leads out the channel semiconductor strips in the corresponding semiconductor-strip-structure column.

2. The memory block according to claim 1, wherein
at least part of each channel semiconductor strip in each semiconductor-strip-structure column is exposed through the stepped structure thereof; and
each well-connection structure comprises a connecting layer, the connecting layer covers the stepped structure of the corresponding semiconductor-strip-structure column and connects the channel semiconductor strips in the corresponding semiconductor-strip-structure column together.

3. The memory block according to claim 2, wherein
each step comprises a first surface and a second surface, the first surface is parallel to the substrate, and the second surface is perpendicular to the substrate;
the first surface of each step is configured to expose at least part of a corresponding channel semiconductor strip in the corresponding semiconductor-strip-structure column and the second surface of each step is covered by an insulating dielectric, to avoid exposing the drain-region semiconductor strips and the source-region semiconductor strips in the corresponding semiconductor-strip-structure column;
the connecting layer is configured to cover the stepped structure, contact the part of the corresponding channel semiconductor strip exposed through the first surface of each step, and be insulated from the drain-region semiconductor strips and the source-region semiconductor strips in the corresponding semiconductor-strip-structure column through the insulating dielectric.

4. The memory block according to claim 2, wherein
the connecting layer is a polycrystalline silicon connecting layer.

5. The memory block according to claim 4, wherein
a doping type of the connecting layer is the same as that of the channel semiconductor strip and is opposite to that of the drain-region semiconductor strip and the source-region semiconductor strip.

6. The memory block according to claim 2, wherein
each well-connection structure further comprises a connection-improvement layer arranged on the connecting layer, and the connection-improvement layer is a metal-silicide layer.

7. The memory block according to claim 1, wherein
each drain-region semiconductor strip, each channel semiconductor strip, and each source-region semiconductor strip are single-crystal semiconductor strips respectively.

8. The memory block according to claim 1, wherein
along the height direction, two adjacent memory subarray layers comprise one drain-region semiconductor layer, one channel semiconductor layer, one source-region semiconductor layer, another channel semiconductor layer, and another drain-region semiconductor layer sequentially stacked to share the same source-region semiconductor layer; and
an interlayer isolation layer is arranged between every two adjacent memory subarray layers and another two adjacent memory subarray layers to isolate every two adjacent memory subarray layers from another two adjacent memory subarray layers.

9. The memory block according to claim 1, further comprising:
an interlayer-dielectric layer, covering the memory array and the well-lead-out region, wherein, in the well-lead-out region, the interlayer-dielectric layer has at least one lead-out hole corresponding to each well-connection structure, a connecting column is arranged in the lead-out hole, one end of the connecting column is connected to a corresponding well-connection structure, and the other end of the connecting column is exposed outside the interlayer-dielectric layer to serve as a lead-out pad.

10. A manufacture method of a memory block, comprising:
providing a semiconductor structure, wherein the semiconductor structure comprises a substrate and a plurality of memory subarray layers arranged on the substrate and sequentially stacked along a height direction, and each memory subarray layer comprises a drain-region semiconductor layer, a channel semiconductor layer, and a source-region semiconductor layer stacked along the height direction; each drain-region semiconductor layer comprises a plurality of drain-region semiconductor strips distributed along a row direction, each channel semiconductor layer comprises a plurality of channel semiconductor strips distributed along the row direction, and each source-region semiconductor layer comprises a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column;
forming a plurality of removing openings on the side of the semiconductor structure away from the substrate and corresponding to a well-lead-out region of the semiconductor structure, wherein each removing opening corresponds to a corresponding semiconductor-strip-structure column;
removing at least part of the corresponding semiconductor-strip-structure column through the each removing opening, to enable each semiconductor-strip-structure column to include a stepped structure in the well-lead-out region, wherein the stepped structure comprises a plurality of steps; and
forming a well-connection structure in the each removing opening, wherein the well-connection structure corresponds to the corresponding semiconductor-strip-structure column, for electrically connecting the channel semiconductor strips in the corresponding semiconductor-strip-structure column together by using the stepped structure in the corresponding semiconductor-strip-structure column.

11. The manufacture method according to claim 10, wherein
each step of the stepped structure comprises a first surface and a second surface, the first surface is parallel to the substrate, and the second surface is perpendicular to the substrate; the first surface of each step is configured to expose at least part of a corresponding channel semiconductor strip in the corresponding semiconductor-strip-structure column; and
before the forming a well-connection structure in the each removing opening, the method further comprises:
depositing an insulating dielectric layer on the stepped structure, wherein the insulating dielectric layer covers the first surface and the second surface of each step; and
removing the insulating dielectric layer covering the first surface of each step.

12. The manufacture method according to claim 10, wherein
the forming a well-connection structure in the each removing opening comprises:
forming a connecting layer in the each removing opening, wherein the connecting layer covers the stepped structure of the corresponding semiconductor-strip-structure column, for electrically connecting the channel semiconductor strips in the corresponding semiconductor-strip-structure column together.

13. The manufacture method according to claim 12, wherein
the forming a well-connection structure in the each removing opening further comprises:
forming a connection-improvement layer on the side of the connecting layer away from the substrate.

14. The manufacture method according to claim 13, wherein
the connecting layer is a polycrystalline silicon connecting layer, and the connection-improvement layer is a metal-silicide layer.

15. The manufacture method according to claim 10, wherein
after the forming a well-connection structure in the each removing opening, the method further comprises:
forming an interlayer-dielectric layer on the side of the semiconductor structure away from the substrate, wherein, in the well-lead-out region of the semiconductor structure, the interlayer-dielectric layer has at least one lead-out hole corresponding to the well-connection structure, a connecting column is arranged in the lead-out hole, one end of the connecting column is connected to a corresponding well-connection structure, and the other end of the connecting column is exposed outside the interlayer-dielectric layer to serve as a lead-out pad.

16. A memory block, comprising:
a substrate;
a memory array, arranged on the substrate and comprising a plurality of memory cells distributed in a three-dimensional array, wherein the memory array comprises a plurality of memory subarray layers sequentially stacked along a height direction, and each memory subarray layer comprises a drain-region semiconductor layer, a channel semiconductor layer, and a source-region semiconductor layer stacked along the height direction; each drain-region semiconductor layer comprises a plurality of drain-region semiconductor strips distributed along a row direction, each channel semiconductor layer comprises a plurality of channel semiconductor strips distributed along the row direction, and each source-region semiconductor layer comprises a plurality of source-region semiconductor strips distributed along the row direction; each drain-region semiconductor strip, each channel semiconductor strip, and each source-region semiconductor strip extend along a column direction respectively; drain-region semiconductor strips, channel semiconductor strips, and source-region semiconductor strips in the same column of the memory subarray layers is defined as a semiconductor-strip-structure column; and
a well-lead-out region, comprising a plurality of well-connection structures, wherein each semiconductor-strip-structure column extends to the well-lead-out region; in the well-lead-out region, each semiconductor-strip-structure column comprises a stepped structure with a plurality of steps, to enable each channel semiconductor strip in each semiconductor-strip-structure column to be at least partially exposed; each well-connection structure corresponds to a corresponding semiconductor-strip-structure column, and comprises a plurality of well-connection columns spaced apart from each other along the column direction; the well-connection columns and the channel semiconductor strips in the corresponding semiconductor-strip-structure column are arranged in one-to-one correspondence, one end of each well-connection column is connected to a corresponding channel semiconductor strip, the other end of each well-connection column serves as a well-lead-out pad.

17. The memory block according to claim 16, wherein
each step comprises a first surface and a second surface, wherein the first surface is parallel to the substrate, and the second surface is perpendicular to the substrate;
the first surface of each step is configured to expose at least part of the corresponding channel semiconductor strip in the corresponding semiconductor-strip-structure column.

18. The memory block according to claim 17, wherein
each well-connection structure comprises a filling layer, the filling layer is a polycrystalline silicon filling layer, and the filling layer covers the stepped structure of the corresponding semiconductor-strip-structure column;
in the filling layer, the plurality of well-connection columns are spaced apart from each other along the column direction, one end of each well-connection column is connected to the corresponding channel semiconductor strip, the other end of each well-connection column is exposed outside the filling layer to serve as the well-lead-out pad.

19. The memory block according to claim 18, wherein
an isolating layer is arranged between the polycrystalline silicon filling layer and each well-connection column.

20. The memory block according to claim 19, wherein
the first surface and the second surface of each step are covered by an insulating dielectric layer, the insulating dielectric layer is covered by the filling layer, and each well-connection column passes through the insulating dielectric covered on the first surface to connect to the corresponding channel semiconductor strip.
